(19) United States
(12) Patent Application Publication
(10) Pub. No.: US 2024/0371752 A1
(43) Pub. Date: Nov. 7, 2024

(54) SEMICONDUCTOR DEVICE AND MANUFACTURING METHOD OF SEMICONDUCTOR DEVICE

(71) Applicant: SK hynix Inc., Icheon-si Gyeonggi-do (KR)

(72) Inventors: Won Geun CHOI, Icheon-si Gyeonggi-do (KR); Jung Shik JANG, Icheon-si Gyeonggi-do (KR); Rho Gyu KWAK, Icheon-si Gyeonggi-do (KR); Seok Min CHOI, Icheon-si Gyeonggi-do (KR); Jeong Hwan KIM, Icheon-si Gyeonggi-do (KR); Na Yeong YANG, Icheon-si Gyeonggi-do (KR); In Su PARK, Icheon-si Gyeonggi-do (KR); Jung Dal CHOI, Icheon-si Gyeonggi-do (KR)

(73) Assignee: SK hynix Inc., Icheon-si Gyeonggi-do (KR)

(21) Appl. No.: 18/629,346

(22) Filed: Apr. 8, 2024

(30) Foreign Application Priority Data
May 3, 2023 (KR) 10-2023-0057523
Aug. 2, 2023 (KR) 10-2023-0101210
Aug. 9, 2023 (KR) 10-2023-0104288
Aug. 24, 2023 (KR) 10-2023-0111479
Oct. 5, 2023 (KR) 10-2023-0132473

(51) Int. Cl. H01L 23/522; H10B 41/27; H10B 43/27; H10B 63/00

(52) U.S. Cl. CPC H01L 23/5226; H10B 41/27; H10B 43/27; H10B 63/84

(57) ABSTRACT

A semiconductor device may include: a first gate structure including a plurality of first conductive layers that are alternately stacked with a plurality of first insulating layers; a second gate structure including a plurality of second conductive layers that are alternately stacked with a plurality of second insulating layers; a third gate structure including third conductive layers that are alternately stacked with a plurality of third insulating layers; and a first contact plug extending into the first gate structure through the third gate structure and the second gate structure, the first contact plug connected to a first of the plurality of first conductive layers, and the first contact plug including a first inflection portion located at an interface between the second gate structure and the third gate structure.

### CROSS-REFERENCE TO RELATED APPLICATION

This application claims priority under 35 U.S.C. § 119(a) to Korean Patent Application No. 10-2023-0057523 filed on May 3, 2023, Korean Patent Application No. 10-2023-0101210 filed on Aug. 2, 2023, Korean Patent Application No. 10-2023-0104288 filed on Aug. 9, 2023, Korean Patent Application No. 10-2023-0111479 filed on Aug. 24, 2023, and Korean Patent Application No. 10-2023-0132473 filed on Oct. 5, 2023, the entire contents of which applications are incorporated herein by reference in their entirety.

### BACKGROUND

### 1. Technical Field

Embodiments of the present disclosure relate to an electronic device, and more particularly, to a semiconductor device and a manufacturing method for the semiconductor device.

### 2. Related Art

The degree of integration of a semiconductor device is mainly determined by an area occupied by a unit memory cell. Recently, as the improvement in the degree of integration of a semiconductor device for forming memory cells in a single layer on a substrate reaches a limit, a three-dimensional semiconductor device for stacking memory cells on a substrate has been proposed. Furthermore, in order to improve the operational reliability of such a semiconductor device, various structures and manufacturing methods have been developed.

### SUMMARY

In an embodiment, a semiconductor device may include: a first gate structure including a plurality of first conductive layers that are alternately stacked with a plurality of first insulating layers; a second gate structure including a plurality of second conductive layers that are alternately stacked with a plurality of second insulating layers; a third gate structure including a plurality of third conductive layers that are alternately stacked with a plurality of third insulating layers; and a first contact plug extending into the first gate structure through the third gate structure and the second gate structure, the first contact plug connected to a first of the plurality of first conductive layers, and the first contact plug including a first inflection portion located at an interface between the second gate structure and the third gate structure.

In an embodiment, a semiconductor device may include: a first gate structure including a plurality of first conductive layers that are alternately stacked with a plurality of first insulating layers; a second gate structure including a plurality of second conductive layers that are alternately stacked with a plurality of second insulating layers; a plurality of first contact plugs located in the second gate structure and the first gate structure, wherein each of the plurality of first contact plugs includes a first pad located in the first gate structure, extends into the first gate structure through the first pad, and is connected to a different one of the plurality of first conductive layers; and a plurality of second contact plugs located in the second gate structure, wherein each of the plurality of second contact plugs is connected to a different one of the plurality of second conductive layers.

In an embodiment, a manufacturing method of a semiconductor device may include: forming a first stack including a plurality of first material layers; forming, over the first stack, a second stack including a plurality of second material layers; forming a plurality of first openings through the second stack to expose the first stack; forming, over the second stack, a third stack including a plurality of third material layers; forming a plurality of second openings through the third stack, wherein each of the plurality of second openings is connected to a different one of the plurality of first openings; forming a plurality of third openings through the third stack to expose the second stack; extending the plurality of first openings into the first stack, wherein each of the plurality of first openings exposes a different one of the plurality of first material layers; and extending the plurality of third openings into the second stack, wherein each of the plurality of third openings exposes a different one of the plurality of second material layers.

In an embodiment, a manufacturing method of a semiconductor device may include: forming a first stack including a plurality of first material layers; forming a plurality of first pad openings in the first stack; forming one of a plurality of first pad sacrificial layers in each of the plurality of first pad openings; forming a second stack on the first stack, the second stack including a plurality of second material layers; forming a plurality of first openings through the second stack to expose the plurality of first pad sacrificial layers; removing each of the plurality of first pad sacrificial layers through a corresponding one of the plurality of first openings; extending the plurality of first openings into the first stack through the plurality of first pad openings, wherein each of the plurality of first openings exposes a different one of the plurality of first material layers; and forming a first contact plug in each of the plurality of first openings, wherein each first contact plug includes a first pad located in a corresponding one of the plurality of first pad openings.

In an embodiment, a semiconductor device may include: a gate structure including a first gate line having a first resistance, a second gate line having a second resistance, and a third gate line having a third resistance; a channel structure extending through a cell region of the gate structure; a first contact plug extending into the gate structure and electrically connected to the first gate line; a second contact plug extending into the gate structure and electrically connected to the second gate line; and a third contact plug extending into the gate structure and electrically connected to the third gate line; wherein the first contact plug, the second contact plug, and the third contact plug may be spaced apart from the cell region by different distances in an arrangement order, and wherein a stacking order of the first gate line, the second gate line, and the third gate line may be different from the arrangement order of the first contact plug, the second contact plug, and the third contact plug.

In an embodiment, a semiconductor device may include: a first gate structure including a first gate line having a first resistance and a second gate line having a second resistance; a second gate structure located on the first gate structure and including a third gate line having a third resistance and a fourth gate line having a fourth resistance; a channel structure including a first sub-channel extending through a cell region of the first gate structure and a second sub-channel extending through the second gate structure, wherein the second sub-channel is connected to the first sub-channel; a first contact plug extending into the first gate structure through the second gate structure and electrically connected to the first gate line; a second contact plug extending into the first gate structure through the second gate structure and electrically connected to the second gate line; a third contact plug extending into the second gate structure, electrically connected to the third gate line, and located between the first contact plug and the second contact plug; and a fourth contact plug extending into the second gate structure and electrically connected to the fourth gate line.

In an embodiment, a semiconductor device may include: a gate structure including first gate lines, third gate lines, and second gate lines stacked between the first gate lines and the third gate lines; a channel structure extending through a cell region of the gate structure; a first group of first contact plugs extending into the gate structure, wherein each of the first contact plugs is electrically connected to a different one of the first gate lines; a second group of second contact plugs extending into the gate structure, wherein each of the second contact plugs is electrically connected to a different one of the second gate lines; and a third group of third contact plugs extending into the gate structure, wherein each of the second contact plugs is electrically connected to a different one of the third gate lines, wherein the second group of second contact plugs may be located closer to the cell region than where the first group of first contact plugs is located, and the second group of first contact plugs is located closer to the cell region than where the third group of third contact plugs is located.

In an embodiment, a semiconductor device may include: a gate structure including a source select line, a drain select line, and a plurality of word lines located between the source select line and the drain select line; a source contact plug extending through the gate structure and electrically connected to the source select line; a first cell contact plug extending through the gate structure and electrically connected to a first word line of the plurality of word lines; and a drain contact plug extending through the gate structure and electrically connected to the drain select line; wherein the source contact plug may be located between the drain contact plug and the first cell contact plug.

In an embodiment, a semiconductor device may include: a first gate structure including a plurality of stacked word lines; a second gate structure including a plurality of first select lines, each of the plurality of first select lines terminated within a first stair structure, wherein the first gate structure and the second gate structure are stacked; a plurality of channel structures extending through the first gate structure and the second gate structure; a plurality of first contact plugs extending through the first gate structure, wherein each of the first contact plugs is electrically connected to a different one of the word lines; and second contact plugs, wherein each of the plurality of second contact plug is electrically connected to a different one of the plurality of first select lines terminated within the first stair structure.

In an embodiment, a semiconductor device may include: a first gate structure having a first width and including a plurality of first gate lines that are alternately stacked with a plurality of first insulating layers; a second gate structure located over the first gate structure, including a plurality of second gate lines that are alternately stacked with a plurality of second insulating layers, and having a second width smaller than the first width, wherein each of the second gate lines is terminated within a first stair structure; a plurality of first contact plugs spaced apart from the second gate structure, and extending into the first gate structure, wherein each of the plurality of first contact plugs is electrically connected to a different one of the first gate lines; and a plurality of second contact plugs, wherein each of the plurality of second contact plugs is electrically connected to a different one of the plurality of second gate lines terminated within the first stair structure and has a smaller width than a width of the first contact plugs.

In an embodiment, a manufacturing method of a semiconductor device may include: forming a first stack including first material layers that are alternately stacked with first insulating layers; forming a second stack on the first stack, the second stack including second material layers that are alternately stacked with second insulating layers; forming a first stair structure in the second stack; forming sacrificial plugs extending into the first stack, wherein each of the sacrificial plugs is connected to a different one of the first material layers; replacing the first material layers and the second material layers with third material layers; replacing the sacrificial plugs with first contact plugs; and forming second contact plugs, wherein each of the second contact plugs is electrically connected to a different one of the third material layers terminated within the first stair structure.

In an embodiment, a semiconductor device may include: a gate structure including a plurality of stacked gate lines; a first contact plug extending through the gate structure and connected to a first gate line of the plurality of gate lines; a second contact plug extending through the gate structure and connected to a second gate line of the gate lines; a first pass transistor connected to the first gate line through the first contact plug; and a second pass transistor connected to the second gate line through the second contact plug, wherein a pitch between the first contact plug and the second contact plug may be substantially the same as a pitch between the first pass transistor and the second pass transistor.

In an embodiment, a semiconductor device may include: a gate structure including a plurality of stacked gate lines; a plurality of first contact plugs extending at different depths from a first surface of the gate structure toward a second surface of the gate structure; a block word line located near the gate structure and extending in a first direction; a plurality of pass transistors, wherein each of the plurality of pass transistors includes a junction and is located in a different one of a plurality of active regions extending in a second direction perpendicular to the first direction and connected to the block word line; and a plurality of second contact plugs aligned with the first contact plugs in the second direction, wherein each of the plurality of second contact plugs is connected to a different one of the plurality of junctions of the pass transistors.

In an embodiment, a semiconductor device may include: a first gate structure including a plurality of stacked first gate lines and including a first cell region, a second cell region, a first common region located between the first cell region and the second cell region, and a second common region located between the first common region and the second cell region; a plurality of first channel structures extending through the first cell region and the first common region of the first gate structure; a plurality of second channel structures extending through the second cell region and the second common region of the first gate structure; and a plurality of first contact plugs extending through the first common region of the first gate structure, wherein each of the plurality of first contact plugs is electrically connected to a different one of the first gate lines.

In an embodiment, a semiconductor device may include: a first gate structure including a plurality of stacked first gate lines and including a first cell region adjacent to a first common region in a first direction; a second gate structure adjacent to the first gate structure in a second direction intersecting the first direction, the second gate structure including a plurality of stacked second gate lines and including a third cell region adjacent to a third common region in the first direction; a first page buffer located below the third cell region and the third common region; a plurality of first channel structures extending through the first cell region and the first common region of the first gate structure; a plurality of first bit lines extending in the second direction and connecting the first channel structures to the first page buffer; and a plurality of first contact plugs extending through the first common region of the first gate structure, wherein each of the plurality of first contact plugs is electrically connected to a different one of the first gate lines.

In an embodiment, a semiconductor device may include: a first gate structure including a plurality of stacked first gate lines and including a first common region and a second common region; a second gate structure including stacked second gate lines and including a third common region and a fourth common region; a plurality of first channel structures extending through the first common region of the first gate structure; a plurality of fourth channel structures extending through the fourth common region of the second gate structure; a plurality of first contact plugs extending through the first common region, wherein each of the first contact plugs is electrically connected to a different one of the first gate lines; and a plurality of second contact plugs extending through the fourth common region, wherein each of the second contact plugs is electrically connected to a different one of the second gate lines.

### BRIEF DESCRIPTION OF THE DRAWINGS

FIG. 1A and FIG. 1B are diagrams illustrating the structure of a semiconductor device in accordance with an embodiment.

FIG. 2A and FIG. 2B are diagrams illustrating the structure of a semiconductor device in accordance with an embodiment.

FIG. 3 is a diagram illustrating the structure of a semiconductor device in accordance with an embodiment.

FIG. 4 is a diagram illustrating the structure of a semiconductor device in accordance with an embodiment.

FIG. 5 is a diagram illustrating the structure of a semiconductor device in accordance with an embodiment.

FIG. 6A through FIG. 6K are diagrams illustrating various views of a semiconductor device formed using a method of manufacturing a semiconductor device in accordance with an embodiment.

FIG. 7A through FIG. 7C are diagrams illustrating various views of a semiconductor device formed using a method of manufacturing a semiconductor device in accordance with an embodiment.

FIG. 8A through FIG. 8C are diagrams illustrating various views of a semiconductor device formed using a method of manufacturing a semiconductor device in accordance with an embodiment.

FIG. 9A through FIG. 9C are diagrams illustrating the structure of a semiconductor device in accordance with an embodiment.

FIG. 10A and FIG. 10B are diagrams illustrating the structure of a semiconductor device in accordance with an embodiment.

FIG. 11A through FIG. 11C are diagrams illustrating the structure of a semiconductor device in accordance with an embodiment.

FIG. 12A through FIG. 12C are diagrams illustrating the structure of a semiconductor device in accordance with an embodiment.

FIG. 13A through FIG. 13C are diagrams illustrating the structure of a semiconductor device in accordance with an embodiment.

FIG. 14A and FIG. 14B are diagrams illustrating the structure of a semiconductor device in accordance with an embodiment.

FIG. 15A and FIG. 15B are diagrams illustrating the structure of a semiconductor device in accordance with an embodiment.

FIG. 16 is a diagram illustrating the structure of a semiconductor device in accordance with an embodiment.

FIG. 17A through FIG. 17H are diagrams illustrating various views of a semiconductor device formed using a method of manufacturing a semiconductor device in accordance with an embodiment.

FIG. 18A through FIG. 18C are diagrams illustrating the structure of a semiconductor device in accordance with an embodiment.

FIG. 19A and FIG. 19B are diagrams illustrating the structure of a semiconductor device in accordance with an embodiment.

FIG. 20A and FIG. 20B are cross-sectional views illustrating the structure of a semiconductor device in accordance with an embodiment.

FIG. 21A through FIG. 21G are diagrams illustrating various views of a semiconductor device formed using a method of manufacturing a semiconductor device in accordance with an embodiment.

FIG. 22A and FIG. 22B are diagrams illustrating various views of a semiconductor device formed using a method of manufacturing a semiconductor device in accordance with an embodiment.

FIG. 23A and FIG. 23B are diagrams illustrating the configuration of a semiconductor device in accordance with an embodiment.

FIG. 24A through FIG. 24D are diagrams illustrating the structure of a semiconductor device in accordance with an embodiment.

FIG. 25 is a diagram illustrating the structure of a semiconductor device in accordance with an embodiment.

FIG. 26A and FIG. 26B are diagrams illustrating the structure of a semiconductor device in accordance with an embodiment.

FIG. 27A through FIG. 27D are diagrams illustrating the structure of a semiconductor device in accordance with an embodiment.

FIG. 28A through FIG. 28E are diagrams illustrating the structure of a semiconductor device in accordance with an embodiment.

FIG. 29A and FIG. 29B are diagrams illustrating the structure of a semiconductor device in accordance with an embodiment.

FIG. 30A through FIG. 30C are diagrams illustrating the structure of a semiconductor device in accordance with an embodiment.

FIG. 31A through FIG. 31E are diagrams illustrating the structure of a semiconductor device in accordance with an embodiment.

FIG. 32 is a configuration diagram of a semiconductor device according to an embodiment of the present disclosure.

FIG. 33 is a configuration diagram of a semiconductor device according to an embodiment of the present disclosure.

### DETAILED DESCRIPTION

Various embodiments are directed to a semiconductor device having a stable structure and improved characteristics and a manufacturing method of the semiconductor device.

By stacking memory cells in three dimensions, the degree of integration of a semiconductor device may be improved. A semiconductor device having a stable structure and improved reliability may also be provided.

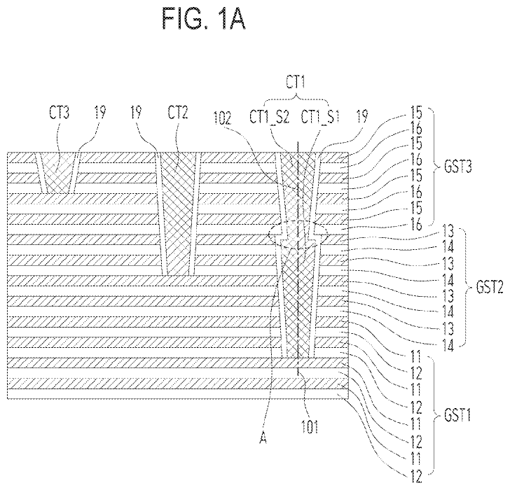

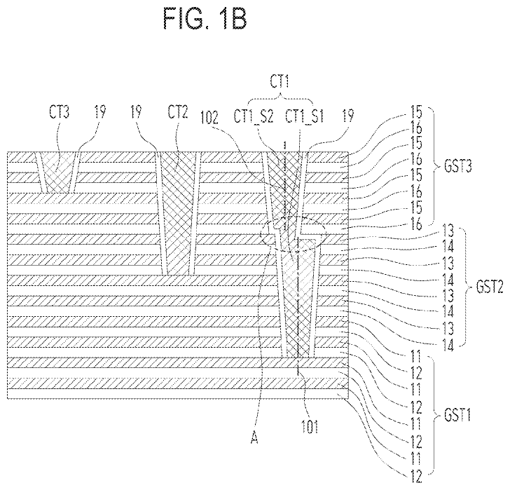

Although terms such as “first” and “second” may be used herein to describe various elements, the elements are not limited by these terms. These terms are used to distinguish one element from other elements and do not imply size, order, priority, or importance. As described in the detailed description and shown in the drawings, multiple gate structures or stacks may be formed on or over each other in multiple processes. For example, a first gate structure (or first stack) may be formed, and a second gate structure (or second stack) may be formed on, over, above, covering, stacked on, or adjacent to the first gate structure (or first stack), such as shown in FIG. 1, for example. Similarly, a third gate structure (or third stack) may be formed on, over, above, covering, stacked on, or adjacent to the second gate structure (or second stack), and the process may be repeated to include the desirable quantity of gate structures (or stacks). Additional processes may be applied to previous gate structures (or stacks) between formation of consecutive gate structures (or stacks). Terms such as “top,” “bottom,” “above,” “below,” “under,” “over,” “upper,” “lower,” “uppermost,” “lowermost,” “front,” “rear,” “level,” and other terms implying spatial relationship are provided only for the purpose of ease of description or reference and are not otherwise limiting.

Many element groups are repeated in a single drawing or embodiment and many other repeated elements may have a one-to-one correspondence with a group of elements. For example, one group of elements may include any combination of one or more holes, one or more openings, a pad, a pad opening, one or more inflection portions, a spacer a contact plug, two or more sub-contact plugs, and so forth, which group's elements may be referred to as corresponding to each other. Each group or element in a group may also be considered to correspond to elements outside the group. For example, a contact plug of a plurality of contact plugs may be electrically connected to one conductive layer of a plurality of conductive layers, in which example the contact plug may be referred to as corresponding to the conductive layer to which the contact plug is electrically connected. Generally, when one of a first plurality of elements corresponds to a one of a second plurality of elements, the correspondence is on a one-to-one basis. For example, each of a first plurality of elements may be coupled to, electrically connected to, grouped with, processed with, arranged with, and so forth, a different one of the second plurality of elements.

The cross-hatching throughout the figures illustrates corresponding or similar areas between the figures rather than indicating the materials for the areas. Content described for one figure and applicable to subsequent figures will not be repeated for each figure for the sake of brevity throughout the specification.

Hereafter, embodiments in accordance with the technical spirit of the present disclosure will be described with reference to the accompanying drawings.

FIG. 1A and FIG. 1B are diagrams illustrating the structure of a semiconductor device in accordance with an embodiment.

Referring to FIG. 1A and FIG. 1B, the semiconductor device includes a first gate structure GST1, a second gate structure GST2, a third gate structure GST3, and a first contact plug CT1. The semiconductor device further includes a second contact plug CT2, a third contact plug CT3, an insulating spacer 19, or any combination thereof.

The first gate structure GST1 includes a plurality of first conductive layers 11 that are alternately stacked with a plurality of first insulating layers 12, such as shown in FIG. 1A and many of the other figures. The second gate structure GST2 includes a plurality of second conductive layers 13 that are alternately stacked with a plurality of second insulating layers 14. Alternately stacked includes, for example, forming a conductive layer on (over) an insulating layer, forming a second insulating layer on (over) the conductive layer, forming second conductive layer on (over) the second insulating layer, and so forth. The third gate structure GST3 includes a plurality of third conductive layers 15 that are alternately stacked with a plurality of third insulating layers 16. Thus, each gate structure may include a plurality of stacked layers. The second gate structure GST2 is located between the first gate structure GST1 and the third gate structure GST3 in this example. The quantity of stacked layers (the conductive layers 11, 13, or 15 and the insulating layers 12, 14, or 16) included in the first gate structure GST1, the second gate structure GST2, and the third gate structure GST3 may be the same as or different from each other. The first conductive layers 11, the second conductive layers 13, and the third conductive layers 15 may be gate lines. The first conductive layers 11, the second conductive layers 13, and the third conductive layers 15 may be word lines, select lines, or bit lines.

The first contact plug CT1 extends into the first gate structure GST1 through the third gate structure GST3 and the second gate structure GST2 in the example of FIG. 1A. The first contact plug CT1 is connected to a one of the first conductive layers 11, in this example, the first conductive layer 11 that is second from the bottom of the first gate structure GST1 in FIG. 1A. As an example, the semiconductor device may include a plurality of first contact plugs CT1, and each of the first contact plugs CT1 may be electrically connected to a different one of the first conductive layers 11.

The first contact plug CT1 may include an inflection portion A. As an example, the inflection portion A may be located at an interface between the second gate structure GST2 and the third gate structure GST3. The inflection portion A may be a section where a gradient of sidewalls of the first contact plug CT1 changes suddenly or may be a portion where a step exists in the sidewalls. For example, an inflection portion may generally be located where one gate structure and another gate structure meet.

The first contact plug CT1 includes a first sub-contact plug CT1_S1 and a second sub-contact plug CT1_S2 in the example of FIG. 1A. The first sub-contact plug CT1_S1 extends into the first gate structure GST1 through the second gate structure GST2 and is connected to one of the first conductive layers 11 of the first gate structure GST1 in the example of FIG. 1A. The second sub-contact plug CT1_S2 extends through the third gate structure GST3 and is connected to the first sub-contact plug CT1_S1. The first sub-contact plug CT1_S1 and the second sub-contact plug CT1_S2 may comprise separate layers between which an interface exists, i.e., where the first sub-contact plug CT1_S1 and the second sub-contact plug CT1_S2 connect or contact each other or may be a single layer connected without an interface.

The first sub-contact plug CT1_S1 and the second sub-contact plug CT1_S2 may have a uniform width or a variable width. As an example, the first sub-contact plug CT1_S1 and the second sub-contact plug CT1_S2 each have a smaller width at a lower end than at an upper end, such as shown in FIG. 1A. At an area where the first sub-contact plug CT1_S1 and the second sub-contact plug CT1_S2 are connected to each other, the first sub-contact plug CT1_S1 has a greater width than the width at the lower end of the second sub-contact plug CT1_S2, and the inflection portion A results from a difference in width between the first sub-contact plug CT1_S1 and the second sub-contact plug CT1_S2 in the example of FIG. 1A. The inflection portion A is located at an interface between the first sub-contact plug CT1_S1 and the second sub-contact plug CT1_S2. At inflection portion A, the width of the first sub-contact plug CT1_S1 and the width of the second sub-contact plug CT1_S2 may be different from each other.

The first sub-contact plug CT1_S1 and the second sub-contact plug CT1_S2 may be aligned or misaligned with each other. Referring to the example of FIG. 1A, a central axis 101 of the first sub-contact plug CT1_S1 and a central axis 102 of the second sub-contact plug CT1_S2 coincide or align with each other to form a single straight line. Referring to the example of FIG. 1B, a central axis 101 of the first sub-contact plug CT1_S1 and a central axis 102 of the second sub-contact plug CT1_S2 deviate from each other and are not aligned to form a single straight line.

The second contact plug CT2 extends into the second gate structure GST2 through the third gate structure GST3 as shown in the example of FIG. 1A. The second contact plug CT2 is connected to one of the second conductive layers 13 of the second gate structure GST2, in this example, the second conductive layer 13 that is second from the bottom of the second gate structure GST2 in FIG. 1A. As an example, the semiconductor device may include a plurality of second contact plugs CT2, and each of the second contact plugs CT2 may be electrically connected to one of the second conductive layers 13. As another example, the semiconductor device may include a plurality of second contact plugs CT2, and each of the second contact plugs CT2 may be electrically connected to a different one of the second conductive layers 13.

The third contact plug CT3 is located in the third gate structure GST3. The third contact plug CT3 is connected to one of the third conductive layers 15 of the third gate structure GST3, in this example, the third conductive layer 13 that is second from the bottom of the third gate structure GST3 in FIG. 1A. As an example, the semiconductor device may include a plurality of third contact plugs CT3, and each of the third contact plugs CT3 may be electrically connected to one of the third conductive layers 15. As another example, the semiconductor device may include a plurality of third contact plugs CT3, and each of the third contact plugs CT3 may be electrically connected to a different one of the third conductive layers 15.

The sidewall of each first contact plug CT1, the sidewalls of each second contact plug CT2, and the sidewalls of each third contact plug CT3 are individually surrounded by an insulating spacer 19. In other words, an insulating spacer 19 surrounds each contact plug CT1, CT2, or CT3. Each of the insulating spacers 19 may have a uniform width (or thickness) or a variable width. As an example, the insulating spacer 19 may surround the inflection portion A of the first contact plug CT1, and a shape of the inflection portion A may be transferred to the insulating spacer 19. In other words, the shape of the insulating spacer 19 may depend on the shape of the inflection portion A.

According to the structure described above, the first contact plug CT1 may be located in the first gate structure GST1, the second gate structure GST2, and the third gate structure GST3. The second contact plug CT2 may be located in the second gate structure GST2 and the third gate structure GST3. The third contact plug CT3 may be located in the third gate structure GST3. At least one of the first contact plugs CT1, the second contact plugs CT2, and the third contact plugs CT3 may include the inflection portion A.

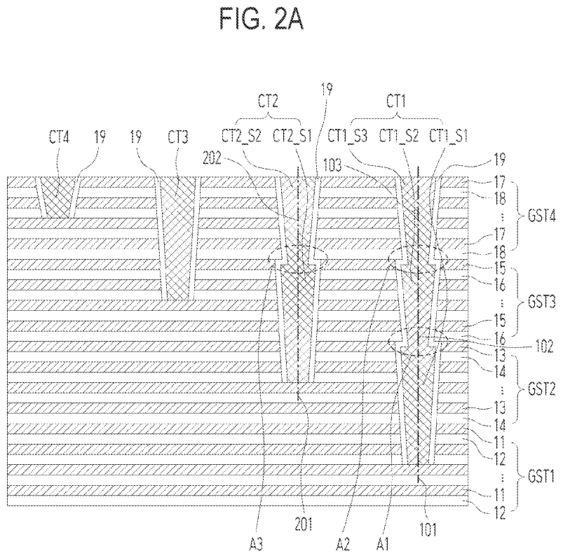

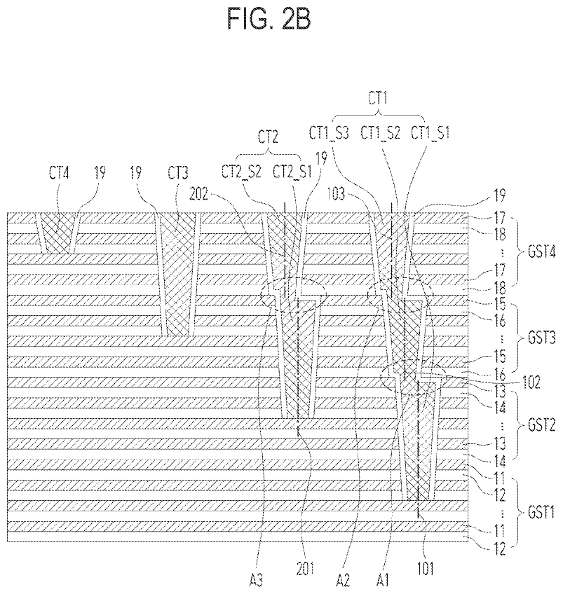

FIG. 2A and FIG. 2B are diagrams illustrating the structure of a semiconductor device in accordance with an embodiment.

Referring to FIG. 2A and FIG. 2B, the semiconductor device includes a first gate structure GST1, a second gate structure GST2, a third gate structure GST3, and a first contact plug CT1. The semiconductor device further includes a fourth gate structure GST4, a second contact plug CT2, a third contact plug CT3, a fourth contact plug CT4, an insulating spacer 19, or any combination thereof.

The first gate structure GST1 includes a plurality of first conductive layers 11 that are alternately stacked with a plurality of first insulating layers 12. The second gate structure GST2 includes a plurality of second conductive layers 13 that are alternately stacked with a plurality of second insulating layers 14. The third gate structure GST3 includes a plurality of third conductive layers 15 that are alternately stacked with a plurality of third insulating layers 16. The fourth gate structure GST4 includes a plurality of fourth conductive layers 17 that are alternately stacked with a plurality of fourth insulating layers 18. The third gate structure GST3 is located between the second gate structure GST2 and the fourth gate structure GST4 in this example. The quantity of stacked layers (the conductive layers 11, 13, 15, 17 and the insulating layers 12, 14, 16, 18) among the various gate structures may be the same as or different from each other in different gate structures.

The first contact plug CT1 extends into the first gate structure GST1 through the fourth gate structure GST4, the third gate structure GST3, and the second gate structure GST2 in the example of FIG. 2A. The first contact plug CT1 may include a first inflection portion A1 and a second inflection portion A2. As an example, the first inflection portion A1 may be located at an interface between the second gate structure GST2 and the third gate structure GST3, and the second inflection portion A2 may be located at an interface between the third gate structure GST3 and the fourth gate structure GST4.

The first contact plug CT1 includes a first sub-contact plug CT1_S1, a second sub-contact plug CT1_S2, and a third sub-contact plug CT1_S3 in the example of FIG. 2A. The third sub-contact plug CT1_S3 extends through the fourth gate structure GST4 and is connected to the second sub-contact plug CT1_S2. At an area where the second sub-contact plug CT1_S2 and the third sub-contact plug CT1_S3 are connected to each other, the second sub-contact plug CT1_S2 has a greater width than the third sub-contact plug CT1_S3, and the second inflection portion A2 results from a difference in width between the second sub-contact plug CT1_S2 and the third sub-contact plug CT1_S3. The second inflection portion A2 is located at an interface between the second sub-contact plug CT1_S2 and the third sub-contact plug CT1_S3. At the second inflection portion A2, the width of the second sub-contact plug CT1_S2 and the width of the third sub-contact plug CT1_S3 may be different from each other.

The first sub-contact plug CT1_S1 and the second sub-contact plug CT1_S2 may be aligned or misaligned with each other, and the second sub-contact plug CT1_S2 and the third sub-contact plug CT1_S3 may be aligned or misaligned with each other. Referring to the example of FIG. 2A, a central axis 101 of the first sub-contact plug CT1_S1, a central axis 102 of the second sub-contact plug CT1_S2, and a central axis 103 of the third sub-contact plug CT1_S3 coincide or align with each other to form a single straight line. Referring to the example of FIG. 2B, a central axis 101 of the first sub-contact plug CT1_S1, a central axis 102 of the second sub-contact plug CT1_S2, and a central axis 103 of the third sub-contact plug CT1_S3 deviate from each other, i.e., the three central axes 101, 102, and 103 are not aligned to form a single straight line.

The second contact plug CT2 extends into the second gate structure GST2 through the fourth gate structure GST4 and the third gate structure GST3 in the example of FIG. 2A. The second contact plug CT2 includes a third inflection portion A3. In this example, the third inflection portion A3 is located at an interface between the third gate structure GST3 and the fourth gate structure GST4.

The second contact plug CT2 includes a first sub-contact plug CT2_S1 and a second sub-contact plug CT2_S2. The first sub-contact plug CT2_S1 extends into the second gate structure GST2 through the third gate structure GST3 and the fourth gate structure GST4 and is connected to one of the second conductive layers 13 of the second gate structure GST2, in this example, the second conductive layer 13 that is second from the bottom of the second gate structure GST2 in FIG. 2A. The second sub-contact plug CT2_S2 extends through the fourth gate structure GST4 and is connected to the first sub-contact plug CT2_S1.

The first sub-contact plug CT2_S1 and the second sub-contact plug CT2_S2 of the second contact plug CT2 may be aligned or misaligned with each other. Referring to the example of FIG. 2A, a central axis 201 of the first sub-contact plug CT2_S1 and a central axis 202 of the second sub-contact plug CT2_S2 coincide or align with each other to form a single straight line. Referring to the example of FIG. 2B, a central axis 201 of the first sub-contact plug CT2_S1 and a central axis 202 of the second sub-contact plug CT2_S2 deviate from each other and are not aligned to form a single straight line.

The third contact plug CT3 extends into the third gate structure GST3 through the fourth gate structure GST4. The fourth contact plug CT4 is located in the fourth gate structure GST4. The fourth contact plug CT4 is connected to one of the fourth conductive layers 17 of the fourth gate structure GST3, in this example, the fourth conductive layer 17 that is second from the bottom of the fourth gate structure GST4 in FIG. 2A. As an example, the semiconductor device may include a plurality of fourth contact plugs CT4, and each of the fourth contact plugs CT4 may be electrically connected to one of the fourth conductive layers 17. As another example, the semiconductor device may include a plurality of fourth contact plugs CT4, and each of the fourth contact plugs CT4 may be electrically connected to a different one of the fourth conductive layers 17.

The sidewalls of each first contact plug CT1, the sidewalls of each second contact plug CT2, the sidewalls of each the third contact plug CT3, and the sidewalls of each fourth contact plug CT4 are individually surrounded by an insulating spacer 19.

According to the structure described above, the first contact plug CT1 may be located in the first gate structure GST1, the second gate structure GST2, the third gate structure GST3, and the fourth gate structure GST4. The second contact plug CT2 may be located in the second gate structure GST2, the third gate structure GST3, and the fourth gate structure GST4. The third contact plug CT3 may be located in the third gate structure GST3 and the fourth gate structure GST3. The fourth contact plug CT4 may be located in the fourth gate structure GST4. At least one of the first contact plugs CT1, the second contact plugs CT2, the third contact plugs CT3, and the fourth contact plugs CT4 may include at least one inflection portion.

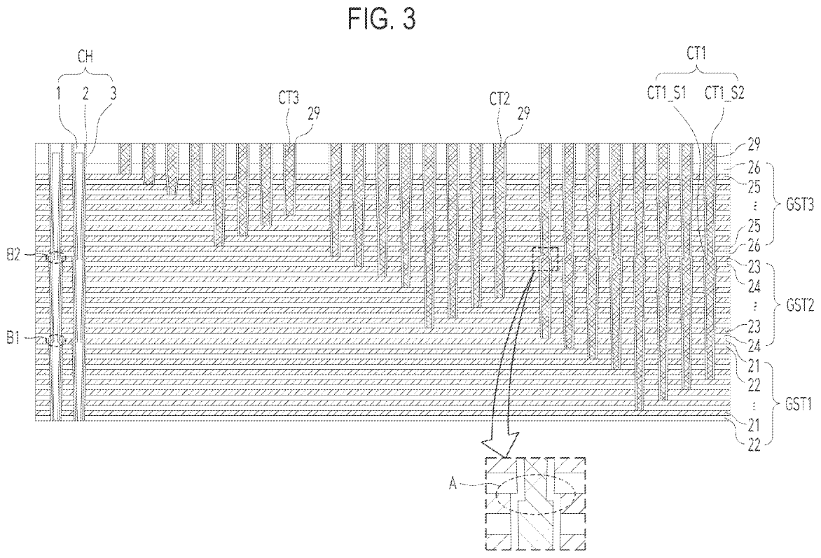

FIG. 3 is a diagram illustrating the structure of a semiconductor device in accordance with an embodiment.

Referring to the example of FIG. 3, the semiconductor device includes a first gate structure GST1, a second gate structure GST2, a third gate structure GST3, and a plurality of first contact plugs CT1. The semiconductor device further includes at least one channel structure CH, a plurality of second contact plugs CT2, a plurality of third contact plugs CT3, a plurality of insulating spacers 29, or any combination thereof. In one example, the first gate structure GST1 may be formed, after which the second gate structure GST2 may be formed on or over the first gate structure GST1 (for example, covering the first gate structure GST1), and the third gate structure GST3 may be formed on or over the second gate structure GST2 (for example, covering the second gate structure GST2).

The first gate structure GST1 includes a plurality of first conductive layers 21 that are alternately stacked with a plurality of first insulating layers 22. The second gate structure GST2 includes a plurality of second conductive layers 23 that are alternately stacked with a plurality of second insulating layers 24. The third gate structure GST3 includes a plurality of third conductive layers 25 that are alternately stacked with a plurality of third insulating layers 26.

The plurality of first contact plugs CT1 extend into the first gate structure GST1 through the third gate structure GST3 and the second gate structure GST2. Each of the plurality of first contact plugs CT1 may include an inflection portion A. The inflection portion A may be located at an interface between the second gate structure GST2 and the third gate structure GST3. The inflection portion A is located at an area where the first sub-contact plug CT1_S1 and the second sub-contact plug CT1_S2 are connected to or touch each other. Each of the plurality of first contact plugs CT1 may include a first sub-contact plug CT1_S1 and a second sub-contact plug CT1_S2. The first sub-contact plugs CT1_S1 may have different heights or lengths, and the second sub-contact plugs CT1_S2 may have substantially the same height or length. In this example, each of the first contact plugs CT1 is connected to a different one of the first conductive layers 21 in the example of FIG. 3, i.e., no two first contact plugs CT1 are connected to the same first conductive layer 21, and no two first conductive layers 21 are connected to the same first contact plug CT1.

The plurality of second contact plugs CT2 extend into the second gate structure GST2 through the third gate structure GST3. Each of the second contact plugs CT2 is connected to a different one of the second conductive layers 23 in the example of FIG. 3, i.e., no two first contact plugs CT1 are connected to the same first conductive layer 21, and no two first conductive layers 21 are connected to the same first contact plug CT1. The plurality of third contact plugs CT3 is located in the third gate structure GST3. Each of the third contact plugs CT3 is connected to a different one of the third conductive layers 25 in the example of FIG. 3.

The sidewalls of each first contact plug CT1, the sidewalls of each second contact plug CT2, and the sidewalls of each third contact plug CT3 are individually surrounded by an insulating spacer 29.

At least one channel structure CH is located in the first gate structure GST1, the second gate structure GST2, and the third gate structure GST3 in the example of FIG. 3. The at least one channel structure CH extends through the third gate structure GST3, the second gate structure GST2, and the first gate structure GST1, and may be connected between a source line and a bit line.

Each of the channel structures CH includes a channel layer 1. Each of the channel structures CH may further include a memory layer 2, an insulating core 3, or any combination thereof. The channel layer 1 may include a semiconductor material such as silicon or germanium. The memory layer 2 may include a tunneling layer, a data storage layer, a blocking layer, or any combination thereof. The data storage layer may include a floating gate, polysilicon, a charge trap material, a nitride, a variable resistance material, or the like, or any combination thereof.

Each channel structure CH may include at least one inflection portion B1 and/or B2. As an example, the channel structure CH may include a first inflection portion B1 located at an interface between the first gate structure GST1 and the second gate structure GST2, and a second inflection portion B2 may be located at an interface between the second gate structure GST2 and the third gate structure GST3. The semiconductor device may include electrode structures instead of the channel structures CH.

According to the structure described above, the first contact plugs CT1, the second contact plugs CT2, and the third contact plugs CT3 may be located in the first gate structures GST1, the second gate structures GST2, and the third gate structures GST3. At least one of the first contact plugs CT1, the second contact plugs CT2, and the third contact plugs CT3 may include the inflection portion A. As an example, the first contact plugs CT1 may include inflection portions A, and at least one of the second contact plugs CT2 and at least one of the third contact plugs CT3 may not include inflection portions A.

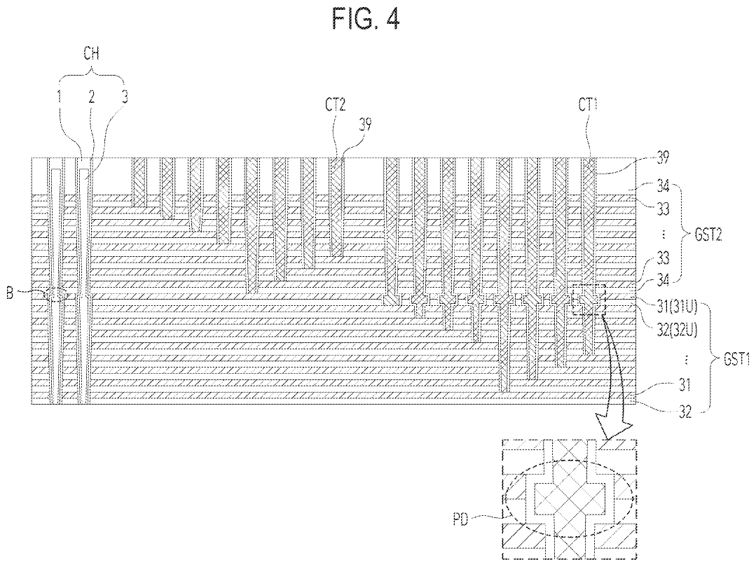

FIG. 4 is a diagram illustrating the structure of a semiconductor device in accordance with an embodiment.

Referring to FIG. 4, the semiconductor device includes a first gate structure GST1, a second gate structure GST2, and a plurality of first contact plugs CT1. The semiconductor device further includes at least one channel structure CH, a plurality of second contact plugs CT2, a plurality of insulating spacers 39, or any combination thereof.

The first gate structure GST1 includes a plurality of first conductive layers 31 that are alternately stacked with a plurality of first insulating layers 32. The second gate structure GST2 includes a plurality of second conductive layers 33 that are alternately stacked with a plurality of second insulating layers 34. Each of the channel structures CH may include a channel layer 1, a memory layer 2, an insulating core 3, or any combination thereof. Each of the channel structures CH may include an inflection portion B located at an interface between the first gate structure GST1 and the second gate structure GST2. The sidewalls of each first contact plug CT1 and the sidewalls of each second contact plug CT2 are individually surrounded by an insulating spacer 39.

The plurality of first contact plugs CT1 are located in the first gate structure GST1 and the second gate structure GST2. The first contact plugs CT1 extend through the second gate structure GST2, and each first contact plug CT1 is connected to a different one of the first conductive layers 31. The leftmost or rightmost first contact plug CT1 may not be connected to an uppermost first conductive layer 31U of the first conductive layers 31. As an example, the uppermost first conductive layer 31U may be connected to any one of the first contact plugs CT1. Alternatively, the uppermost first conductive layer 31U may not be electrically connected to any contact plug and may be a dummy gate line.

Each of the first contact plugs CT1 may include a pad PD. The pad PD may be located in the first gate structure GST1. The pad PD may be located on an upper surface of the first gate structure GST. As an example, the pad PD may overlap with, or exist in the same layer as, the uppermost first conductive layer 31U of the first conductive layers 31. Alternatively, the pad PD may overlap with the uppermost first conductive layer 31U of the first conductive layers 31 and an uppermost first insulating layer 32U of the first insulating layers 32. The pad PD may protrude or extend from sidewalls of the first contact plug CT1. For example, a width of the pad PD is wider than a width of the first contact plug CT1. The pad PD may be located at a level corresponding to the inflection portion B. For example, the level may refer to a distance from a bottom of the first gate structure GST1.

The plurality of second contact plugs CT2 is located in the second gate structure GST2. Each of the second contact plugs CT2 is connected to a different one of the second conductive layers 33 of the second gate structure GST2 in the example of FIG. 4. One of the second contact plugs CT2 may optionally be connected to the uppermost first conductive layer 31U. The second contact plugs CT2 may include or may not include pads.

According to the structure described above, each of the first contact plugs CT1 may include a pad PD. Each of the first contact plugs CT1 may extend into the first gate structure GST1 through one of the pads PD and may be connected to a different one of the first conductive layers 31, for example, no two first contact plugs CT1 may be connected to the same first conductive layer 31, and no two first conductive layers 31 are connected to the same first contact plug CT1. The pad PD may be directly connected to the first conductive layer 31.

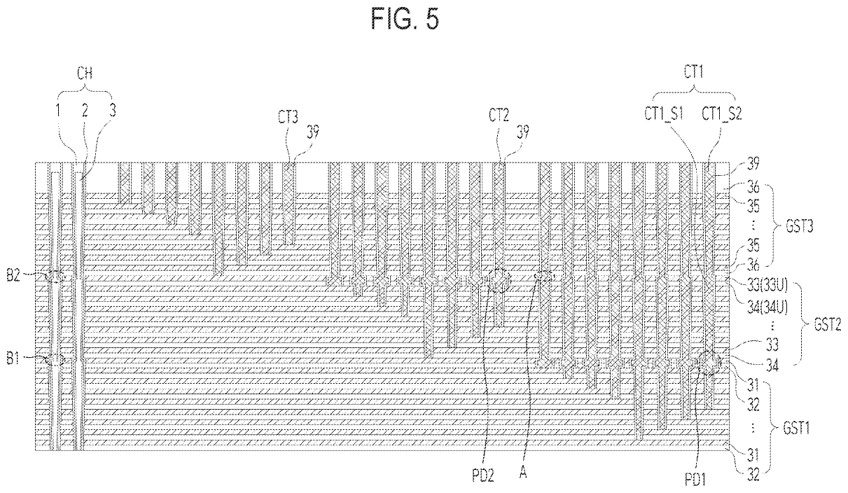

FIG. 5 is a diagram illustrating the structure of a semiconductor device in accordance with an embodiment.

Referring to the example of FIG. 5, the semiconductor device includes a first gate structure GST1, a second gate structure GST2, a third gate structure GST3, and a plurality of first contact plugs CT1. The semiconductor device further includes at least one channel structure CH, a plurality of second contact plugs CT2, a plurality of third contact plugs CT3, insulating spacers 39, or any combination thereof.

The first gate structure GST1 includes a plurality of first conductive layers 31 that are alternately stacked with a plurality of first insulating layers 32. The second gate structure GST2 includes a plurality of second conductive layers 33 that are alternately stacked with a plurality of second insulating layers 34. The third gate structure GST3 includes a plurality of third conductive layers 35 that are alternately stacked with a plurality of third insulating layers 36.

The first contact plugs CT1 are located in the first gate structure GST1, the second gate structure GST2, and the third gate structure GST3. Each of the first contact plugs CT1 includes a first sub-contact plug CT1_S1 and a second sub-contact plug CT1_S2 in the example of FIG. 5.

The plurality of first sub-contact plugs CT1_S1 are located in the first gate structure GST1 and the second gate structure GST2. Each first sub-contact plugs CT1_S1 includes a first pad PD1 located in the first gate structure GST1. The first pad PD1 may protrude or extend from sidewalls of the first sub-contact plug CT1_S1. Each first sub-contact plug CT1_S1 extends into the first gate structure GST1 through the first pad PD1 and is connected to a different one of the first conductive layers 31. The second sub-contact plug CT1_S2 is connected to the first sub-contact plug CT1_S1 and extends through the third gate structure GST3. An inflection portion A may be located at an interface between the first sub-contact plug CT1_S1 and the second sub-contact plug CT1_S2.

The plurality of second contact plugs CT2 are located in the second gate structure GST2 and the third gate structure GST3. Each of the second contact plugs CT2 includes a second pad PD2. The second pads PD2 are located at a different level than the first pads PD1. For example, the level may refer to a distance from a bottom or lowermost part of the first gate structure GST1. The second pads PD2 are located in the second gate structure GST2. The second pad PD2 may advantageously be located on an upper surface of the second gate structure GST2. As an example, the second pad PD2 may overlap with an uppermost second conductive layer 33U of the second conductive layers 33. Alternatively, the second pad PD2 may overlap with the uppermost second conductive layer 33U and an uppermost second insulating layer 34U. The second pad PD2 protrudes from sidewalls of one of the second contact plugs CT2. Each of the second contact plugs CT2 extends into the second gate structure GST2 through the second pad PD2 and is connected to a different one of the second conductive layers 33.

The third contact plugs CT3 are located in the third gate structure GST3. Each of the third contact plugs CT3 is connected to a different one of the third conductive layers 35. The third contact plug CT3 may optionally be connected to the uppermost second conductive layer 33U. The sidewalls of each first contact plug CT1, the sidewalls of each second contact plug CT2, and the sidewalls of each third contact plug CT3 are individually surrounded by an insulating spacer 39.

Each of the channel structures CH may include a channel layer 1, a memory layer 2, an insulating core 3, or any combination thereof. Each of the channel structures CH may include a first inflection portion B1 located at an interface between the first gate structure GST1 and the second gate structure GST2 and a second inflection portion B2 may be located at an interface between the second gate structure GST2 and the third gate structure GST3. The first inflection portion B1 may be located at a level corresponding to the level of the first pad PD1, and the second inflection portion B2 may be located at a level corresponding to the level of the second pad PD2.

According to the structure described above, each of the first contact plugs CT1 may include the first pad PD1 and the inflection portion A. Each first contact plug CT1 may extend into the first gate structure GST1 through the first pad PD1 and may be connected to a different one of the first conductive layers 31. The first pad PD1 may be directly connected to one of the first conductive layers 31. Each of the second contact plugs CT2 may include the second pad PD2. Each second contact plug CT2 may extend into the second gate structure GST2 through the second pad PD2 and may be connected to a different one of the second conductive layers 33. The second pad PD2 may be directly connected to one of the second conductive layers 33.

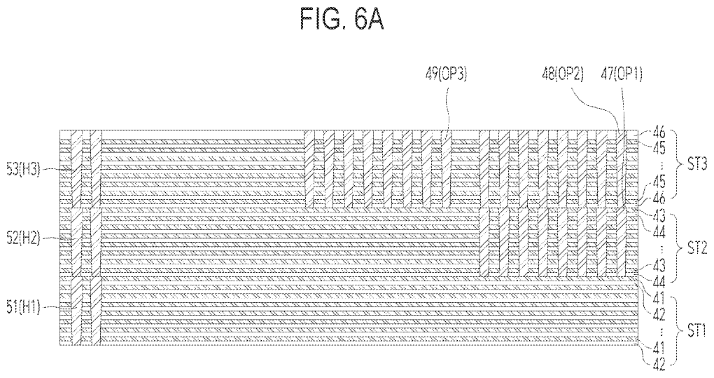

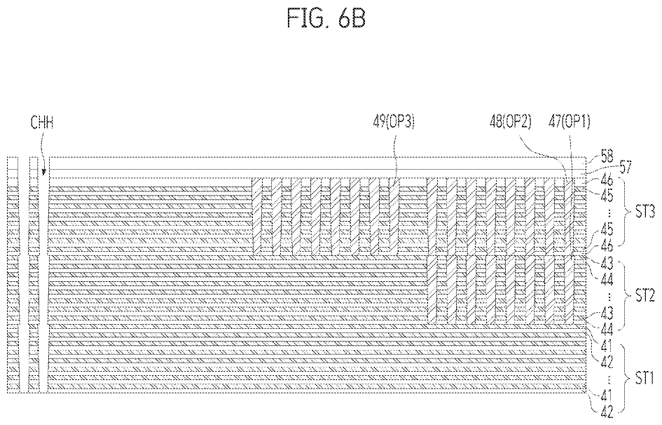

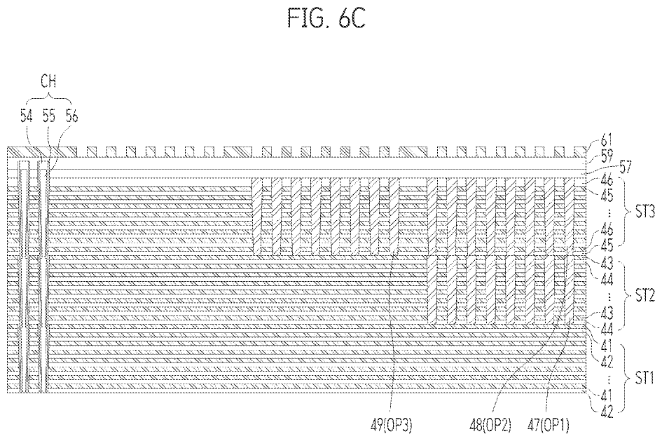

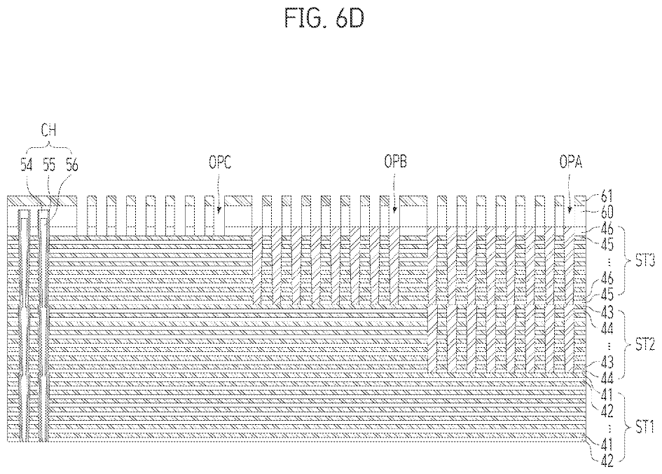

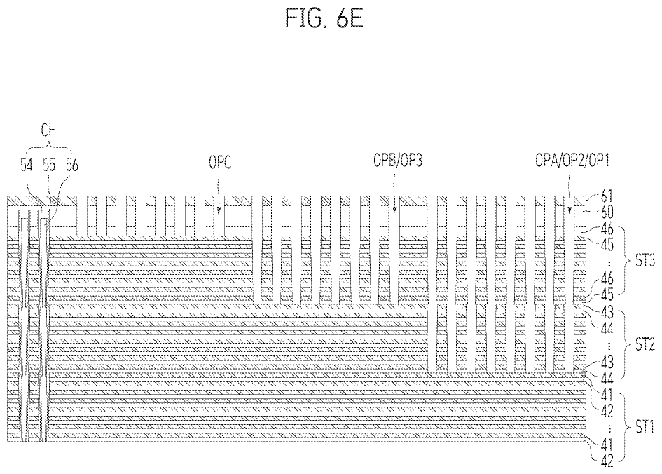

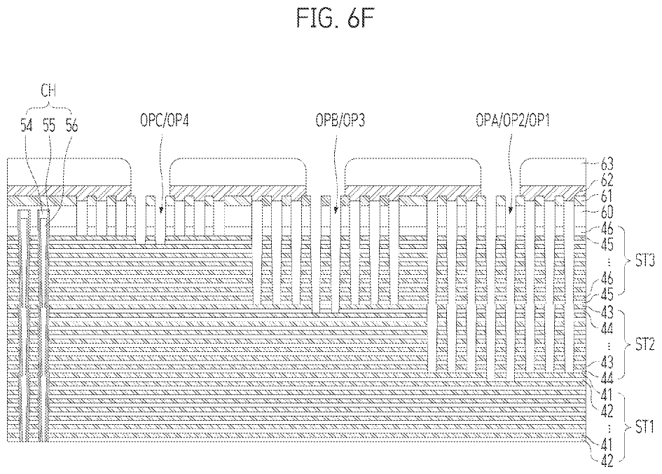

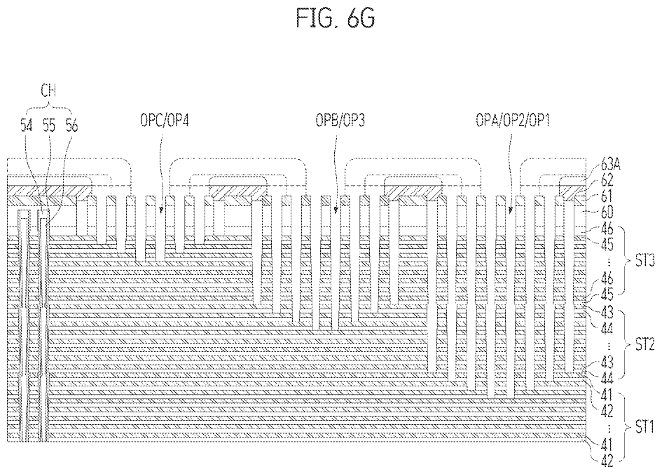

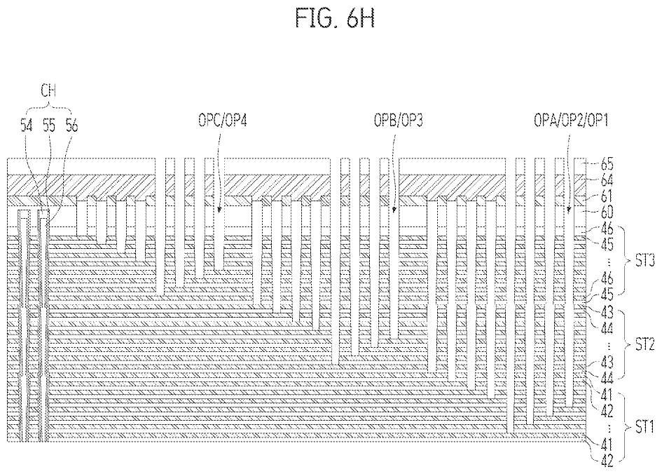

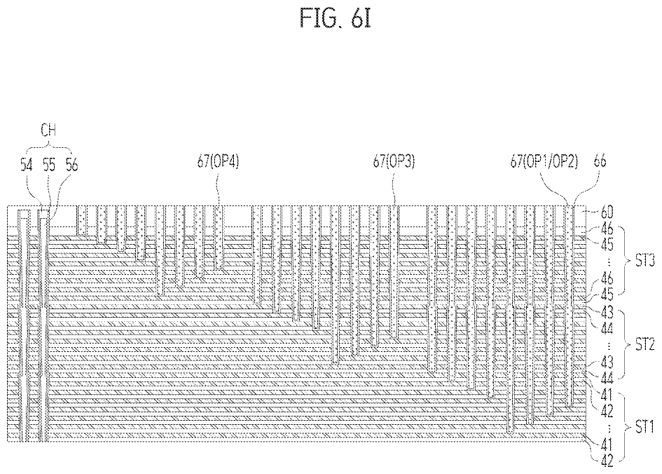

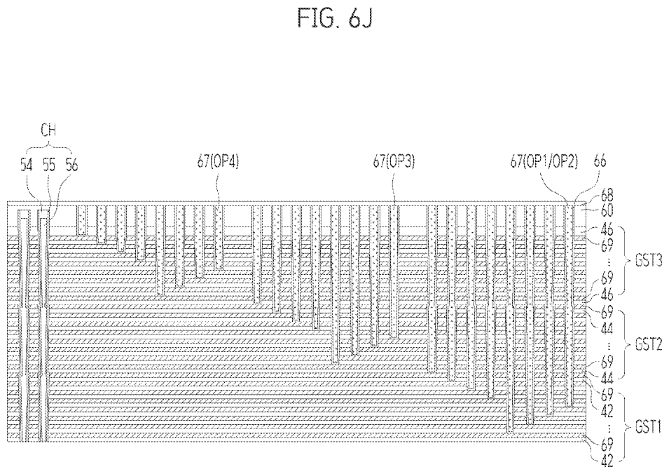

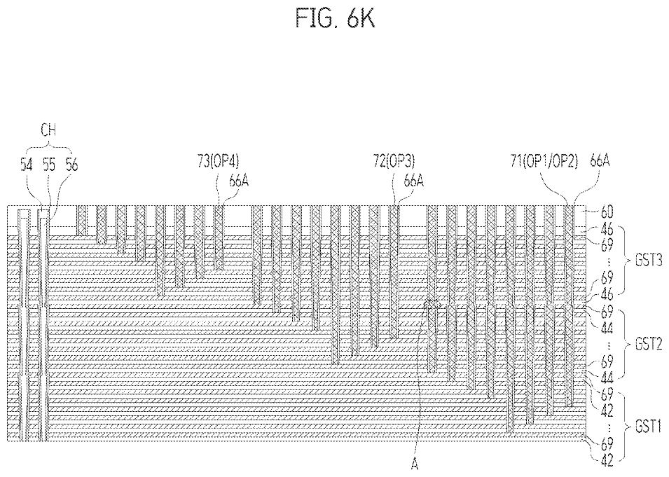

FIG. 6A through FIG. 6K are diagrams illustrating various views of a semiconductor device formed using a method of manufacturing a semiconductor device in accordance with an embodiment.

Referring to the example of FIG. 6A, a first stack ST1 including a plurality of first material layers 41 is formed. The first stack ST1 includes the plurality of first material layers 41 that are alternately stacked with a plurality of first insulating layers 42. The first material layers 41 may be used to form gate lines. Each of the first material layers 41 may comprise a material having a high etching selectivity with respect to the etching selectivity of the first insulating layers 42. As an example, each of the first material layers 41 may comprise a sacrificial material such as a nitride or a conductive material such as polysilicon or metal.

After the first stack ST1 is formed, a plurality of first holes H1 are formed in the first stack ST1, and a first sacrificial pattern 51 is formed in each of the first holes H1. As shown in the example of FIG. 6A, each first hole H1 is filled with a first sacrificial pattern 51. The first holes H1 may be used to form channel structures. Each of the first sacrificial patterns 51 may comprise a material having a high etching selectivity with respect to the etching selectivity of the first material layers 41 and the first insulating layers 42. As an example, each of the first sacrificial patterns 51 may comprise tungsten (W).

Subsequently, such as after the first stack ST1 is formed, a second stack ST2 including a plurality of second material layers 43 is formed. As an example, the second stack ST2 is formed by alternately stacking one of the plurality of second material layers 43 and one of a plurality of second insulating layers 44 on the first stack ST1, such as shown in FIG. 6A. The second material layers 43 may be used to form gate lines. Each of the second material layers 43 may comprise a material having a high etching selectivity with respect to the etching selectivity of the second insulating layers 44. As an example, each of the second material layers 43 may comprise a sacrificial material such as a nitride or a conductive material such as polysilicon or metal.

After the second stack ST2 is formed, first openings OP1 exposing the first stack ST1 are formed in the second stack ST2. The first openings OP1 may be used to form first contact plugs. A first sacrificial layer 47 is formed in each of the first openings OP1. As shown in the example of FIG. 6A, each first opening OP1 is filled with a first sacrificial layer 47. Each of the first sacrificial layers 47 may comprise a material having a high etching selectivity with respect to the etching selectivity of the second material layers 43 and the second insulating layers 44. As an example, each of the second sacrificial layers 47 may comprise tungsten (W).

Second holes H2 connected to, or aligning at least in part with, the first holes H1 are formed in the second stack ST2. A second sacrificial pattern 52 is formed in each of the second holes H2. As shown in the example of FIG. 6A, each second hole H2 is filled with a second sacrificial pattern 52. Each of the second sacrificial patterns 52 may comprise a material having a high etching selectivity with respect to the etching selectivity of the second material layers 43 and the second insulating layers 44. As an example, each of the second sacrificial patterns 52 may comprise tungsten (W). The second holes H2 may be formed when the first openings OP1 are formed, for example, the second holes H2 may be formed at the same time the first openings OP1 are formed, and the second sacrificial patterns 52 may be formed when the first sacrificial layers 47 are formed for example, the second sacrificial patterns 52 and the first sacrificial layers 47 may be formed at the same time (simultaneously). As an example, the first openings OP1 and the second holes H2 may be formed simultaneously in the second stack ST2 and may be filled with the same sacrificial material.

Subsequently, a third stack ST3 including a plurality of third material layers 45 is formed. As an example, the third stack ST3 may be formed by alternately stacking one of the plurality of third material layers 45 and one of the plurality of third insulating layers 46 on or over the second stack ST2. The third material layers 45 may be used to form gate lines. Each of the third material layers 45 may comprise a material having a high etching selectivity with respect to the etching selectivity of the third insulating layers 46. As an example, each of the third material layers 45 may comprise a sacrificial material such as a nitride or a conductive material such as polysilicon or metal.

Subsequently, second openings OP2 connected to, or aligning at least in part with, the first openings OP1 are formed in the third stack ST3. At an interface at an interface between the second stack ST2 and the third stack ST3, the first openings OP1 may have a width different from the width of the second openings OP2. Subsequently, a second sacrificial layer 48 is formed in each of the second openings OP2. As shown in the example of FIG. 6A, each second opening OP2 is filled with a second sacrificial layer 48. Each of the second sacrificial layers 48 may comprise a material having a high etching selectivity with respect to the etching selectivity of the third material layers 45 and the third insulating layers 46. As an example, each of the second sacrificial layers 48 may comprise tungsten (W).

Third openings OP3 exposing the second stack ST2 are formed in the third stack ST3. A third sacrificial layer 49 is formed in each of the third openings OP3. As shown in the example of FIG. 6A, each third opening OP3 is filled with a third sacrificial layer 49. Each of the third sacrificial layers 49 may comprise a material having a high etching selectivity with respect to the etching selectivity of the third material layers 45 and the third insulating layers 46. The third openings OP3 may be formed when the second openings OP2 are formed, for example, during the same process, and the third sacrificial layers 49 may be formed when the second sacrificial layers 48 are formed, for example, during the same process.

Third holes H3 connected to, or aligning at least in part with, the second holes H2 are formed in the third stack ST3. A third sacrificial pattern 53 is formed in each of the third holes H3. As shown in the example of FIG. 6A, each third hole H3 is filled with a third sacrificial pattern 53. Each of the third sacrificial patterns 53 may comprise a material having a high etching selectivity with respect to the etching selectivity of the third material layers 45 and the third insulating layers 46. The third holes H3 may be formed when the second openings OP2 and the third openings OP3 are formed. The third sacrificial patterns 53 may be formed when the second sacrificial layers 48 and the third sacrificial layers 49 are formed. As an example, the second openings OP2, the third openings OP3, and the third holes H3 may be formed simultaneously in the third stack ST3 and each may be filled with the same sacrificial material.

Referring to the example of FIG. 6B, a first buffer layer 57 is formed on or over the third stack ST3, and a second buffer layer 58 is formed on or over the first buffer layer 57. The second buffer layer 58 may include a material having a high etching selectivity with respect to the etching selectivity of the first buffer layer 57. As an example, the second buffer layer 58 may comprise a nitride, and the first buffer layer 57 may comprise an oxide.

Subsequently, the third sacrificial patterns 53 are exposed by etching the second buffer layer 58 and the first buffer layer 57, and the third sacrificial patterns 53, the second sacrificial patterns 52, and the first sacrificial patterns 51 are removed. As an example, the third sacrificial patterns 53, the second sacrificial patterns 52, and the first sacrificial patterns 51 may be selectively removed using a strip process. As a result, channel holes CHH are formed, and each channel hole CHH may have a shape in which the first hole H1, the second hole H2, and the third hole H3 are connected to each other.

Referring to FIG. 6C, a channel structure CH is formed in each channel hole CHH. As an example, a memory layer 55 is formed in each channel hole CHH, and a channel layer 54 and an insulating core 56 are formed in each memory layer 55. Subsequently, the second buffer layer 58 is removed. As an example, the second buffer layer 58 may be removed using a strip process. Subsequently, an insulating layer 59 may be formed on or over the first buffer layer 57. The insulating layer 59 may comprise an insulating material such as an oxide. Because the remaining first buffer layer 57 may be used as an interlayer insulating layer together with the insulating layer 59, the first buffer layer 57 and the insulating layer 59 will hereinafter be collectively referred to as an interlayer insulating layer 60.

Subsequently, a first mask layer 61 is formed on or over the interlayer insulating layer 60. For example, the first mask layer 61 exposes regions where first contact plugs, second contact plugs, and third contact plugs are to be formed. As an example, the first mask layer 61 may be a hard mask layer comprising polysilicon.

Referring to the example of FIG. 6D and FIG. 6A, openings OPA, OPB, and OPC are formed by etching the interlayer insulating layer 60 using the first mask layer 61 as an etching barrier. The openings OPA expose the second sacrificial layers 48 and connect to the second openings OP2. The openings OPB expose the third sacrificial layers 49 and connect to the third openings OP3. The openings OPC expose the third stack ST3.

Referring to FIG. 6E and FIG. 6A, the first sacrificial layers 47 and the second sacrificial layers 48 are removed through the openings OPA. Through this process, the first openings OP1 and the second openings OP2 are reopened. The third sacrificial layers 49 are removed through the openings OPB. Through this process, the third openings OP3 may be reopened.

Referring to FIG. 6F, a second mask layer 62 is formed on or over the first mask layer 61. The openings OPA, OPB, and OPC may be sealed by the second mask layer 62. As an example, the second mask layer 62 may be a hard mask layer including carbon (C). Subsequently, a first mask pattern 63 is formed on the second mask layer 62. The first mask pattern 63 may expose at least one of the openings OPA. The first mask pattern 63 may expose at least one of the openings OPB. The first mask pattern 63 may expose at least one of the openings OPC. The first mask pattern 63 may comprise a photoresist.

Subsequently, the second mask layer 62 is etched using the first mask pattern 63 as an etching barrier in the example of FIG. 6F. Through this process, at least one opening OPA is exposed, and the first opening OP1 and the second opening OP2 connected to the opening OPA are exposed. At least one opening OPB is exposed, and the third opening OP3 connected to the opening OPB is exposed in this example. At least one opening OPC is exposed, and the third stack ST3 is exposed through the opening OPC.

Subsequently, the first openings OP1 are extended into the first stack ST1. As an example, the first stack ST1 exposed through the openings OPA, the second openings OP2, and the first openings OP1 are etched using the first mask pattern 63 as an etching barrier. The third openings OP3 are extended into the second stack ST2. As an example, the second stack ST2 exposed through the openings OPB and the third openings OP3 are etched using the first mask pattern 63 as an etching barrier. Fourth openings OP4 are formed in the third stack ST3. As an example, the third stack ST3 exposed through the openings OPC may be etched using the first mask pattern 63 as an etching barrier.

Referring to FIG. 6G, after the first mask pattern 63 is shrunken, for example, reduced in size or at least partially removed, the second mask layer 62 may be etched using the shrunken first mask pattern 63A as an etching barrier. Through this process, the quantity of first openings OP1 exposed through the first mask pattern 63A is increased. Subsequently, the first openings OP1 are extended into the first stack ST1 by etching the first stack ST1 using the first mask pattern 63A as an etching barrier. The first openings OP1 exposed initially are additionally extended in a state in which the first openings OP1 are already extended and may thus have a greater depth than the first openings OP1 exposed later.

By shrinking, or reducing in size, the first mask pattern 63, the quantity of third openings OP3 exposed through the first mask pattern 63A is increased. Subsequently, the third openings OP3 are extended into the second stack ST2 by etching the second stack ST2 using the first mask pattern 63A as an etching barrier. The third openings OP3 exposed initially are additionally extended in a state in which the third openings OP3 are already extended and may thus have a greater depth than the third openings OP3 exposed later.

By shrinking the first mask pattern 63, the number of openings OPC exposed through the first mask pattern 63A is increased. Subsequently, the fourth openings OP4 are extended into the third stack ST3 by etching the third stack ST3 using the first mask pattern 63A as an etching barrier. The fourth openings OP4 exposed initially are additionally extended in a state in which the fourth openings OP4 are already extended and may thus have a greater depth than the fourth openings OP3 exposed later.

When the first openings OP1 are extended into the first stack ST1, the third openings OP3 may be extended into the second stack ST2. When the first openings OP1 are extended into the first stack ST1, the fourth openings OP4 may be formed in the third stack ST3. As an example, the first openings OP1, the third openings OP3, and the fourth openings OP4 may be extended simultaneously.

The process of shrinking the first mask pattern 63A and etching the first to third stacks ST1 to ST3 may be repeated. Through this repetition, the first openings OP1, second openings OP2, and third openings OP3 may be extended at various depths. The first material layers 41 may be exposed through the first openings OP1, the second material layers 43 may be exposed through the third openings OP3, and the third material layers 45 may be exposed through the fourth openings OP4.

Referring to FIG. 6H, the first openings OP1, the second openings OP2, and the third openings OP3 may be additionally extended. As an example, the first mask pattern 63A and the second mask layer 62 are removed, and a third mask layer 64 and a second mask pattern 65 are then formed on or over the first mask layer 61. The third mask layer 64 may be a hard mask layer including carbon (C). The second mask pattern 65 may include a photoresist.

The second mask pattern 65 exposes at least one of the first openings OP1. As an example, among 2n first openings OP1, the first openings OP1 located closer to the center of the plurality of first openings OP1 may have a greater depth, and the first openings OP1 located closer to an outer side of the plurality of first openings OP1 may have a smaller depth, where n is an integer having a value of 1 or more. The second mask pattern 65 may expose n first openings OP1 of the first openings OP1. Subsequently, the n first openings OP1 may be extended into the first stack ST1 by etching n first material layers 41 using the second mask pattern 65 as an etching barrier. Through this process, the first openings OP1 may expose the various different first material layers 41.

For example, in a process of etching the first stack ST1 in order to extend the first openings OP1, inner walls of the second openings OP2 and the first openings OP1 may be etched. As a result, a shape of some of inflection portions located at an interface between the first openings OP1 and the second openings OP2 may be changed. As an example, the inflection portion may disappear at a connection portion at an interface between the first opening OP1 and the second opening OP2. Alternatively, a difference in width between the first opening OP1 and the second opening OP2 at the connection portion may be reduced or decreased, and a change in gradient of the inflection portion may be alleviated or reduced.

The second mask pattern 65 exposes at least one of the third openings OP3. As an example, among 2n third openings OP3, the third openings OP3 located closer to the center of the plurality of third openings OP3 may have a greater depth, and the third openings OP3 located closer to an outer side of the plurality of third openings OP3 may have a smaller depth. The second mask pattern 65 may expose n third openings OP3 of the third openings OP3. Subsequently, the n third openings OP3 may be extended into the second stack ST2 by etching n second material layers 43 using the second mask pattern 65 as an etching barrier. Through this process, the third openings OP3 may expose the various different second material layers 43.

The second mask pattern 65 exposes at least one of the fourth openings OP4. As an example, among 2n fourth openings OP4, the fourth openings OP4 located closer to the center of the plurality of fourth openings OP4 may have a greater depth, and the fourth openings OP4 located closer to an outer side of the plurality of fourth openings OP4 may have a smaller depth. The second mask pattern 65 may expose n fourth openings OP4 of the fourth openings OP4. Subsequently, the n fourth openings OP4 may be extended into the third stack ST3 by etching n third material layers 45 using the second mask pattern 65 as an etching barrier. Through this process, the fourth openings OP4 may expose the various different third material layers 45.

When the first openings OP1 are additionally extended, the third openings OP3 may be additionally extended. When the first openings OP1 are additionally extended, the fourth openings OP4 may be additionally extended. As an example, the first openings OP1, the third openings OP3, and the fourth openings OP4 may be additionally extended simultaneously.

Referring to FIG. 6I, the second mask pattern 65, the third mask layer 64, and the first mask layer 61 are removed. Subsequently, insulating liners 66 are formed in the first openings OP1, the second openings OP2, the third openings OP3, and the fourth openings OP4. Each of the insulating liners 66 may comprise an insulating material such as an oxide. Subsequently, fourth sacrificial layers 67 may be formed in the first openings OP1, the second openings OP2, the third openings OP3, and the fourth openings OP4. As an example, liner layers are formed along inner surfaces of the first openings OP1, the second openings OP2, the third openings OP3, and the fourth openings OP4, and fourth sacrificial material layers are then formed, i.e., the fourth sacrificial material layers fill the first openings OP1, the second openings OP2, the third openings OP3, and the fourth openings OP4. Subsequently, the insulating liners 66 and the fourth sacrificial layers 67 may be formed by planarizing the fourth sacrificial material layers and the liner layers until the interlayer insulating layer 60 is exposed. The planarization process may be performed as a chemical mechanical polishing (CMP) process.

Referring to FIG. 6J, an insulating layer 68 is formed. The first material layers 41, the second material layers 43, and the third material layers 45 are replaced with fourth material layers 69. As an example, after slits are formed in the first stack ST1, the second stack ST2, and the third stack ST3, the first material layers 41, the second material layers 43, and the third material layers 45 are removed through the slits. Subsequently, the fourth material layers 69 are formed in regions where the first material layers 41, the second material layers 43, and the third material layers 45 were removed. The first material layers 41, the second material layers 43, and the third material layers 45 may be etched using a wet etching process. Each of the fourth material layers 69 may comprise a metal such as tungsten (W) or molybdenum (Mo). When the first material layers 41, the second material layers 43, and the third material layers 45 each include a conductive material, the above replacement process may be omitted, and the first material layers 41, the second material layers 43, and the third material layers 45 may be used as the fourth material layers 69. Alternatively, instead of removing the first material layers 41, the second material layers 43, and the third material layers 45, a silicidation process or the like for reducing resistances of the first material layers 41, the second material layers 43, and the third material layers 45 may be performed.

Through this process, a first gate structure GST1 is formed including the plurality of fourth material layers 69 that are alternately stacked with the plurality of first insulating layers 42. The fourth material layers 69 of the first gate structure GST1 may be first conductive layers. A second gate structure GST2 is formed including the fourth material layers 69 that are alternately stacked with the second insulating layers 44. The fourth material layers 69 of the second gate structure GST2 may be second conductive layers. A third gate structure GST3 is formed including the fourth material layers 69 that are alternately stacked with the third insulating layers 46. The fourth material layers 69 of the third gate structure GST3 may be third conductive layers.

Referring to FIG. 6K, the fourth sacrificial layers 67 are exposed by removing the insulating layer 68. As an example, the insulating layer 68 are planarized using a CMP process until the fourth sacrificial layers 67 are exposed. Subsequently, the fourth sacrificial layers 67 are removed. As an example, the fourth sacrificial layers 67 may be selectively removed using a strip process.

Subsequently, insulating spacers 66A are formed. As an example, the insulating liners 66 may be etched using a blanket etching process. The fourth material layers 69 are exposed by etching portions of the insulating liners 66 formed on bottom surfaces of the first openings OP1, the third openings OP3, and the fourth openings OP4. Portions of the insulating liners 66 remaining on inner walls of the first openings OP1, the second openings OP2, the third openings OP3, and the fourth openings OP4 become the insulating spacers 66A.

Subsequently, first contact plugs 71 are formed in the first openings OP1 and the second openings OP2. Each of the first contact plugs 71 is electrically connected to a different one of the fourth material layers 69 of the first gate structure GST1. Each of the first contact plugs 71 may comprise a metal such as tungsten (W) or molybdenum (Mo). As an example, each of the first contact plugs 71 may be formed by forming a metal barrier layer in one of the first openings OP1 and the second openings OP2 and then forming metal gap fill layers. Each of the first contact plugs 71 has a shape similar to a shape of the outer perimeter of the first openings OP1 and the second openings OP2. The first contact plugs 71 may include inflection portions A located at an interface between the second gate structure GST2 and the third gate structure GST3.

Second contact plugs 72 are formed in the third openings OP3. Each of the second contact plugs 72 is electrically connected to a different one of the fourth material layers 69 of the second gate structure GST2. Each of the second contact plugs 72 may comprise a metal such as tungsten (W) or molybdenum (Mo). As an example, each of the second contact plugs 72 may be formed by forming a metal barrier layer in one of the third openings OP3 and then forming metal gap fill layers. The third openings OP3 may not include inflection portions.

Third contact plugs 73 are formed in the fourth openings OP4. Each of the third contact plugs 73 is electrically connected to a different one of the fourth material layers 69 of the third gate structure GST3. Each of the third contact plugs 73 may comprise a metal such as tungsten (W) or molybdenum (Mo). As an example, each of the third contact plugs 73 may be formed by forming a metal barrier layer in one of the fourth openings OP4 and then forming metal gap fill layers. The fourth openings OP4 may not include inflection portions.

When the first contact plugs 71 are formed, the second contact plugs 72 may be formed. When the first contact plugs 71 are formed, the third contact plugs 73 may be formed. The first contact plugs 71, the second contact plugs 72, and the third contact plugs 73 may be formed simultaneously.

According to the manufacturing method described above, the first contact plugs 71, the second contact plugs 72, and the third contact plugs 73 are formed in the first gate structures GST1, the second gate structures GST2, and the third gate structures GST3. The first contact plugs 71 are formed in the first openings OP1 and the second openings OP2, and may include the inflection portions located at portions where the first openings OP1 and the second openings OP2 are connected to each other. Each second contact plugs 72 is formed in a different third opening OP3, and may not include an inflection portion. Each third contact plug 73 is formed in a different fourth opening OP4, and may not include an inflection portion.

By repeatedly performing the shrinking of the mask pattern and the etching process, the first openings OP1 may advantageously extend into the first gate structure GST1 at different depths. The third openings OP3 may extend into the third gate structure GST3 at different depths. When the first openings OP1 are extended, the third openings OP3 may be extended and the fourth openings OP4 may be formed or extended.

Each of the first contact plugs 71, the second contact plugs 72, and the third contact plugs 73 may be connected to a different one of the fourth material layers 69, without patterning the first stacks ST1, the second stacks ST2, and the third stacks ST3 in a stair shape. Accordingly, manufacturing cost may be reduced, and wafer warpage may be improved.

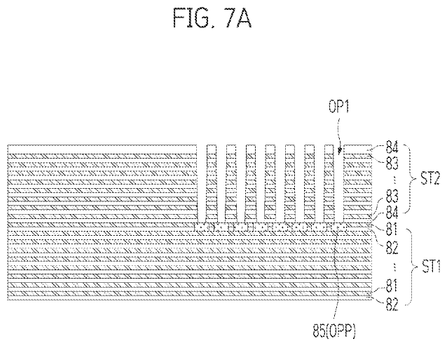

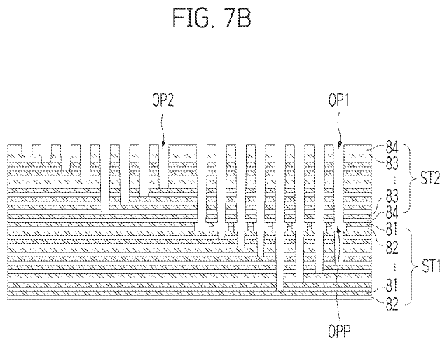

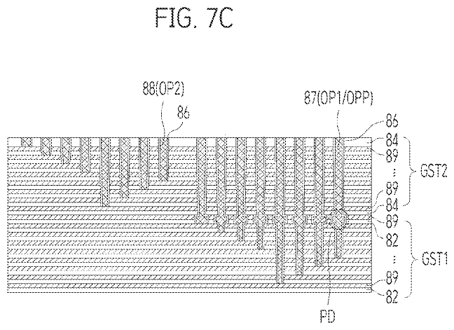

FIG. 7A through FIG. 7C are diagrams illustrating various views of a semiconductor device formed using a method of manufacturing a semiconductor device in accordance with an embodiment.

Referring to FIG. 7A, a first stack ST1 including a plurality of first material layers 81 is formed. The first stack ST1 may include the plurality of first material layers 81 that are alternately stacked with a plurality of first insulating layers 82.

Subsequently, a plurality of pad sacrificial layers 85 are formed in the first stack ST1, such as shown in FIG. 7A. The pad sacrificial layers 85 may be formed at locations where first contact plugs are to be formed in a subsequent process. As an example, pad openings OPP may be formed by etching the first stack ST1, and thereafter the pad sacrificial layers 85 may be formed in the pad openings OPP. Each of the pad sacrificial layers 85 may comprise a material having a high etching selectivity with respect to the etching selectivity of the first material layers 81 and the first insulating layers 82. As an example, each of the pad sacrificial layers 85 may comprise tungsten (W).

Subsequently, a second stack ST2 including a plurality of second material layers 83 is formed. The second stack ST2 may include the second material layers 83 that are alternately stacked with a plurality of second insulating layers 84, such as shown in FIG. 7A. Subsequently, a plurality of first openings OP1 exposing the pad sacrificial layers 85 are formed in the second stack ST2. The first openings OP1 may be formed by etching the second stack ST2 using the pad sacrificial layers 85 as an etching barrier.

Referring to FIG. 7B, the pad sacrificial layers 85 are removed through the first openings OP1. Through this process, the pad openings OPP may be reopened. The pad openings OPP may have a greater width than the first openings OP1. At an area where each pad opening OPP is connected to a corresponding first opening OP1, a width of the pad opening OPP may be greater than a width of the first opening OP1.

Subsequently, the first openings OP1 are extended into the first stack ST1 through the pad openings OPP. The pad openings OPP may have a greater width than extended portions of the first openings OP1. Each of the first material layers 81 is exposed through a different one of the first openings OP1. As an example, a mask pattern exposing at least one of the first openings OP1 may be formed, and the first stack ST1 may be etched using the mask pattern as an etching barrier. By repeatedly performing a process of shrinking or reducing in size the mask pattern and etching the first stack ST1, the first openings OP1 may be extended to different depths within the first stack ST1.

Second openings OP2 are formed in the second stack ST2. When the first openings OP1 are extended into the first stack ST1, the second openings OP2 may be formed. Each of the second material layers 83 may be exposed through a different one of the second openings OP2.

Referring to FIG. 7C, the first material layers 81 and the second material layers 83 may be replaced with fourth material layers 89. Through this process, a first gate structure GST1 is formed including the fourth material layers 89 that are alternately stacked with the first insulating layers 82. A second gate structure GST2 is formed including the fourth material layers 89 that are alternately stacked with the second insulating layers 84.

Insulating spacers 86 and first contact plugs 87 are formed in the first openings OP1 and the pad openings OPP. Each of the first contact plugs 87 may include a pad PD located in the pad opening OPP. The pad PD may protrude from sidewalls of the first contact plug 87. Each of the first contact plugs 87 is electrically connected to a different one of the fourth material layers 89 of the first gate structure GST1 as shown in the example of FIG. 7C.

Insulating spacers 86 and second contact plugs 88 may be formed in the second openings OP2. The second contact plugs 88 may not include pads. Each of the second contact plugs 88 is electrically connected to a different one of the fourth material layers 89 of the second gate structure GST2 as shown in the example of FIG. 7C.

According to the manufacturing method described above, the first openings OP1 may be formed at a uniform depth using the pad sacrificial layer 85 as an etching barrier. By extending the first openings OP1 through the pad openings OPP, the first openings OP1 may be extended to a desired depth.

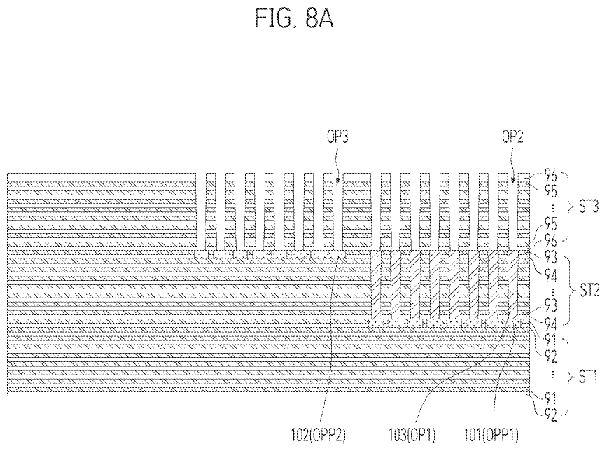

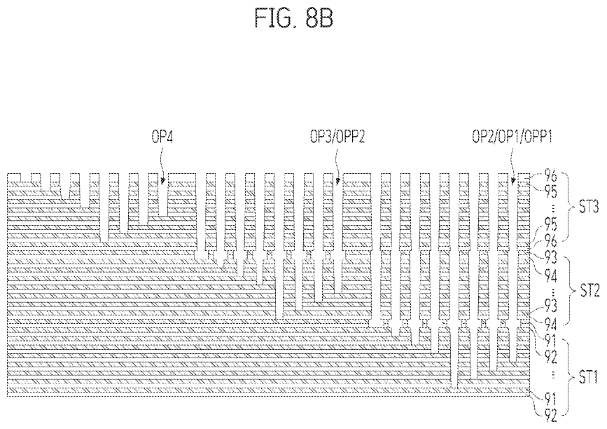

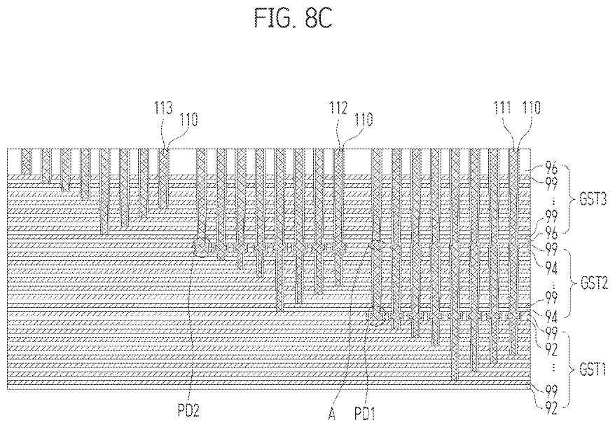

FIG. 8A through FIG. 8C are diagrams illustrating various views of a semiconductor device formed using a method of manufacturing a semiconductor device in accordance with an embodiment.

Referring to FIG. 8A, a first stack ST1 including a plurality of first material layers 91 is formed. The first stack ST1 includes the first material layers 91 that are alternately stacked with first insulating layers 92. Subsequently, first pad sacrificial layers 101 are formed in the first stack ST1. The first pad sacrificial layers 101 may be formed at locations where first contact plugs are to be formed in a subsequent process.

Subsequently, a second stack ST2 including a plurality of second material layers 93 is formed. The second stack ST2 includes the second material layers 93 that are alternately stacked with second insulating layers 94. Subsequently, a plurality of first openings OP1. each exposing a different one of the first pad sacrificial layers 101, is formed in the second stack ST2, and a plurality of first sacrificial layers 103 may then be formed in the first openings OP1.

A plurality of second pad sacrificial layers 102 is formed in the second stack ST2. The second pad sacrificial layers 102 may be formed at locations where second contact plugs are to be formed in a subsequent process. The second pad sacrificial layers 102 may be formed after the first openings OP1 are formed or may be formed before the first openings OP1 are formed.

Subsequently, a third stack ST3 including a plurality of third material layers 95 is formed. The third stack ST3 includes alternately stacked third material layers 95 and third insulating layers 96. Subsequently, second openings OP2 exposing the first sacrificial layers 103 are formed in the third stack ST3. Third openings OP3 exposing the second pad sacrificial layers 102 are formed in the third stack ST3. When the second openings OP2 are formed, the third openings OP3 may also be formed.

Referring to FIG. 8B, the first openings OP1 and first pad openings OPP1 are reopened by removing the first sacrificial layers 103 and the first pad sacrificial layers 101 through the second openings OP2. Second pad openings OPP2 are reopened by removing the second pad sacrificial layers 102 through the third openings OP3.

Subsequently, the first openings OP1 are extended into the first stack ST1 through the first pad openings OPP1. The third openings OP3 are extended into the second stack ST2 through the second pad openings OPP2. Fourth openings OP4 are formed in the third stack ST3.

When the first openings OP1 are extended into the first stack ST1, the third openings OP3 may be extended into the second stack ST2. When the first openings OP1 are extended, the fourth openings OP4 may be formed. When the first openings OP1 and the third openings OP3 are extended, the fourth openings OP4 may be formed or extended.

Referring to FIG. 8C, the first material layers 91, the second material layers 93, and the third material layers 95 are replaced with fourth material layers 99. Through this process, a first gate structure GST1 is formed including the fourth material layers 99 that are alternately stacked with the first insulating layers 92. A second gate structure GST2 is formed including the fourth material layers 99 that are alternately stacked with the second insulating layers 94. A third gate structure GST3 is formed including the fourth material layers 99 that are alternately stacked with the third insulating layers 96.

Insulating spacers 110 and first contact plugs 111 are formed in each of the first openings OP1, the second openings OP2, and the first pad openings OPP1. Each of the first contact plugs 111 includes a first pad PD1 and an inflection portion A in this example. The first pad PD1 is located in the first pad opening OPP1 and may protrude from sidewalls of the first contact plug 111. Each of the inflection portions A is located at an interface between the second gate structure GST2 and the third gate structure GST3. Each of the first contact plugs 111 is electrically connected to a different one of the fourth material layers 99 of the first gate structure GST1.

An insulating spacer 110 and a second contact plug 112 are formed in each of the third openings OP3. Each of the second contact plugs 112 includes a second pad PD2 and may not include an inflection portion. One second pad PD2 is located in each second pad opening OPP2 and may protrude from sidewalls of the corresponding second contact plug 112. Each of the second contact plugs 112 is electrically connected to a different one of the fourth material layers 99 of the second gate structure GST2.

An insulating spacer 110 and a third contact plug 113 are formed in each of the fourth openings OP4. Each of the third contact plugs 113 may not include a pad and may not include an inflection portion. Each of the third contact plugs 113 is electrically connected to a different one of the fourth material layers 99 of the third gate structure GST3.

According to the manufacturing method described above, the first openings OP1 may be extended through the first pad openings OPP1, and at the same time, the third openings OP3 may be extended through the second pad openings OPP2. The first openings OP1 and the third openings OP3 may be extended at the same time as the fourth openings OP4 are formed or extended.

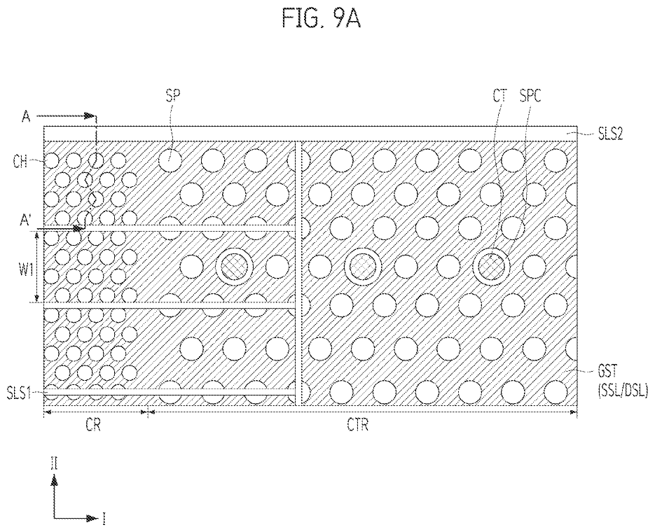

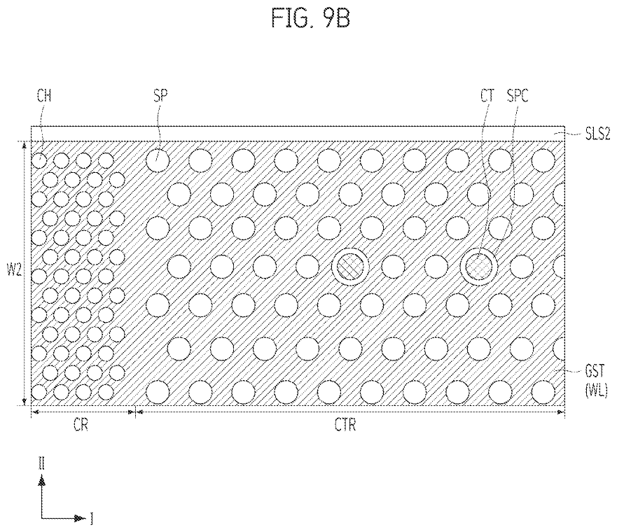

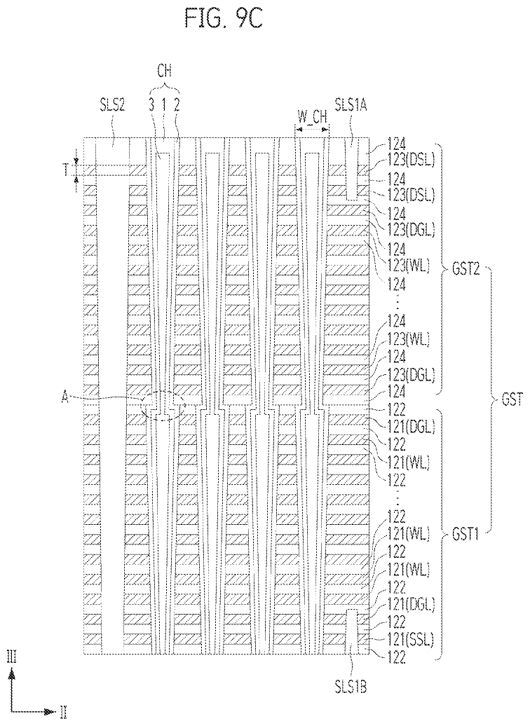

FIG. 9A through 9C are diagrams illustrating the structure of a semiconductor device in accordance with an embodiment. FIG. 9A and FIG. 9B are plan views, and FIG. 9C is a cross-sectional view taken through line A-A′ of FIG. 9A.

Referring to FIG. 9A through FIG. 9C, the semiconductor device includes a gate structure GST, a channel structure CH, and contact plugs CT. The semiconductor device may further include at least one of an insulating spacer SPC, a first slit structure SLS1, and a second slit structure SLS2.

The gate structure GST includes a first gate structure GST1 and a second gate structure GST2. The first gate structure GST1 includes first conductive layers 121 that are alternately stacked with first insulating layers 122. The second gate structure GST2 includes second conductive layers 123 that are alternately stacked with second insulating layers 124. The first conductive layers 121 and the second conductive layers 123 may be gate lines such as word lines WL, select lines, or dummy gate lines DGL. The select line may be a drain select line DSL or a source select line SSL. The dummy gate line DGL may be a dummy word line, a dummy source select line, or a dummy drain select line.

The dummy gate line DGL may be located between the source select line SSL and the word line WL or may be located between the drain select line DSL and the word line WL. The dummy gate line DGL may be located at an interface between the first gate structure GST1 and the second gate structure GST2. As an example, the gate structure GST may include at least one source select line SSL, at least one dummy gate line DGL, word lines WL, at least one dummy gate line DGL, word lines WL, at least one dummy gate line DGL, and at least one drain select line DSL that are consecutively stacked.

The gate lines may have substantially the same thickness or have different thicknesses. As an example, at least one of the source select line SSL, the drain select line DSL, and the dummy gate line DGL may have a greater thickness than the thickness of the word line WL and may also have a smaller resistance than the resistance of the word line WL.

The first slit structure SLS1 may insulate select lines located at the same level as each other. The first slit structure SLS1 may have a shape in which a line extending in a first direction I and a line extending in a second direction II intersecting the first direction I intersect each other. The second direction II may be perpendicular to the first direction. The first slit structure SLS1 may include at least one of a first slit structure SLS1A for isolating the drain select lines DSL from each other and a first slit structure SLS1B for isolating the source select lines SSL from each other. The first slit structure SLS1 may be located at a height at which the first slit structure SLS1 extends through the select line and does not extend through the word lines WL. The first slit structure SLS1A may be located at a height at which the first slit structure SLS1A extends through the drain select lines DSL and may be located above the word lines WL. The first slit structure SLS1B may be located a depth at which the first slit structure SLS1B extends through the source select line SSL and may be located below the word lines WL.

The second slit structure SLS2 may be used to divide the gate structure GST in memory block units. The second slit structure SLS2 may extend in the first direction I. The second slit structure SLS2 may have a greater height than the first slit structure SLS1. The second slit structure SLS2 may have a height where the second slit structure SLS2 extends through the source select line SSL, the word lines WL, and the drain select line DSL. The second slit structure SLS2 may be an isolation insulating layer. Alternatively, the second slit structure SLS2 may include a source contact structure electrically connected to a source structure and an insulating spacer surrounding sidewalls of the source contact structure.

In a plane extending between the first direction I and the second direction II but not in the third direction III, the drain select line DSL, the source select line SSL, and the word line WL may have the same shape or have different shapes. The word line WL, the drain select line DSL, and the source select line SSL may extend in the first direction I. The drain select line DSL or the source select line SSL may have a first width W1 in the second direction II. The word line WL may have a second width W2 in the second direction II. The first width W1 may be identified by the distance between consecutive first slit structures SLS1 and may be smaller than the second width W2. A gate line having a smaller width may have a greater resistance than a gate line having a larger width. As an example, at least one of the drain select lines DSL and the source select lines SSL may have a greater resistance than the resistance of the word line WL.

The channel structure CH extends in a third direction III through a cell region CR of the gate structure GST. The third direction III is a direction perpendicular to the plane located between the first direction I and the second direction II. The channel structure CH may include at least one of a channel layer 1, a memory layer 2, and an insulating core 3.

The channel structure CH may have a uniform width or have different widths that vary depending on the level or height of the channel structure CH in direction III. As an example, the channel structure CH may have a cross section with a tapered shape or a cross section with a bowing shape. The channel structure CH may have at least one inflection portion A on its sidewall. A drain select transistor may be located in a region where the channel structure CH and the drain select line DSL intersect each other, a memory cell may be located in a region where the channel structure CH and the word line WL intersect each other, and a source select transistor may be located in a region where the channel structure CH and the source select line SSL intersect each other. A dummy source select transistor, a dummy drain select transistor, or a dummy memory cell may be located in a region where the channel structure CH and the dummy gate line DGL intersect each other.

A support SP may extend in the third direction III through a contact region CTR of the gate structure GST. The support SP may have a structure that is substantially the same as or different from that of the channel structure CH. As an example, the support SP may include at least one of a dummy channel layer, a dummy memory layer, and a dummy insulating core. The support SP may include an insulating layer, a conductive layer, and the like.

The contact plugs CT may extend in the third direction III through the contact region CTR of the gate structure GST. The sidewalls of each contact plug CT are individually surrounded by an insulating spacer SPC. The contact plugs CT may extend into the gate structure GST at different depths and are electrically connected to a different one of the conductive layers 121. The contact plugs CT may be electrically connected to the gate lines, respectively.

Locations of the contact plugs CT may be determined in consideration of resistances of the gate lines. A contact plug CT connected to a gate line having a relatively greater resistance may be located closer to the cell region CR than the distance to a contact plug CT connected to a gate line having a relatively smaller resistance. As an example, the contact plug CT connected to the gate line having a relatively greater resistance may be located closer to the channel structure CH than the contact plug CT connected to the gate line having a relatively smaller resistance.

The resistances of the gate lines depend on various factors. As an example, the resistance of the gate line may vary depending on a width W_CH of the channel structure CH formed through the gate line. A gate line through which the channel structure CH is formed at a larger width W_CH may have a greater resistance than a gate line through which the channel structure CH is formed at a smaller width W_CH. As an example, the resistance of the gate line may vary depending on a thickness T of the gate line. A gate line having a relatively smaller thickness T may have a greater resistance than a gate line having a relatively larger thickness T. As an example, the resistances of the gate lines may vary depending on widths W1 and W2 of the gate lines. A gate line having a relatively smaller width W1 may have a greater resistance than a gate line having a relatively larger width W2. At least one of the drain select line DSL and the source select line SSL may have a greater resistance than the word line WL.

When the resistances of the gate lines are different from each other, signal transmission speeds are different from each other. A memory cell or a select transistor connected to a gate line having a relatively greater resistance has a slower operation speed than a memory cell or a select transistor connected to a gate line having a relatively smaller resistance. Accordingly, in order to compensate for a difference in operation speed due to a difference in resistance between gate lines, operation conditions may be changed or a shape, an arrangement method, and the like, of the contact plugs CT may be adjusted, depending on the resistances of the gate lines. As an example, a contact plug CT connected to a gate line having a relatively greater resistance may be located closer to a cell region CR than a contact plug CT connected to a gate line having a relatively smaller resistance. Through this process, speed reduction due to the difference in resistance between the gate lines may be improved.

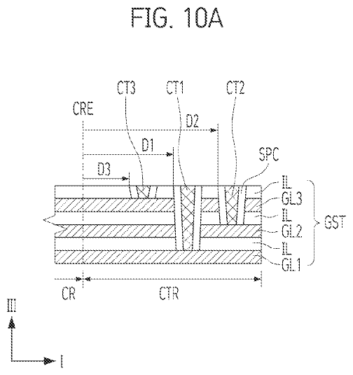

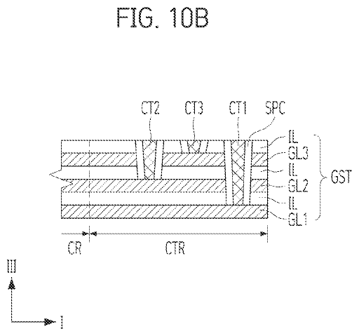

FIG. 10A and FIG. 10B are diagrams illustrating the structure of a semiconductor device in accordance with an embodiment.

Referring to FIG. 10A and FIG. 10B, the semiconductor device includes a gate structure GST, a first contact plug CT1, a second contact plug CT2, and a third contact plug CT3. The semiconductor device further includes insulating spacers SPC, where the sidewalls of each first contact plug CT1, the sidewalls of each second contact plug CT2, and the sidewalls of each third contact plugs CT3 are individually surrounded by an insulating spacer SPC. The gate structure GST includes gate lines GL1, GL2, and GL3 that are alternately stacked with insulating layers IL. The gate lines GL1, GL2, and GL3 may be source select lines, drain select lines, word lines, or dummy gate lines.

The first contact plug CT1 extends into the gate structure GST and is electrically connected to a first gate line GL1. The second contact plug CT2 extends into the gate structure GST and is electrically connected to a second gate line GL2. The third contact plug CT3 extends into the gate structure GST and is electrically connected to a third gate line GL3.

The first contact plug CT1, the second contact plug CT2, and the third contact plug CT3 may be located adjacent to each other in the first direction I, i.e., no other contact plugs intervene between consecutive contact plugs, and may extend in the third direction III. For reference, the first contact plug CT1, the second contact plug CT2, and the third contact plugs CT3 are illustrated in the same cross section for convenience of explanation, but the first contact plug CT1, the second contact plug CT2, and the third contact plug CT3 may be located in different cross sections.

The first gate line GL1, the second gate line GL2, and the third gate line GL3 may have different resistances depending on the thickness of each gate line. Some gate lines may have a relatively greater thickness and a relatively smaller resistance than the other gate lines. Some gate lines may have a relatively smaller thickness and a relatively greater resistance than the other gate lines.

According to an embodiment of the present disclosure, the first contact plug CT1, the second contact plug CT2, and the third contact plug CT3 may be arranged according to resistances of the first gate line GL1, the second gate line GL2, and the third gate line GL3. The first contact plug CT1, the second contact plug CT2, and the third contact plug CT3 may be arranged to be spaced apart from a cell region CR by different distances. In such a case, depths of the first contact plug CT1, the second contact plug CT2, and the third contact plug CT3 arranged in the first direction I might not have a specific directivity or order. Instead of arranging the first contact plug CT1, the second contact plug CT2, and the third contact plug CT3 such that a depth of the contact plug increases or decreases as a distance from the cell region CR increases or decreases, the first contact plug CT1, the second contact plug CT2 and the third contact plug CT3 having different depths may be mixed and arranged.

Referring to FIG. 10A, the first gate line GL1 having a first resistance is located below the second gate line GL2 having a second resistance and the third gate line GL3 having a third resistance. The first contact plug CT1 is located between the second contact plug CT2 and the third contact plug CT3. The first contact plug CT1 extends into the gate structure GST at a greater depth than the depth to which the second contact plug CT2 extends and the depth to which the third contact plug CT3 extends.

The third gate line GL3 is located above the second gate line GL2. The second gate line GL2 is located above the first gate line GL1, and the third gate line GL3 is located above the second gate line GL2. The third resistance is greater than the first resistance, and the first resistance is greater than the second resistance in this example.

The first contact plug CT1 is spaced apart from the cell region CR by a first distance D1. The second contact plug CT2 is spaced apart from the cell region CR by a second distance D2. The third contact plug CT3 is spaced apart from the cell region CR by a third distance D3. In this example, the distances D1, D2, and D3 are determined as distances from a cell region edge CRE to the nearest edge of the corresponding contact plug to the cell region edge CRE. A contact plug connected to a gate line, having a relatively great resistance among the gate lines GL1, GL2, and GL3 connected to the first contact plug CT1, the second contact plug CT2, and the third contact plug CT3, is disposed relatively close to the cell region CR. The third distance D3 is smaller than the first distance D1, and the first distance D1 is smaller than the second distance D2 in the example of FIG. 10A. The third contact plug CT3 is located closer to the cell region CR than where the first contact plug CT1 is located, and the first contact plug CT1 is located closer to the cell region CR than where the second contact plug CT2 is located.

Accordingly, the stacking order of the first gate line GL1, the second gate line GL2, and the third gate line GL3 and the arrangement order of the first contact plug CT1, the second contact plug CT2, and the third contact plug CT3 may be different from each other. The first gate line GL1, the second gate line GL2, and the third gate line GL3 may be sequentially stacked, while the third contact plug CT3, the first contact plug CT1, and the second contact plug CT2 may be sequentially arranged. For example, the contact plugs may be arranged according to resistance of the gate line connected to the corresponding contact plug. The first gate line GL1, the second gate line GL2, and the third gate line GL3 may be sequentially stacked, for example, GL1, GL2, and GL3. The first contact plug CT1, the second contact plug CT2, and the third contact plug CT3 may be arranged (formed) in a non-sequential order, for example, not sequentially arranged by depth of contact plug, distance from the cell region, electrical connection corresponding to a specific gate line order, not in sequential order CT1, CT2, and CT3 or CT3, CT2, and CT1, and so forth. In an example where the first contact plug CT1 is electrically connected to the first gate line GL1, the second contact plug CT2 is electrically connected to the second gate line GL2, and the third contact plug CT3 is electrically connected to the third gate line GL3, when the gate lines are sequentially stacked as GL1, GL2, and GL3, the contact plugs are not sequentially arranged in the order CT1, CT2, and CT3 based on distance between the cell region and the corresponding contact plug. Such an arrangement may be referred to a non-sequential, random, or non-consecutive order based on corresponding connection between each contact plug and the first gate line GL1, the second gate line GL2, and the third gate line GL3.

Referring to FIG. 10B, the first gate line GL1 having a first resistance is located below the second gate line GL2 having a second resistance and the third gate line GL3 having a third resistance. The third contact plug CT3 is located between the second contact plug CT2 and the first contact plug CT1. The third contact plug CT3 extends into the gate structure GST at a smaller depth than the depth to which the second contact plug CT2 extends and the depth to which the first contact plug CT1 extends.

The second resistance is greater than the third resistance, and the third resistance is greater than the first resistance in this example. A contact plug, connected to a gate line having a relatively great resistance among the gate lines GL1, GL2, and GL3 connected to the first contact plug CT1, the second contact plug CT2, and the third contact plug CT3, is disposed relatively close to the cell region CR. The second contact plug CT2 is located closer to the cell region CR than where the third contact plug CT3 is located, and the third contact plug CT3 is located closer to the cell region CR than where the first contact plug CT1 is located.

Accordingly, the stacking order of the first gate line GL1, the second gate line GL2, and the third gate line GL3 and the arrangement order of the first contact plug CT1, the second contact plug CT2, and the third contact plug CT3 may be different from each other. The first gate line GL1, the second gate line GL2, and the third gate line GL3 may be sequentially stacked, while the second contact plug CT2, the third contact plug CT3, and the first contact plug CT1 may be sequentially arranged.

According to the structure described above, the first contact plug CT1, the second contact plug CT2, and the third contact plugs CT3 may advantageously be arranged according to the resistances of the first gate line GL1, the second gate line GL2, and the third gate line GL3. The contact plug connected to the gate line having the greatest resistance may be disposed closest to the cell region CR to reduce a signal transmission path, and the contact plug connected to the gate line having the smallest resistance may be disposed farthest from the cell region CR to increase a signal transmission path.

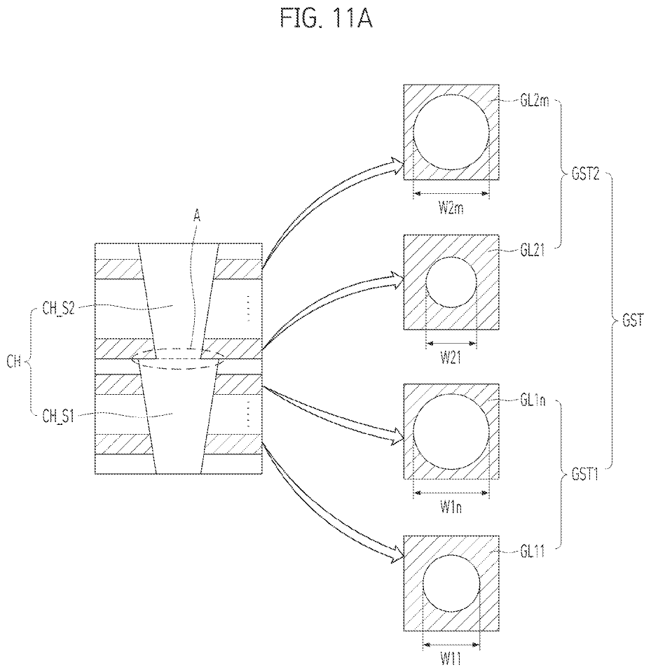

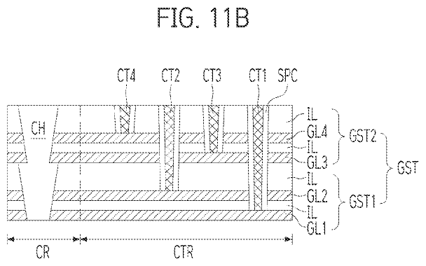

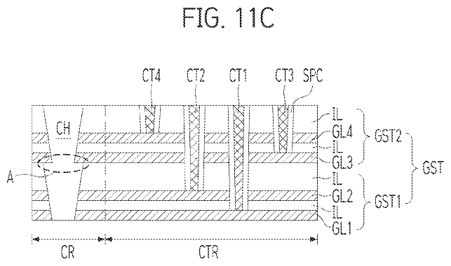

FIG. 11A through FIG. 11C are diagrams illustrating the structure of a semiconductor device in accordance with an embodiment.

Referring to FIG. 11A, a gate structure GST may include a first gate structure GST1 and a second gate structure GST2. The first gate structure GST1 may include first gate lines GL11 to GL1n that are alternately stacked with insulating layers IL. The second gate structure GST2 may be located on or over (e.g., stacked on) the first gate structure GST1 and may include second gate lines GL21 to GL2m that are alternately stacked with insulating layers IL. In this example, n and m may be integers having values of 1 or more and may be the same as or different from each other.

A channel structure CH includes a first sub-channel structure CH_S1 and a second sub-channel structure CH_S2 in this example. The first sub-channel structure CH_S1 extends through a cell region CR of the first gate structure GST1. The second sub-channel structure CH_S2 is connected to the first sub-channel structure CH_S1 and extends through the second gate structure GST2. Each of the first sub-channel structure CH_S1 and the second sub-channel structure CH_S2 has a cross section with a taped shape. The channel structure includes an inflection portion A where the first sub-channel structure CH_S1 and the second sub-channel structure CH_S2 are connected to each other, and the first sub-channel structure CH_S1 and the second sub-channel structure CH_S2 have different widths at the inflection portion A.

The first sub-channel structure CH_S1 is formed through the first gate line GL11 at a first width W11 and is formed through the first gate line GL1n at a first width W1n. The first width W11 and the first width W1n may be different from each other, and the first width W1n may be greater than the first width W11, such as shown in FIG. 11A. The first gate line GL1n may have a greater resistance than the first gate line GL11.

The second sub-channel structure CH_S2 is formed through the second gate line GL21 at a second width W21 and is formed through the second gate line GL2m at a second width W2m. The second width W21 and the second width W2m may be different from each other, and the second width W2m may be greater than the second width W21, such as shown in FIG. 11A. The second gate line GL2m may have a greater resistance than the second gate line GL21.

Referring to FIG. 11B and FIG. 11C, the semiconductor device includes a gate structure GST, a channel structure CH, and a first contact plug CT1, a second contact plug CT2, a third contact plug CT3, and a fourth contact plug CT4. The channel structure CH is located in the cell region CR, and the first contact plug CT1, the second contact plug CT2, the third contact plug CT3, and the fourth contact plug CT4 are located in a contact region CTR.

The gate structure GST includes a first gate structure GST1 and a second gate structure GST2. The first gate structure GST1 includes a first gate line GL1 having a first resistance and a second gate line GL2 having a second resistance. The second gate line GL2 is located above the first gate line GL1. The second gate structure GST2 includes a third gate line GL3 having a third resistance and a fourth gate line GL4 having a fourth resistance. The fourth gate line GL4 is located above the third gate line GL3. In this example, the fourth resistance may be substantially the same as the second resistance or may be greater than the second resistance. The second resistance may be greater than the third resistance. The third resistance may be substantially the same as the first resistance or may be greater than the first resistance.

The first contact plug CT1 extends into the first gate structure GST1 through the second gate structure GST2 and is electrically connected to the first gate line GL1. The second contact plug CT2 extends into the first gate structure GST1 through the second gate structure GST2 and is electrically connected to the second gate line GL2. The third contact plug CT3 extends into the second gate structure GST2 and is electrically connected to the third gate line GL3. The fourth contact plug CT4 extends into the second gate structure GST2 and is electrically connected to the fourth gate line GL4.

Contact plugs connected to the first gate structure GST1 and contact plugs connected to the second gate structure GST2 may be mixed and arranged. At least one of the contact plugs connected to the first gate structure GST1 may be located between the contact plugs connected to the second gate structure GST2, for example contact plug CT2 in the example of FIG. 11B. At least one of the contact plugs connected to the second gate structure GST2 may be located between the contact plugs connected to the first gate structure GST1, for example contact plug CT3 in the example of FIG. 11B.

The third contact plug CT3 is located between the first contact plug CT1 and the second contact plug CT2 in the example of FIG. 11B. The second contact plug CT2 is located between the third contact plug CT3 and the fourth contact plug CT4 in the example of FIG. 11B.

The fourth contact plug CT4 is located closer to the cell region CR than where the second contact plug CT2 is located in the example of FIG. 11B. The second contact plug CT2 is located closer to the cell region CR than where the third contact plug CT3 is located in the example of FIG. 11B. The third contact plug CT3 is located closer to the cell region CR than where the first contact plug CT1 is located in the example of FIG. 11B.

Referring to FIG. 11C, when the first gate line GL1 has substantially the same resistance as the third gate line GL3, one of the first contact plug CT1 and the third contact plug CT3 may be located closer to the cell region than where the other of the first contact plug CT1 and the third contact plug CT3 is located. As an example, the first contact plug CT1 may be located closer to the cell region CR than where the third contact plug CT3 is located.

A plurality of contact plugs connected to the first gate structure GST1 may be located between contact plugs connected to the second gate structure GST2. The first contact plug CT1 and the second contact plug CT2 are located between the third contact plug CT3 and the fourth contact plug CT4 in the example of FIG. 11C. In another example, a plurality of contact plugs connected to the second gate structure GST2 may be located between contact plugs connected to the first gate structure GST1. The third contact plug CT3 and the fourth contact plug CT4 may be located between the first contact plug CT1 and the second contact plug CT2 in another example.

According to the structure described above, the channel structure CH may include at least one inflection portion A and may have different widths depending on levels, e.g., location or distance of the width of the channel structure CH from the bottom or top of the device relative to the drawing. The resistances of the gate lines GL1, GL2, GL3, and GL4 may be different from each other depending on the widths of the channel structure CH, and the contact plugs CT1, CT2, CT3, and CT4 may be arranged according to the resistances.

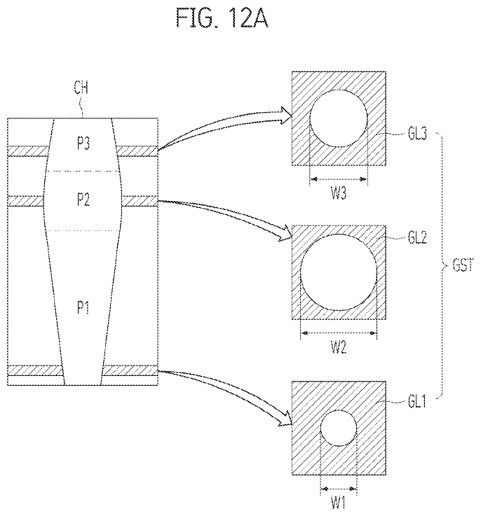

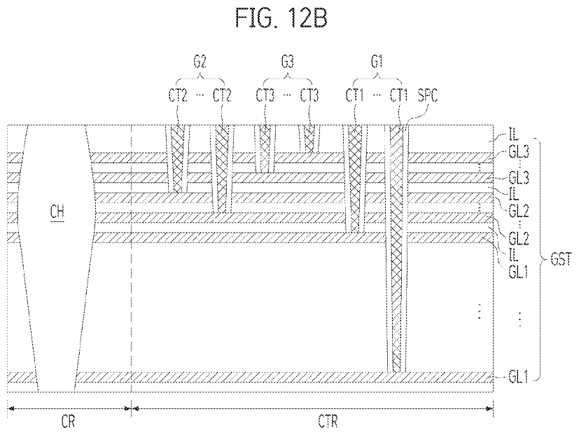

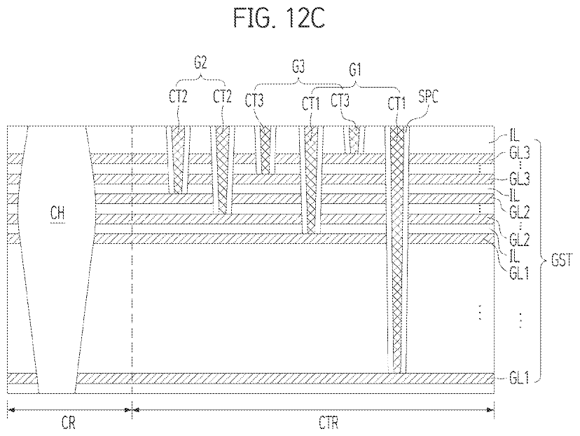

FIG. 12A through FIG. 12C are diagrams illustrating the structure of a semiconductor device in accordance with an embodiment.

Referring to FIG. 12A, a gate structure GST may include a plurality of first gate lines GL1, a plurality of second gate lines GL2, and a plurality of third gate lines GL3. The second gate lines GL2 may be located between the first gate lines GL1 and the third gate lines GL3.

A channel structure CH includes a first portion P1, a second portion P2, and a third portion P3 in the example of FIG. 12A. A portion of the channel structure CH formed through the first gate lines GL1 is referred to as the first portion P1. A portion of the channel structure CH formed through the second gate lines GL2 is referred to as the second portion P2. A portion of the channel structure CH formed through the third gate lines GL3 is referred to as the third portion P3. The second portion P2 is located between the first portion P1 and the third portion P3 in this example.

The first portion P1 has a first width W1, the second portion P2 has a second width W2, and the third portion P3 has a third width W3. The second width W2 may be greater than the first width W1 and the third width W3. The second width W2 is greater than the third width W3, and the third width W3 is greater than the first width W1 in this example. The channel structure CH may include a cross section with a bowing shape. The bowing shape may be caused by an etching process for forming a channel hole. In this example, the second width W2 may refer to a maximum width of the second portion P2 or an average width of the second portion P2.

Referring to FIG. 12B and FIG. 12C, the semiconductor device includes a gate structure GST, a channel structure CH, a first group G1 of first contact plugs CT1, a second group G2 of second contact plugs CT2, and a third group G3 of third contact plugs CT3. The channel structure CH is located in the cell region CR, and the first contact plug CT1, the second contact plug CT2, and the third contact plug CT3 are located in the contact region CTR.

The gate structure GST includes a plurality of first gate lines GL1, a plurality of second gate lines GL2, and a plurality of third gate lines GL3. The second gate lines GL2 are located between the first gate lines GL1 and the third gate lines GL3. The second gate lines GL2 may have a greater resistance than the first gate lines GL1 and the third gate lines GL3. The second gate lines GL2 may have a greater resistance than the third gate lines GL3, and the third gate lines GL3 may have substantially the same resistance as the first gate lines GL1 or have a greater resistance than the first gate lines GL1.

The first group G1 of first contact plugs CT1 extends into the gate structure GST and is electrically connected to the first gate lines GL1, where one first contact plug CT1 is connected to a different one of the first gate lines GL1. The second group G2 of second contact plugs CT2 extends into the gate structure GST and is electrically connected to the second gate lines GL2, where one second contact plug CT2 is connected to a different one of the second gate lines GL2. The third group G3 of third contact plugs CT3 extends into the gate structure GST and is electrically connected to the third gate lines GL3, where one third contact plug CT3 is connected to a different one of the third gate lines GL3.

Referring to FIG. 12B, the second group G2 is located closer to the cell region CR than where the first group G1 and the third group G3 are located. The second group G2 is located closer to the cell region CR than where the third group G3 is located, and the third group G3 is located closer to the cell region CR than where the first group G1 is located.

Referring to FIG. 12C, groups G1 and G3 are mixed and arranged. At least one of the first contact plugs CT1 and at least one of the third contact plugs CT3 is mixed and arranged, in other words, at least one of the third group G3 overlaps with at least one of the first group G1, such as shown in FIG. 12C. As an example, the third contact plug CT3 of the third group G3 is located closer to the cell region CR than where the first group G1 is located, and at least one of the first contact plugs CT1 of the first group G1 is located closer to the cell region CR than where at least one third contact plug CT3 of the third group G3 is located.

According to the structure described above, the contact plugs CT1, CT2, and CT3 may be disposed in consideration of a difference in resistance between the gate lines depending on the shape of the channel structure CH. Accordingly, a difference in operation speed due to the difference in resistance between the gate lines may be improved.

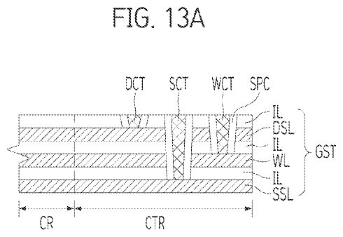

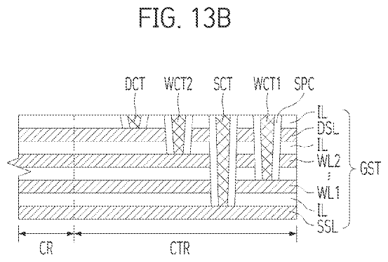

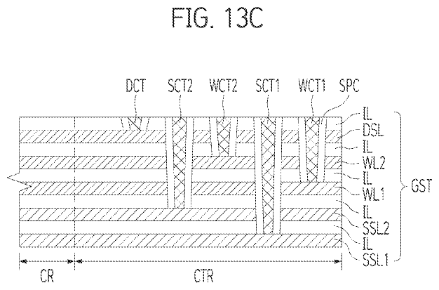

FIG. 13A through FIG. 13C are diagrams illustrating the structure of a semiconductor device in accordance with an embodiment.

Referring to FIG. 13A through FIG. 13C, a gate structure GST includes at least one source select line SSL, at least one word line WL, and at least one drain select line DSL. The word line WL may be advantageously located between the source select line SSL and the drain select line DSL.

A source contact plug SCT may extend into the gate structure GST and is electrically connected to the source select line SSL. A cell contact plug WCT extends into the gate structure GST and is electrically connected to the word line WL. A drain contact plug DCT extends into the gate structure GST and is electrically connected to the drain select line DSL.

At least one of the drain select line DSL and the source select line SSL may have a smaller width than the width of the word line WL. At least one of the drain select line DSL and the source select line SSL may have a greater resistance than the resistance of the word line WL. At least one of the drain contact plug DCT and the source contact plug SCT may be located closer to the cell region than where the cell contact plug WCT is located.

Referring to FIG. 13A, the source contact plug SCT is located between the drain contact plug DCT and the cell contact plug WCT. The drain select line DSL may have substantially the same resistance as the source select line SSL or have a greater resistance than the source select line SSL. The drain contact plug DCT is shown located closer to the cell region CR than where the source contact plug SCT is located. The source contact plug SCT is shown located closer to the cell region CR than the cell contact plug WCT is.

Referring to FIG. 13B, the gate structure GST includes a first word line WL1 and a second word line WL2. The second word line WL2 is located above the first word line WL1 and may have a greater resistance than the first word line WL1. A first cell contact plug WCT1 extends into the gate structure GST and is electrically connected to the first word line WL1. A second cell contact plug WCT2 extends into the gate structure GST and is electrically connected to the second word line WL2.

The source contact plug SCT is shown located between the first cell contact plug WCT1 and the second cell contact plug WCT2. The second word line WL2 may have a greater resistance than the source select line SSL, and the source select line SSL may have a greater resistance than the first word line WL1.

The second cell contact plug WCT2 is shown located between the drain contact plug DCT and the source contact plug SCT. The drain select line DSL may have a greater resistance than the second word line WL2, and the second word line WL2 may have a greater resistance than the source select line SSL.

Referring to FIG. 13C, the gate structure GST includes a first source select line SSL1 and a second source select line SSL2. The second source select line SSL2 is located above the first source select line SSL1 and may have a greater resistance than the first source select line SSL1. A first source contact plug SCT1 extend into the gate structure GST and is electrically connected to the first source select line SSL1. A second source contact plug SCT2 extends into the gate structure GST and is electrically connected to the second source select line SSL2.

The second cell contact plug WCT2 is shown located between the first source contact plug SCT1 and the second source contact plug SCT2. The second source select line SSL2 may have a greater resistance than the second word line WL2, and the second word line WL2 may have a greater resistance than the first source select line SSL1.

According to the structure described above, the source contact plug SCT, the drain contact plug DCT, and the cell contact plug WCT may be arranged in consideration of widths, thicknesses, and the like, of the source select line SSL and the drain select line DSL. Accordingly, a difference in operation speed due to a difference in resistance between the gate lines may be improved.

Alternatively, a width of the channel structure may be considered in addition to the widths, the thicknesses, and the like, of the source select line SSL and the drain select line DSL.

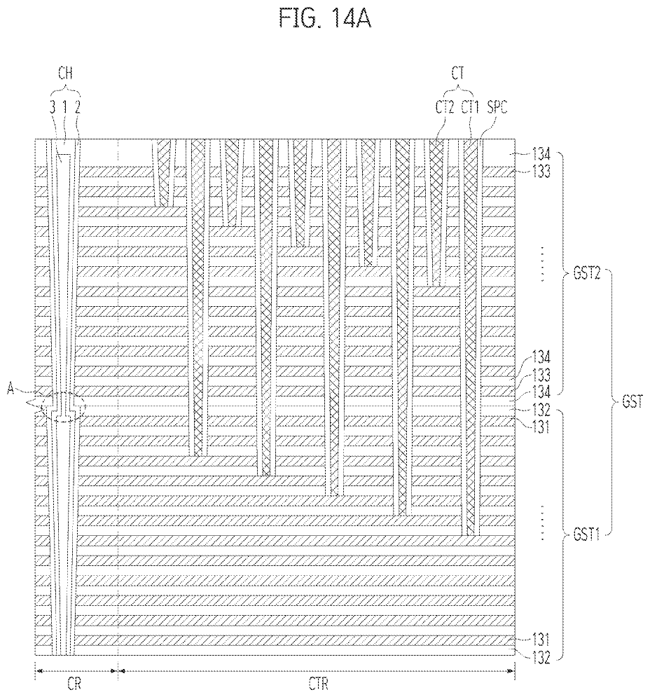

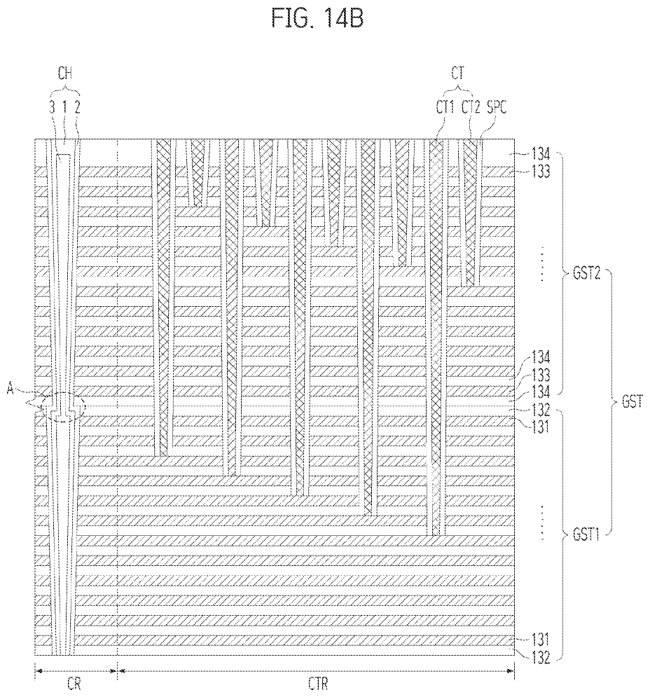

FIG. 14A and FIG. 14B are diagrams illustrating the structure of a semiconductor device in accordance with an embodiment.

Referring to FIG. 14A and FIG. 14B, the semiconductor device includes a gate structure GST, a channel structure CH, and contact plugs CT. The gate structure GST includes a first gate structure GST1 and a second gate structure GST2. The first gate structure GST1 includes a plurality of first conductive layers 131 that are alternately stacked with a plurality of first insulating layers 132. The second gate structure GST2 is located on or over (e.g., stacked on) the first gate structure GST1 and includes a plurality of second conductive layers 133 that are alternately stacked with a plurality of second insulating layers 134. The first conductive layers 131 and the second conductive layers 133 may include at least one of source select lines, word lines, drain select lines, and dummy gate lines. The channel structure CH includes at least one of a channel layer 1, a memory layer 2, and an insulating core 3.

The contact plugs CT extend into the gate structure GST at different depths. Each of the first contact plugs CT1 extends into the first gate structure GST1 through the second gate structure GST2 and is electrically connected to a different one of the first conductive layers 131. Each of the second contact plugs CT2 extends into the second gate structure GST2 and is electrically connected to a different one of the second conductive layers 133.

The channel structure CH may include an inflection portion A located at an interface between the first gate structure GST1 and the second gate structure GST2. The channel structure CH may have a shape repeated based on the inflection portion A. As an example, a tapered shape may be repeated in both the first gate structure GST1 and the second gate structure GST2 or a bowing shape may be repeated in both the first gate structure GST1 and the second gate structure GST2.

When the channel structure CH has a tapered shape, a first conductive layer 131 located at a relatively higher level among the first conductive layers 131 may have a greater resistance than a first conductive layer 131 located at a relatively lower level among the first conductive layers 131. A second conductive layer 133 located at a relatively higher level among the second conductive layers 133 may have a greater resistance than a second conductive layer 133 located at a relatively lower level among the second conductive layers 133. Accordingly, the first contact plugs CT1 may be alternately arranged with the second contact plugs CT2.

When the channel structure CH has a repetitive tapered shape, the conductive layers 131 and 133 located at similar levels with respect to each gate structure GST1 and gate structure GST2 may have substantially the same resistance. For example, a conductive layer having a similar level includes a lowermost conductive layer 131 and a lowermost conductive layer 133, an nth conductive layer 131 and an nth conductive layer 133, an uppermost conductive layer 131 and an uppermost conductive layer 133, and so forth. In this example, as illustrated in FIG. 14A, the second contact plug CT2 connected to the second gate structure GST2 may be arranged first, i.e., closest to the cell region CR. Alternatively, as illustrated in FIG. 14B, the first contact plug CT1 may be arranged first, i.e., closest to the cell region CR.

According to the structure described above, the first contact plugs CT1 connected to the first gate structure GST1 and the second contact plugs CT2 connected to the second gate structure GST2 may be arranged in consideration of a difference in resistance between gate lines depending on a width of the channel structure CH. Accordingly, in a multi-stack structure, a difference in operation speed due to the difference in resistance between the gate lines may be improved.

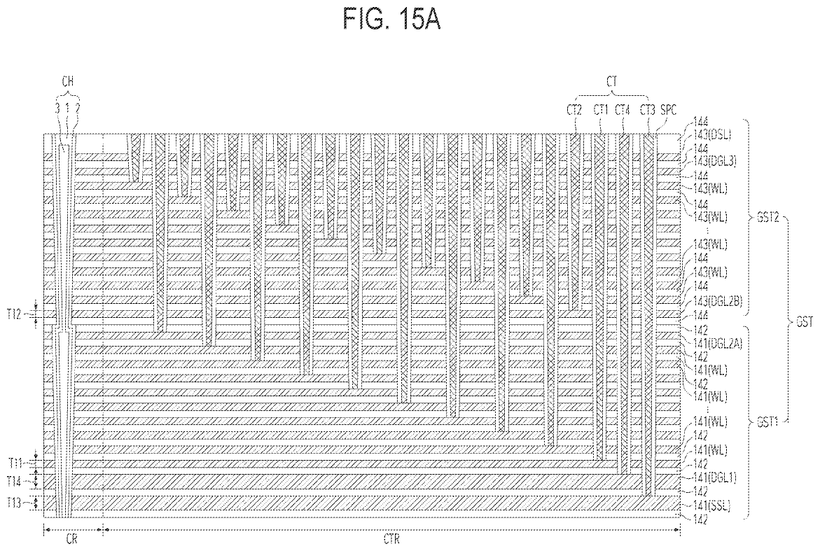

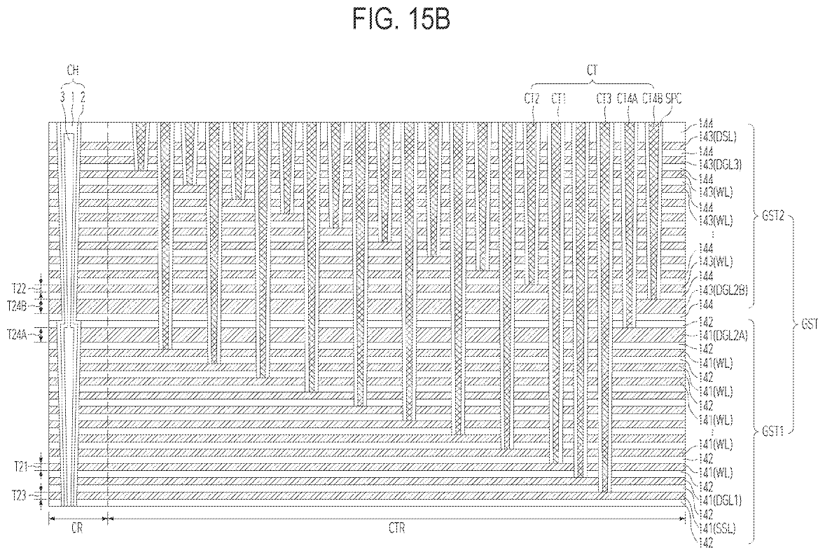

FIG. 15A and FIG. 15B are diagrams illustrating the structure of a semiconductor device in accordance with an embodiment.

Referring to FIG. 15A and FIG. 15B, the semiconductor device includes a gate structure GST, a plurality of contact plugs CT, a plurality of insulating spacers SPC, and a channel structure CH. The gate structure GST includes a first gate structure GST1 and a second gate structure GST2. The first gate structure GST1 includes a plurality of first conductive layers 141 that are alternately stacked with a plurality of first insulating layers 142. The second gate structure GST2 may include a plurality of second conductive layers 143 that are alternately stacked with a plurality of second insulating layers 144.

At least one lowermost first conductive layer 141 of the first conductive layers 141 may be a source select line SSL. The remaining first conductive layers 141 may be word lines WL. At least one first dummy gate line DGL1 may be located between the source select line SSL and the word lines WL. At least one uppermost first conductive layer 141 of the first conductive layers 141 may be a second dummy gate line DGL2A.

At least one uppermost second conductive layer 143 of the second conductive layers 143 may be a drain select line DSL. The remaining second conductive layers 143 may be word lines WL. At least one third dummy gate line DGL3 may be located between the drain select line DSL and the word lines WL. At least one lowermost second conductive layer 143 of the second conductive layers 143 may be a second dummy gate line DGL2B. The source select line SSL, the word lines WL, the first dummy gate line DGL1, the second dummy gate line DGL2A and DGL2B, the third dummy gate line DGL3, and the drain select line DSL may have substantially the same thickness or have different thicknesses.

Referring to FIG. 15A, the word lines WL of the first gate structure GST1 have a first thickness T11, and the word lines WL of the second gate structure GST2 have a second thickness T12. The first thickness T11 and the second thickness T12 may be substantially the same as each other.

At least one of the source select line SSL and drain select line DSL may have a third thickness T13. At least one of the first dummy gate line DGL1, the second dummy gate lines DGL2A and DGL2B, and the third dummy gate line DGL3 may have a fourth thickness T14.

The third thickness T13 may be greater than the first thickness T11 and the second thickness T12. At least one of the source select line SSL and the drain select line DSL may have a smaller resistance than the word lines WL. At least one of the first dummy gate line DGL1, the second dummy gate lines DGL2A and DGL2B, and the third dummy gate line DGL3 may have a smaller resistance than the word lines WL.

As an example, each first contact plug CT1 is connected to a different one of the word lines WL or the second dummy gate line DGL2A of the first gate structure GST1. Each second contact plug CT2 is connected to a different one of the word lines WL or the second dummy gate line DGL2B of the second gate structure GST2. A third contact plug CT3 is connected to the source select line SSL, and a fourth contact plug is connected to the first gate dummy line DGL1. The source select line SSL and the first dummy gate line DGL1 may have a relatively smaller resistance than the remaining gate lines. Accordingly, the third contact plug CT3 and the fourth contact plug CT4 may be located to be spaced apart from the cell region CR compared to the locations of the first contact plug CT1 and the second contact plug CT2.

The contact plugs CT may be arranged in consideration not only of thicknesses of gate lines but also of resistances of the gate lines according to a shape of the channel structure CH. As an example, a width at which the channel structure CH is formed through the first dummy gate line DGL1 may be greater than a width at which the channel structure CH is formed through the source select line SSL. Accordingly, the first dummy gate line DGL1 may have a greater resistance than the source select line SSL, and the fourth contact plug CT4 may be located closer to the cell region CR than where the third contact plug CT3 is located.

Referring to FIG. 15B, the word lines WL of the first gate structure GST1 have a first thickness T21, and the word lines WL of the second gate structure GST2 have a second thickness T22. The first thickness T21 and the second thickness T22 may be substantially the same as each other.

At least one of the source select line SSL and drain select line DSL may have a third thickness T33. A second dummy gate line DGL2A of the first gate structure GST1 may have a fourth thickness T24A. A second dummy gate line DGL2B of the second gate structure GST2 may have a fourth thickness T24B. The fourth thickness T24A and the fourth thickness T24B may be greater than the first thickness T21, the second thickness T22, and the third thickness T23.

As shown in the example of FIG. 15B, a first contact plug CT1 is shown connected to a word line WL of the first gate structure GST1, and a second contact plug CT2 is shown connected to a word line WL of the second gate structure GST2. A third contact plug CT3 is shown connected to the source select line SSL. A fourth contact plug CT4A is shown connected to the second dummy gate line DGL2A, and a fourth contact plug CT4B is shown connected to the second dummy gate line DGL2B. The second dummy gate lines DGL2A and DGL2B may have a relatively smaller resistance than the remaining gate lines. Accordingly, the fourth contact plugs CT4A and CT4B have locations spaced apart from the cell region CR compared to the locations of the first contact plug CT1, the second contact plug CTS, and the third contact plug CT3.

A width at which the channel structure CH is formed through the second dummy gate line DGL2A is shown greater than a width at which the channel structure CH is formed through the second dummy gate line DGL2B. Accordingly, the second dummy gate line DGL2A has a greater resistance than the second dummy gate line DGL2B, and the fourth contact plug CT4A is located closer to the cell region CR than where the fourth contact plug CT4B is located.

According to the structure described above, the first conductive layers 141 and the second conductive layers 143 may have different resistances depending on their functions or locations. At least one of the word lines WL, the source select line SSL, the drain select line DSL, and the dummy gate lines DGL1, DGL2A, DGL2B, and DGL3 may have a greater thickness and a relatively smaller resistance than the remaining gate lines. Accordingly, the contact plug connected to the gate line having a relatively great thickness may be located relatively far from the cell region CR.

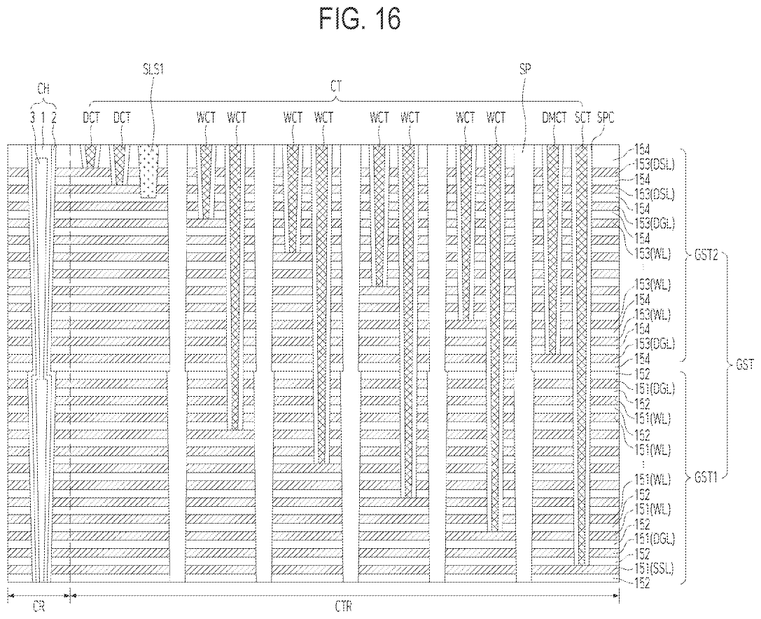

FIG. 16 is a diagram illustrating the structure of a semiconductor device in accordance with an embodiment.

Referring to FIG. 16, the semiconductor device includes a gate structure GST, contact plugs CT, insulating spacers SPC, a channel structure CH, and a first slit structure SLS1. The gate structure GST includes a first gate structure GST1 and a second gate structure GST2. The first gate structure GST1 includes a plurality of first conductive layers 151 that are alternately stacked with a plurality of first insulating layers 152. The second gate structure GST2 includes a plurality of second conductive layers 153 that are alternately stacked with a plurality of second insulating layers 154.

The channel structure CH includes at least one of a channel layer 1, a memory layer 2, and an insulating core 3. At least one support SP may have a structure similar to that of the channel structure CH. As an example, the support SP may include at least one of a dummy channel layer, a dummy memory layer, and a dummy insulating core. As an example, the support SP may include an insulating material such as an oxide or a conductive material such as polysilicon or tungsten. The support SP may be located between the contact plugs CT.

Drain contact plugs DCT are connected to drain select lines DSL, a source contact plug SCT is connected to a source select line SSL, cell contact plugs WCT are connected to word lines WL, and a dummy contact plug DMCT is connected to a dummy gate line DGL in the example of FIG. 16.

As an example, the drain select line DSL may be patterned by the first slit structure SLS1 and may have a smaller width than the remaining gate lines. In this example, the drain contact plugs DCT may be located closer to the cell region CR than where the remaining contact plugs are located.

As an example, the source select line SSL may have a smaller width than the word lines WL, and the source contact plug SCT may be located closer to the cell region CR than where at least some of the cell contact plugs WCT are located.

According to the structure described above, the first conductive layers 151 and the second conductive layers 153 may have different resistances depending on their functions or locations. At least one of the source select line SSL and the drain select line DSL may have a smaller width and a relatively greater resistance than the remaining gate lines. Accordingly, at least one of the source contact plug SCT and the drain contact plug DCT may be located closer to the cell region CR than where the cell contact plugs WCT are located.

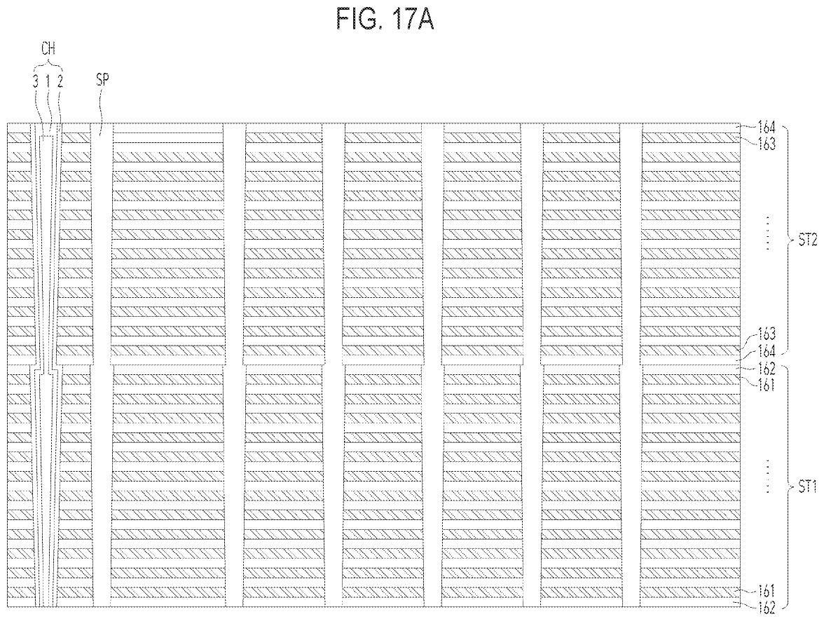

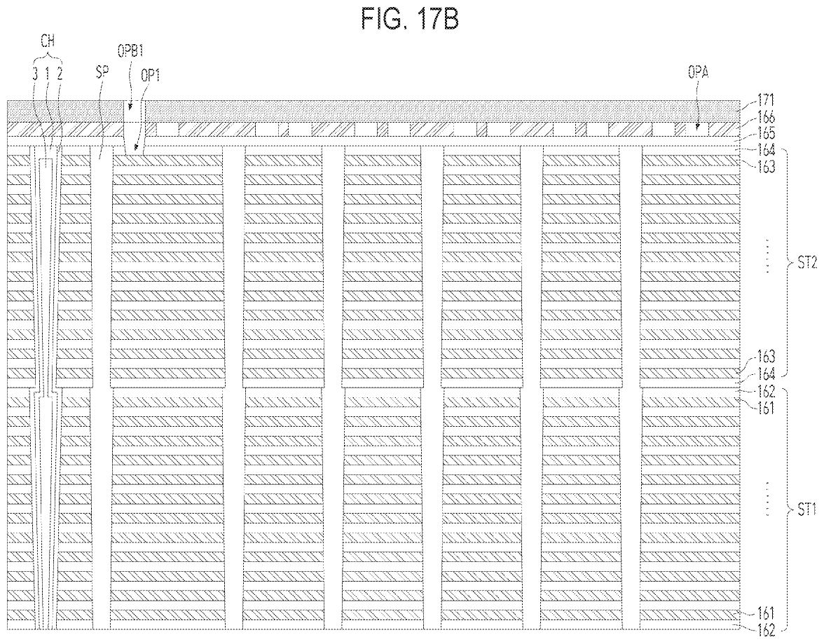

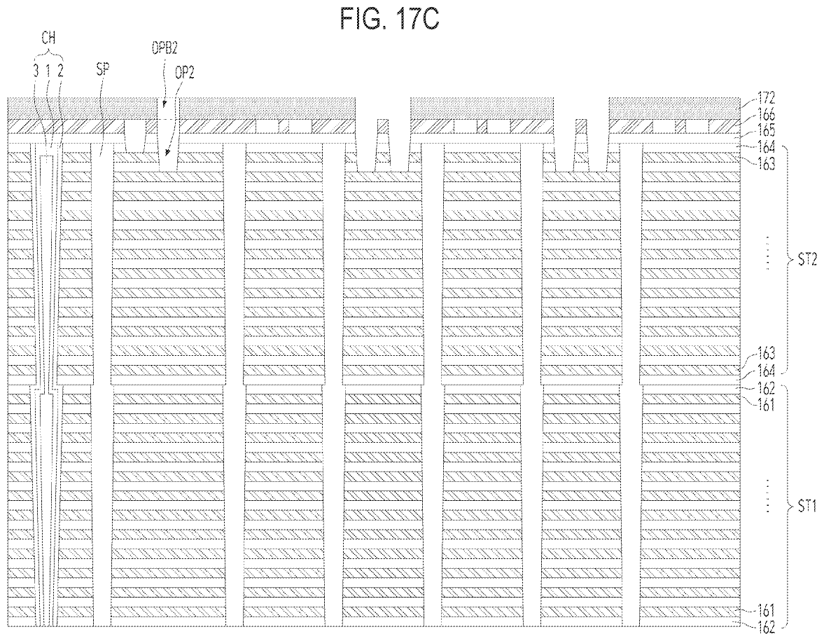

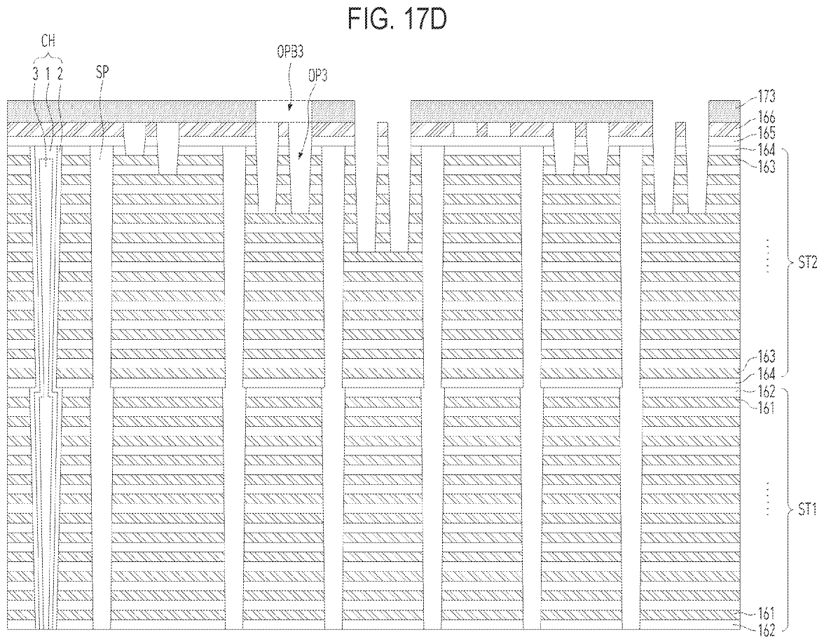

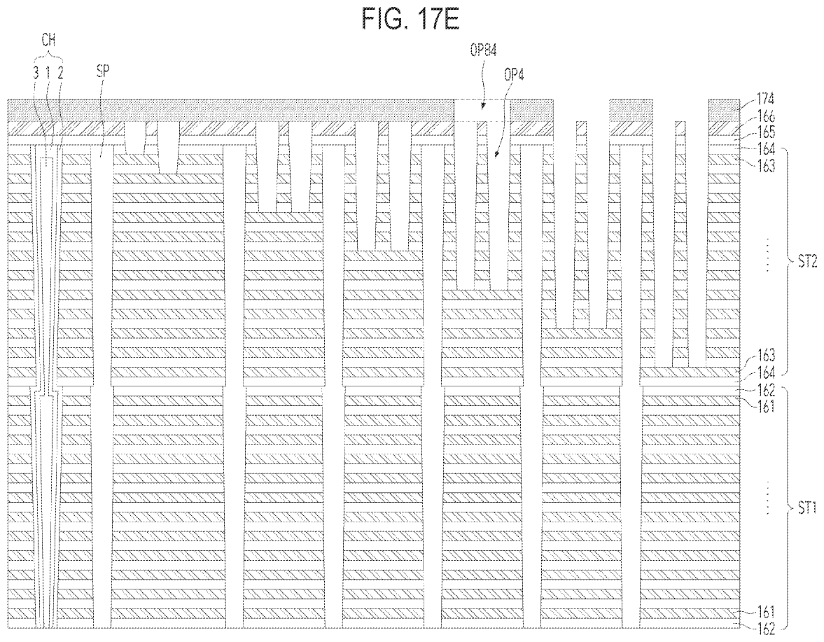

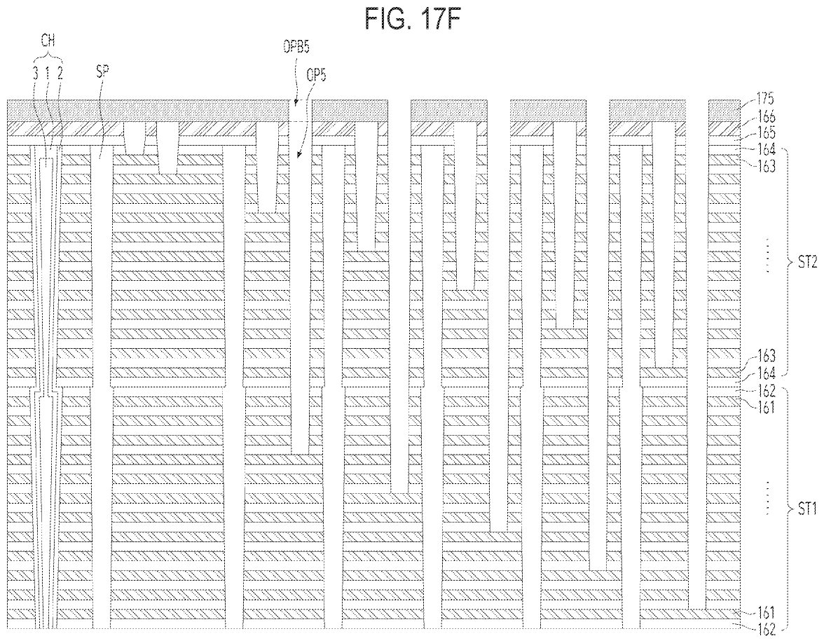

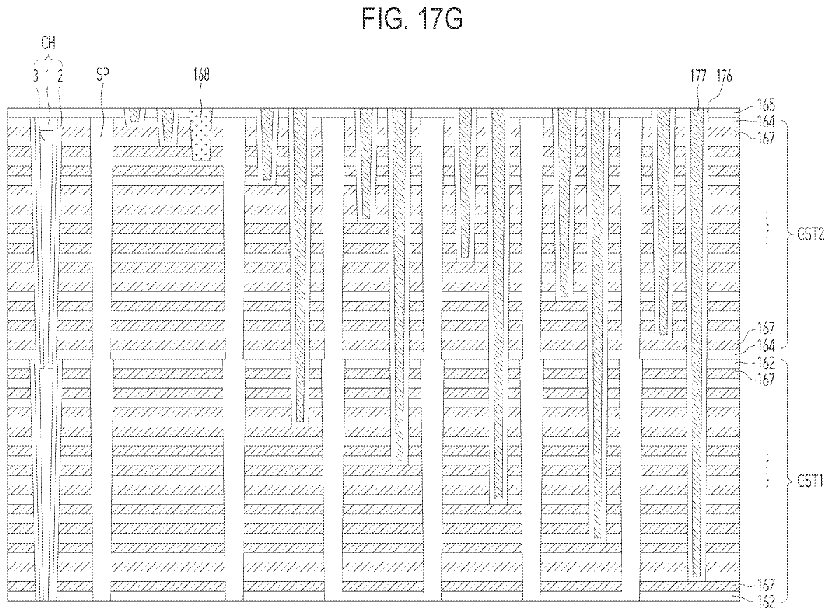

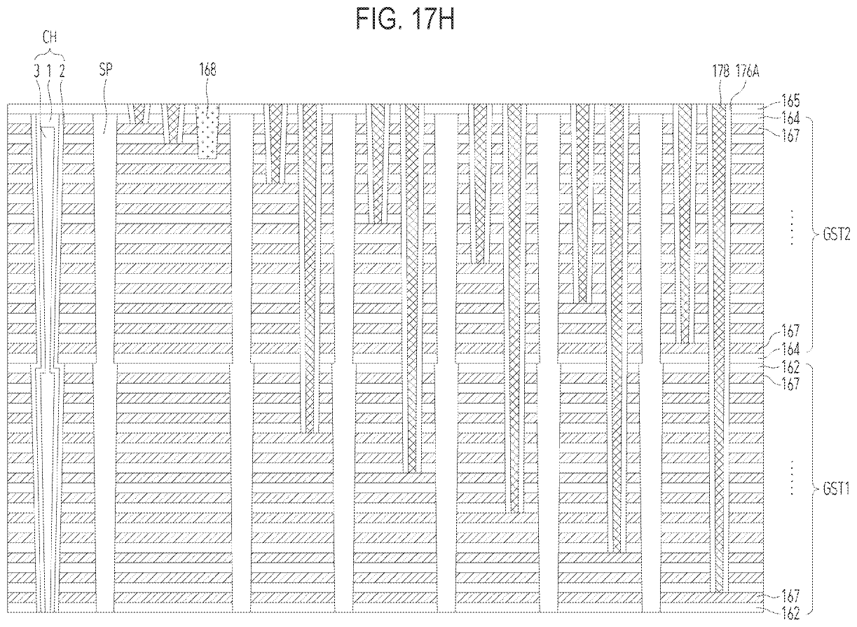

FIG. 17A through FIG. 17H are diagrams illustrating various views of a semiconductor device formed using a method of manufacturing a semiconductor device in accordance with an embodiment.

Referring to FIG. 17A, a first stack ST1 is formed including a plurality of first material layers 161 that are alternately stacked with a plurality of first insulating layers 162. Subsequently, a second stack ST2 may be formed on or over (e.g., stacked on) the first stack ST1. The second stack ST2 may include a plurality of second material layers 163 that are alternately stacked with a plurality of second insulating layers 164. In this example, the first material layers 161 and the second material layers 163 may be used to form gate lines. The first insulating layers 162 and the second insulating layers 164 insulate the stacked gate lines from each other. Each of the first material layers 161 and each of the second material layers 163 may comprise a material having a high etching selectivity with respect to the etching selectivity of the first insulating layers 162 and the second insulating layers 164. As an example, each of the first material layers 161 and each of the second material layers 163 may each comprise a sacrificial material such as a nitride or a conductive material such as polysilicon or metal. Each of the first insulating layers 162 and each of the second insulating layers 164 may comprise an insulating material such as an oxide, a nitride, or a void.

Subsequently, a channel structure CH and a support SP extending through the second stack ST2 and the first stack ST1 may be formed. The channel structure CH may include at least one of a channel layer 1, a memory layer 2, and an insulating core 3. The support SP may be formed when the channel structure CH is formed. Alternatively, at least some of processes for forming the support SP may be performed using processes of forming the channel structure CH. As an example, a channel hole and a support hole may be formed at the same time and may be filled with different materials to form the channel structure CH and the support SP, respectively.

Referring to FIG. 17B, an interlayer insulating layer 165 may be formed on the second stack ST2. The interlayer insulating layer 165 may include an oxide. Subsequently, a hard mask pattern 166 may be formed on the interlayer insulating layer 165. The hard mask pattern 166 includes openings OPA exposing regions where contact plugs are to be formed, for example. As an example, the hard mask pattern 166 may comprise polysilicon.

Subsequently, a first mask pattern 171 may be formed on the hard mask pattern 166. The first mask pattern 171 includes at least one opening OPB1 exposing at least one of the openings OPA. The first mask pattern 171 may cover the remaining openings OPA, and a material of the first mask pattern 171 may be formed in the openings OPA covered by the first mask pattern 171. The first mask pattern 171 may include a photoresist.

Subsequently, the interlayer insulating layer 165 and the second stack ST2 may be etched using the hard mask pattern 166 and the first mask pattern 171 as an etching barrier. Through this process, a first opening OP1 extending into the second stack ST2 and exposing an uppermost one of the second material layers 163 may be formed. Subsequently, the first mask pattern 171 may be removed.

Referring to FIG. 17C, a second mask pattern 172 may be formed on or over the hard mask pattern 166. The second mask pattern 172 includes at least one opening OPB2 exposing at least one of the openings OPA. Subsequently, the interlayer insulating layer 165 and the second stack ST2 may be etched using the hard mask pattern 166 and the second mask pattern 172 as an etching barrier. Through this process, a second opening OP2 extending into the second stack ST2 and exposing the second material layer 163, i.e., a material layer 163 below the uppermost second material layer 163, may be formed. The second opening OP2 may be formed by extending the first opening OP1 or may be newly formed in the second stack ST2. Subsequently, the second mask pattern 172 may be removed.

Referring to FIG. 17D, a third mask pattern 173 may be formed on or over the hard mask pattern 166. The third mask pattern 173 includes at least one opening OPB3 exposing at least one of the openings OPA in the hard mask pattern 166. Subsequently, the interlayer insulating layer 165 and the second stack ST2 may be etched using the hard mask pattern 166 and the third mask pattern 173 as an etching barrier. Through this process, a third opening OP3 extending into the second stack ST2 and exposing one of the plurality of second material layers 163 may be formed. The third opening OP3 may be formed by extending at least one of the first openings OP1 and the second openings OP2 or may be newly formed in the second stack ST2. Subsequently, the third mask pattern 173 may be removed.

Referring to FIG. 17E, a fourth mask pattern 174 may be formed on the hard mask pattern 166. The fourth mask pattern 174 includes at least one opening OPB4 exposing at least one of the openings OPA. Subsequently, the interlayer insulating layer 165 and the second stack ST2 may be etched using the hard mask pattern 166 and the fourth mask pattern 174 as an etching barrier. Through this process, a fourth opening OP4 extending into the second stack ST2 and exposing another of the second material layers 163 may be formed. The fourth opening OP4 may be formed by extending at least one of the first to third openings OP1 to OP3 or may be newly formed in the second stack ST2. Subsequently, the fourth mask pattern 174 may be removed.

Referring to FIG. 17F, a fifth mask pattern 175 may be formed on the hard mask pattern 166. The fifth mask pattern 175 includes at least one opening OPB5 exposing at least one of the openings OPA. Subsequently, the interlayer insulating layer 165 and the second stack ST2 may be etched using the hard mask pattern 166 and the fifth mask pattern 175 as an etching barrier. Through this process, each of a plurality of fifth openings OP5 extending into the first stack ST1 and exposing different layers of the plurality of first material layers 161 may be formed. The fifth opening OP5 may be formed by extending at least one of the first to fourth openings OP1 to OP4 or may be newly formed in the second stack ST2 and the first stack ST1. Subsequently, the fifth mask pattern 175 may be removed.

Referring to FIG. 17G, an insulating liner 176 and a sacrificial layer 177 may be formed in each of the first openings OP1, the second openings OP2, the third openings OP3, the fourth openings OP4, and the fifth openings OP5. As an example, each of the sacrificial layers 177 may comprise tungsten. In a process of forming the insulating liners 176 and the sacrificial layers 177, the hard mask pattern 166 may be removed. Subsequently, the first material layers 161 and the second material layers 163 may be replaced with third material layers 167. Through this process, a first gate structure GST1 may be formed including the plurality of third material layers 167 that are alternately stacked with the plurality of first insulating layers 162. The third material layers 167 of the first gate structure GST1 may be first conductive layers. A second gate structure GST2 may be formed including the plurality of third material layers 167 that are alternately stacked with the plurality of second insulating layers 164. The third material layers 167 of the second gate structure GST2 may be second conductive layers.

Subsequently, a first slit structure 168 may be formed in the second gate structure GST2. The first slit structure 168 may be formed at a depth through a third material layer 167 corresponding to a drain select line among the third material layers 167 and is located on a third material layer 167 corresponding to a word line among the third material layers 167.

Referring to FIG. 17H, the sacrificial layers 177 may be removed. Subsequently, insulating spacers 176A are formed by etching the insulating liners 176. Through this process, each of the third material layers 167 is exposed.

Subsequently, contact plugs 178 are formed. Each of the contact plugs 178 is electrically connected to a different one of the third material layers 167 of the second gate structure GST2 or a different one of the third material layers 167 of the first gate structure GST1.

According to the manufacturing method described above, the contact plugs 178 may be connected to the third material layers 167 without patterning the stacks ST1 and ST2 in a stair shape. Accordingly, manufacturing cost may be reduced, and wafer warpage may be improved. In addition, the contact plugs 178 may be formed at desired locations and at desired depths using a plurality of mask patterns 171, 172, 173, 174, and 175.

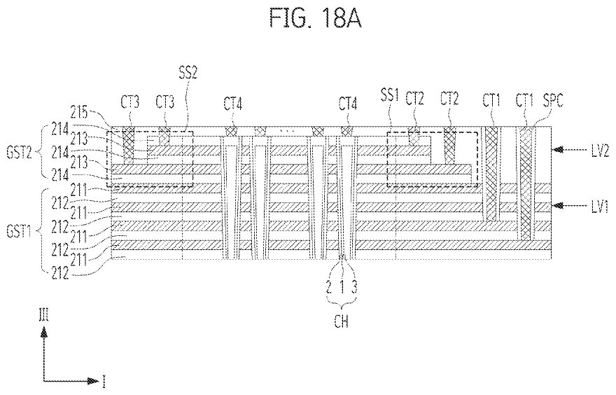

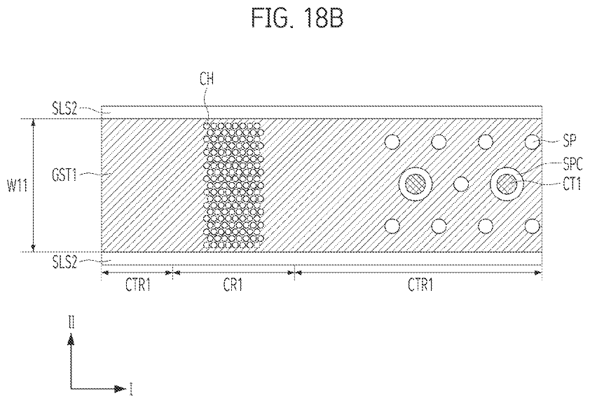

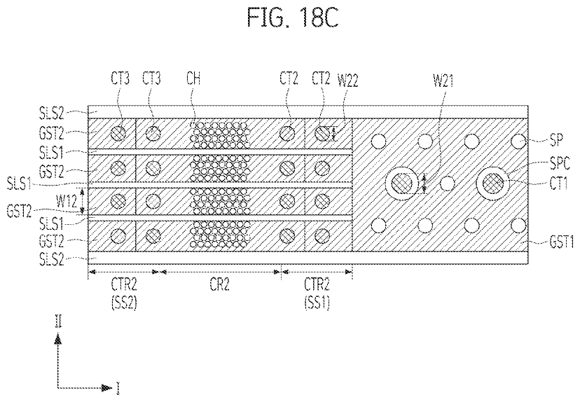

FIG. 18A through FIG. 18C are diagrams illustrating the structure of a semiconductor device in accordance with an embodiment. FIG. 18B is a cross-section taken at a first level LV1 of FIG. 18A, and FIG. 18C is a cross-section taken at a second level LV2 of FIG. 18A.

Referring to FIG. 18A through 18C, the semiconductor device includes at least one of a first gate structure GST1, a second gate structure GST2, a channel structure CH, an interlayer insulating layer 215, a support SP, an insulating spacer SPC, at least one first contact plug CT1, at least one second contact plug CT2, at least one third contact plug CT3, and at least one fourth contact plug CT4.

The first gate structure GST1 includes a plurality of stacked first gate lines 211. The first gate structure GST1 includes the first gate lines 211 that are alternately stacked with a plurality of first insulating layers 212. The first gate lines 211 may be word lines, select lines, dummy gate lines, or the like. The select line may be a source select line or a drain select line. Each of the first gate lines 211 may comprise polysilicon, tungsten, molybdenum, or the like.

The first gate structure GST1 includes a first cell region CR1 and first contact regions CTR1. As an example, the first cell region CR1 may be located between a pair of first contact regions CTR1. The channel structures CH are located in the first cell region CR1, and the first contact plugs CT1 are located in one of the first contact regions CTR1.

The first gate structure GST1 extends in the first direction I. The first cell region CR1 may be adjacent to the first contact region CTR1 in the first direction I. The first gate structure GST1 has a first width W11 in the second direction II, which second direction II intersects the first direction I. The first gate structure GST1 is shown without a stair structure and has a flat upper (outer) surface. The first gate lines 211 may have substantially the same length in the first direction I.

The first gate structure GST1 is located between second slit structures SLS2 as shown in FIG. 18B. A plurality of first gate structures GST1 may be isolated from each other by the second slit structures SLS2. The second slit structures SLS2 extend in the first direction. The second slit structures SLS2 may include an insulating layer or may include a source contact structure and an insulating spacer.

The second gate structure GST2 includes a plurality of stacked second gate lines 213. The second gate structure GST2 includes the second gate lines 213 that are alternately stacked with a plurality of second insulating layers 214. The second gate lines 213 may be word lines, select lines, or the like. The select line may be a source select line or a drain select line. As an example, the first gate lines 211 may be word lines, and the second gate lines 213 may be select lines.

The second gate structure GST2 includes a second cell region CR2 and second contact regions CTR2. As an example, the second cell region CR2 may be located between a pair of second contact regions CTR2. The channel structures CH are located in the second cell region CR2, at least one of the second contact plugs CT2 is located in one of the second contact regions CTR2, and at least one of the third contact plugs CT3 is located in another second contact region CTR2 as shown in FIG. 18C. The second gate structure GST2 includes at least one of a first stair structure SS1 and a second stair structure SS2. The first stair structure SS1 and the second stair structure SS2 are located in two different second contact regions CTR2 as shown in FIG. 18C. Because the second contact regions CTR2 include stair structures SS1 and SS2, the second gate lines 123 may have different lengths in the first direction I.

The second gate structure GST2 extends in the first direction I. The second cell region CR2 may be adjacent to the second contact region CTR2 in the first direction I. The second gate structures GST2 have a second width W12 in the second direction II. The second width W12 may be smaller than the first width W11.

The second gate structure GST2 is located between first slit structures SLS1. A plurality of second gate structures GST2 may be isolated from each other by the first slit structures SLS1. At least one first slit structure SLS1 may be located between a pair of second slit structures SLS2. The first slit structure SLS1 extends in the first direction. The first slit structure SLS1 includes an insulating layer.

The channel structures CH extend through the first gate structure GST1 and the second gate structures GST2. The channel structure CH extends through the first cell region CR1 and the second cell region CR2. As an example, the channel structure CH extends in the third direction III. In this example, the third direction III is a direction perpendicular to the plane extending between the first direction I and the second direction II. The channel structures CH include at least one of a channel layer 1, a memory layer 2, and an insulating core 3. The memory layer 2 may include at least one of a tunneling layer, a data storage layer, and a blocking layer. The channel structures CH are located between the first stair structure SS1 and the second stair structure SS2 in this example.

The first contact plugs CT1 are disposed within the first contact region CTR1 of the first gate structure GST1. Each of the first contact plugs CT1 is electrically connected to a different one of the first gate lines 211. As an example, the first contact plugs CT1 may be electrically connected to the word lines. The first contact plug CT1 may have a first width W21.

The first gate structure GST1 has a flat upper surface. Accordingly, the first contact plug CT1 extends into the first gate structure GST1 through the interlayer insulating layer 215 and is connected to one of the first gate lines 211. A plurality of first contact plugs CT1 extends into the first gate structure GST1 at different depths and each of the plurality of first contact plugs CT1 is connected to a different one of the first gate lines 211. The sidewalls of each first contact plug CT1 are individually surrounded by an insulating spacer SPC. The first contact plug CT1 may be spaced apart from the second gate structure GST2.

Each of the second contact plugs CT2 extends through the interlayer insulating layer 215 and is electrically connected to a different one of the second gate lines 213 as shown in FIG. 18A. The second contact plugs CT2 are disposed within the second contact region CTR2 of the second gate structure GST2. As an example, each of the second contact plugs CT2 may be electrically connected to a different one of the select lines. The second contact plug CT2 has a second width W22 smaller than the first width W21.

Each of the second contact plugs CT2 is connected to a different one of the second gate lines 213 terminated or ending within the first stair structure SS1. Because the second gate lines 213 are each terminated within the first stair structure SS1, the second contact plugs CT2 shown in FIG. 18A do not extend into the second gate structure GST2 but are located on a surface of and connect to the second gate structure GST2.

Each of the third contact plugs CT3 extend through the interlayer insulating layer 215 and is electrically connected to a different one of the second gate lines 213 as shown in FIG. 18A. Each of the third contact plugs CT3 is connected to a different one of the second gate lines 213 terminated within the second stair structure SS2. Because the second gate lines 213 are each terminated within the second stair structure SS2, the third contact plugs CT3 do not extend into the second gate structure GST2 but are located on a surface of and connect to the second gate structure GST2. As an example, one of the third contact plugs CT3 may be electrically connected to one of the select lines.

In the example of FIG. 18A, the second gate structure GST2 includes both the first stair structure SS1 and the second stair structure SS2. One end of the second gate lines 213 is terminated within the first stair structure SS1, and the other end of the second gate lines 213 is terminated within the second stair structure SS2. Accordingly, a first of the second contact plugs CT2 and a first of the third contact plug CT3 are connected to one second gate line 213, and a second of the second contact plugs CT2 and a second of the third contact plug CT3 are connected to another second gate line 213. A bias may be applied to the second gate line 213 in either of two directions through the second contact plug CT2 and the third contact plug CT3.

The fourth contact plugs CT4 are connected to the channel structures CH. The fourth contact plugs CT4 may be located between the second contact plugs CT2 and the third contact plugs CT3.

The supports SP extend through the interlayer insulating layer 215 and the first gate structure GST1. The supports SP are located in a first contact region CTR1 of the first gate structure GST1. The supports SP may be arranged between the first contact plugs CT1 and/or around the first contact plugs CT1. As an example, the support SP may have a structure similar to that of the channel structure SH and may have a dummy channel layer. Each support SP may include a contact plug or may include a contact plug and an insulating spacer. For simplicity of the drawing, FIG. 18A illustrates the first contact plugs CT1, the second contact plugs CT2, the third contact plugs, and the fourth contact plugs CT4 for convenience of explanation, but does not illustrate the supports SP.

According to the structure described above, the semiconductor device may include the first gate structure GST1 and the second gate structure GST2 having different widths. The second gate structure GST2 may have a smaller width than the first gate structure GST1. Because the first contact region CTR1 of the first gate structure GST1 has a relatively larger width, even though the first gate structure GST1 does not include a stair structure, the first gate line 211 may connect to the first contact plug CT1 by extending the first contact plug CT1 into the first gate structure GST1. Because the second contact region CTR2 of the second gate structure GST2 has a relatively small width, space for extending the second contact plug CT2 into the contact region CTR2 may not be sufficient. Accordingly, the second gate line 213 may be connected to the second contact plug CT2 by terminating the second gate lines 213 within the first stair structure SS1 and/or the second stair structure SS2.

The second gate structure GST2 may have a smaller width than the first gate structure GST1, and widths of the second contact plugs CT2 and/or the third contact plugs CT3 may be smaller than the widths of the first contact plugs CT1. By connecting the second contact plugs CT2 to the second gate structure GST2 through the first stair structure SS1 and/or the second stair structure SS2 and terminating the gate lines within the stair structure(s), the second contact plugs CT2 may be connected to gates lines within the second contact region CTR2 having a relatively smaller area. The stair structures facilitate first contact plugs CT1 having a larger width than may be formed through the second gate structure GST2 because the first contact plugs CT1 are located outside the stair structures.

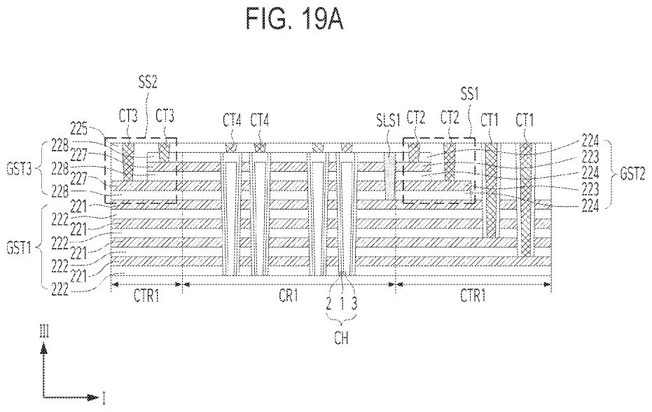

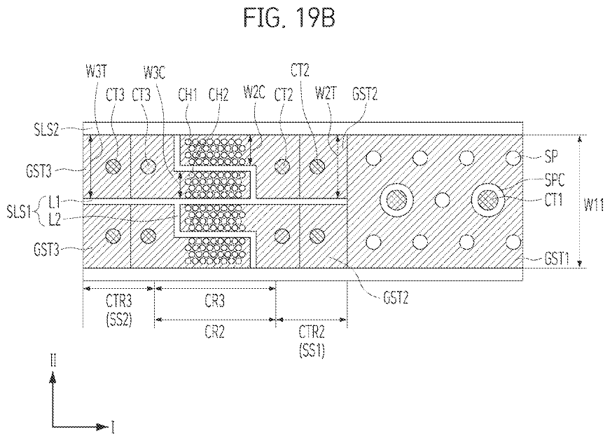

FIG. 19A and FIG. 19B are diagrams illustrating the structure of a semiconductor device in accordance with an embodiment.

Referring to FIG. 19A and FIG. 19B, the semiconductor device includes at least one of a first gate structure GST1, a second gate structure GST2, a third gate structure GST3, a first channel structure CH1, a second channel structure CH2, a support SP, an interlayer insulating layer 225, an insulating spacer SPC, at least one first contact plug CT1, at least one second contact plug CT2, at least one third contact plug CT3, and at least one fourth contact plug CT4.

The first gate structure GST1 does not have a stair shape and has a flat upper surface. The second gate structure GST2 includes a first stair structure SS1 located in a second contact region CTR2. The third gate structure GST3 includes a second stair structure SS2 located in a third contact region CTR3.

The first gate structure GST1 includes first gate lines 221 that are alternately stacked with first insulating layers 222. The second gate structure GST2 includes second gate lines 223 that are alternately stacked with second insulating layers 224. The third gate structure GST3 includes third gate lines 227 that are alternately stacked with third insulating layers 228. As an example, the first gate lines 221 may be word lines, and the second gate lines 223 and the third gate lines 227 may be select lines.

Each of the first contact plugs CT1 extends at a different depth through the first gate structure GST1 and is electrically connected to a different one of the first gate lines 221. Each of the second gate lines 223 is terminated or ends within the first stair structure SS1 of the second gate structure GST2, and each of the second contact plugs CT2 is electrically connected to a different one of the second gate lines 223 terminated within the first stair structure SS1. Each of the third gate lines 227 is terminated within the second stair structure SS2 of the third gate structure GST3, and each of the third contact plugs CT3 is electrically connected to a different one of the third gate lines 227 terminated within the second stair structure SS2.

The second gate structures GST2 are located or stacked on the first gate structure GST1 and have a smaller width than a width of the first gate structure GST1 is shown in the example of FIG. 19B. The second gate structures GST2 include a second cell region CR2 and the second contact region CTR2. The first channel structures CH1 are located in the second cell region CR2, and the second contact plugs CT2 are disposed within to the second contact region CTR2. The second contact region CTR2 has a smaller width than a width of the first contact region CTR1. The second cell region CR2 may be adjacent to the second contact region CTR2 in the first direction I. The second cell region CR2 has a second width W2C, and the second contact region CTR2 has a second width W2T greater than the second width W2C. Accordingly, enough area where the second contact plugs CT2 are located may be secured.

The third gate structure GST3 is located or stacked on the first gate structure GST1 and has a smaller width than the width W11 of the first gate structure GST1. The third gate structure GST3 includes a third cell region CR3 and a third contact region CTR3. The second channel structure CH2 is located in the third cell region CR3, and the third contact plugs CT3 are disposed within the third contact region CTR3. The third contact region CTR3 has a smaller width than the width of the first contact region CTR1. The third cell region CR3 is adjacent to the third contact region CTR3 in the first direction I. The third cell region CR3 has a third width W3C, and the third contact region CTR3 has a third width W3T greater than the third width W3C. Accordingly, enough area where the third contact plugs CT3 are located may be secured.

The second gate structure GST2 is adjacent to the third gate structure GST3 in the first direction I. The second cell region CR2 and the third cell region CR3 are located between the second contact region CTR2 and the third contact region CTR3. The second gate structure GST2 and the third gate structure GST3 may be arranged to be engaged or fit with each other. As an example, the second contact region CTR2 and the third contact region CTR3 are spaced apart in the first direction I by either the second cell region CR2 or the third cell region CR3, and the second cell region CR2 and the third cell region CR3 are adjacent to each other in the second direction II.

The second gate structure GST2 and the third gate structure GST3 are isolated from each other by a first slit structure SLS1. The first slit structure SLS1 includes a first line section L1 and a second line section L2. The first line section L1 extends in the first direction I. As an example, the first line section L1 extends between second gate structures GST2 adjacent to each other in the second direction II and between third gate structures GST3 adjacent to each other in the second direction II.

The second line section L2 extends between the second gate structure GST2 and the third gate structure GST3 where the second gate structure GST2 and the third gate structure GST3 are adjacent to each other in the first direction I. As an example, the second line section L2 extends between the second cell region CR2 and the third contact region CTR3, between the second cell region CR2 and the third cell region CR3, and between the second contact region CTR2 and the third cell region CR3. The second line section L2 may be connected to the first line section L1.

In a device formed according to the structure described above, a first memory string including the first channel structures CH1 may be controlled by a bias, such as a voltage or current bias, transmitted through the second contact plug CT2. A second memory string including the second channel structure CH2 may be controlled by a bias transmitted through the third contact plug CT3. As an example, a bias may be applied to a drain select line of the first memory string via the second contact plug CT2, and the bias may be applied to a drain select line of the second memory string via the third contact plug CT3.

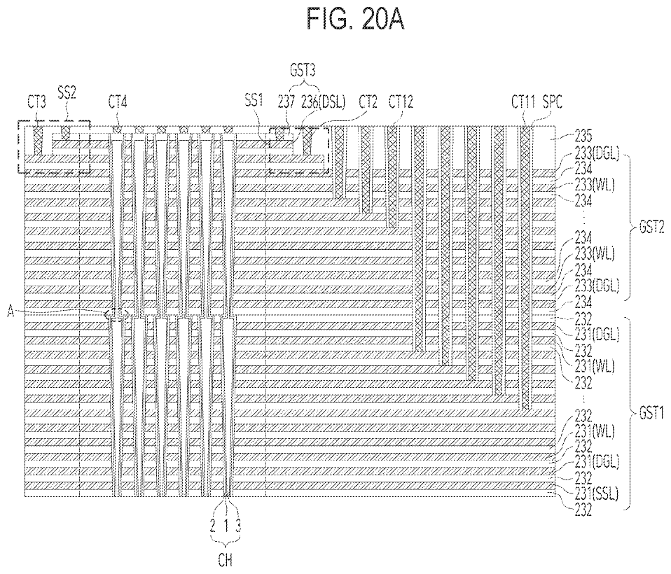

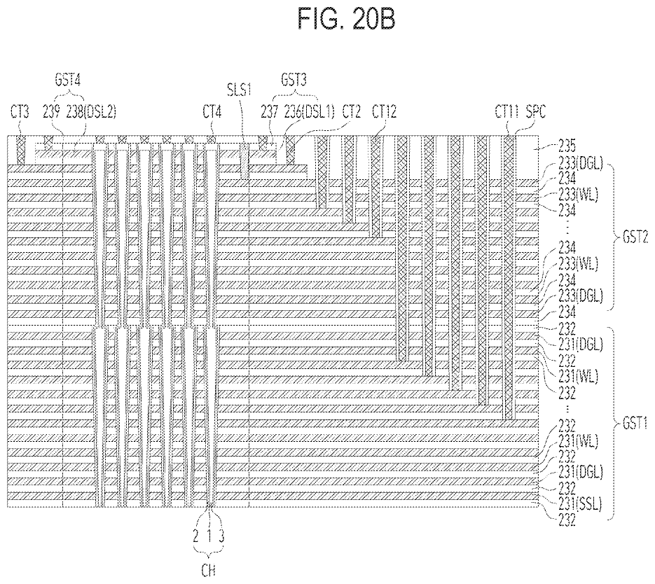

FIG. 20A and FIG. 20B are cross-sectional views illustrating the structure of a semiconductor device in accordance with an embodiment.

Referring to FIG. 20A, the semiconductor device includes a first gate structure GST1, a second gate structure GST2, a third gate structure GST3, at least one channel structure CH, at least one insulating spacer SPC, an interlayer insulating layer 235, at least one first contact plug CT11 at least one first contact plug CT12, at least one second contact plug CT2, at least one third contact plug CT3, and at least one fourth contact plug CT4.

The first gate structure GST1 includes a plurality of first gate lines 231 that are alternately stacked with a plurality of first insulating layers 232. As an example, at least one lowermost first gate line 231 may be a source select line SSL, and the remaining first gate lines 231 may be word lines WL. The second gate structure GST2 may include second gate lines 233 that are alternately stacked with second insulating layers 234. As an example, the second gate lines 233 may be word lines WL. The third gate structure GST3 may include third gate lines 236 that are alternately stacked with third insulating layers 237. As an example, the third gate lines 236 may be drain select lines.

At least one of the first gate lines 231, the second gate lines 233, and the third gate lines 236 is a dummy gate line DGL. As an example, the dummy gate line DGL may be located at at least one of a location between the source select line SSL and the word line WL, a location between the drain select line DSL and the word line WL, and an interface between the first gate structure GST1 and the second gate structure GST2.

The third gate structure GST3 includes at least one of a first stair structure SS1 and a second stair structure SS2. As an example, one end of the drain select line DSL is terminated within the first stair structure SS1 and the other end of the drain select line DSL is terminated within the second stair structure SS2.

The channel structure CH extends through the first gate structure GST1, the second gate structure GST2, and the third gate structure GST3. The channel structure CH has an inflection portion A at or near an interface between the first gate structure GST1 and the second gate structure GST2.

The first contact plugs CT11 are formed through the second gate structure GST2 and extend into the first gate structure GST1. Each different first contact plug CT11 extends at a different depth into the first gate structure GST1 and is connected to a different one of the first gate lines 231. For convenience of explanation and simplicity of the drawing, only some of the first contact plugs CT11 are illustrated in FIG. 20A. Each of the first contact plugs CT11 may be electrically connected to a different one of the source select line SSL, the dummy gate lines DGL, or the word lines WL.

Each different first contact plug CT12 extends at different depth into the second gate structure GST2, and is connected to a different one of the second gate lines 233. For convenience of explanation and simplicity of the drawing, only some of the first contact plugs CT12 are illustrated in FIG. 20A. Each of the first contact plugs CT12 is electrically connected to a different one of the word lines WL or the dummy gate lines DGL. The second contact plug CT2 is connected to a first end of the drain select line DSL within the first stair structure SS1. The third contact plug CT3 is connected to a second end of the drain select line DSL within the second stair structure SS2.

Referring to FIG. 20B, the semiconductor device further includes a fourth gate structure GST4 located or stacked on the second gate structure GST2. The fourth gate structure GST4 includes fourth gate lines 238 that are alternately stacked with fourth insulating layers 239. As an example, the third gate lines 236 may be first drain select lines DSL1, and the fourth gate lines 238 may be second drain select lines DSL2.

The third gate structure GST3 and the fourth gate structure GST4 are isolated from each other by a first slit structure SLS1. A bias may be applied to the first drain select line DSL1 via the second contact plug CT2, and a bias may be applied to the second drain select line DSL2 via the third contact plug CT3.

According to the structure described above, the semiconductor device may include a plurality of gate structures, and contact plugs may be connected in different manners depending on the shapes of the gate structures. When a gate structure does not include a stair structure, contact plugs may be connected in a structure that extends into the gate structure. When a gate structure has a stair structure, contact plugs may be connected via the stair structure. A connection manner of the contact plugs may be determined based on a width of the gate structure, a width of the contact region, and the like.

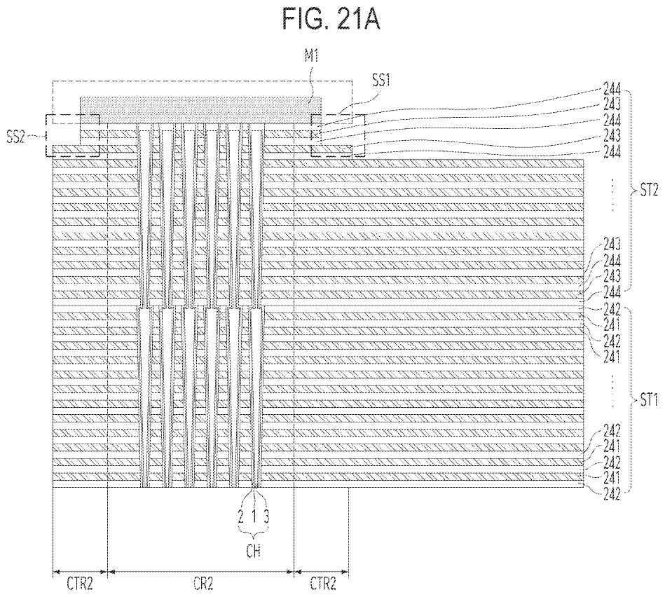

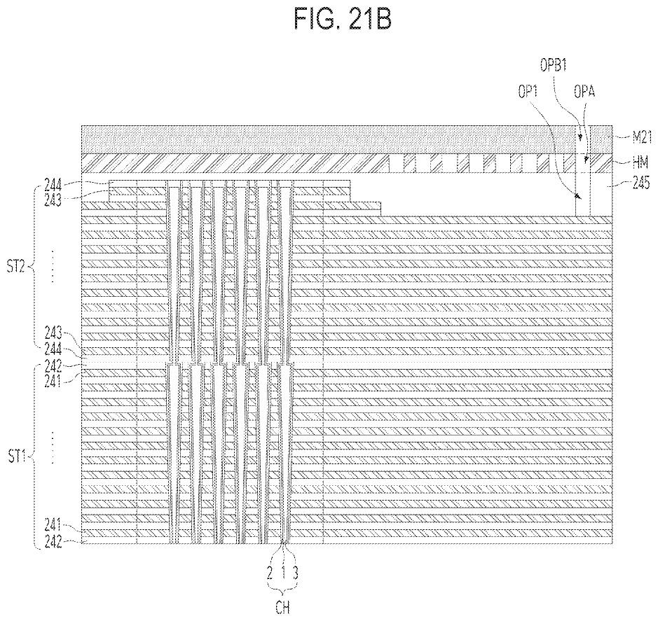

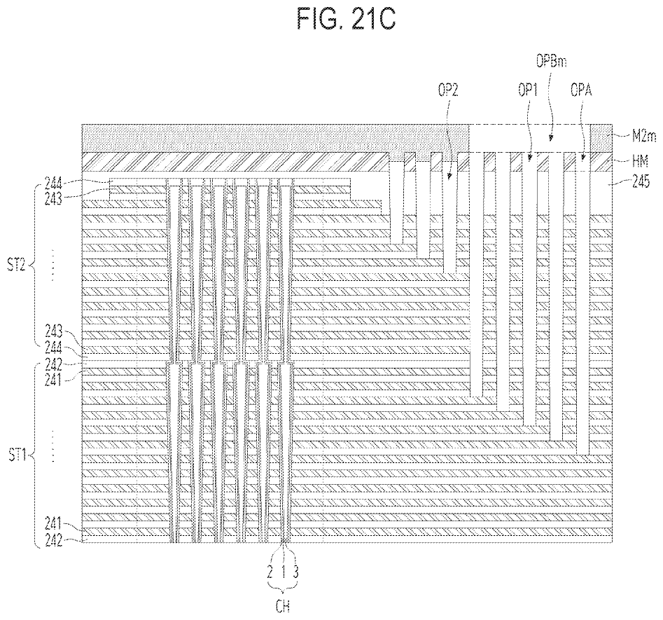

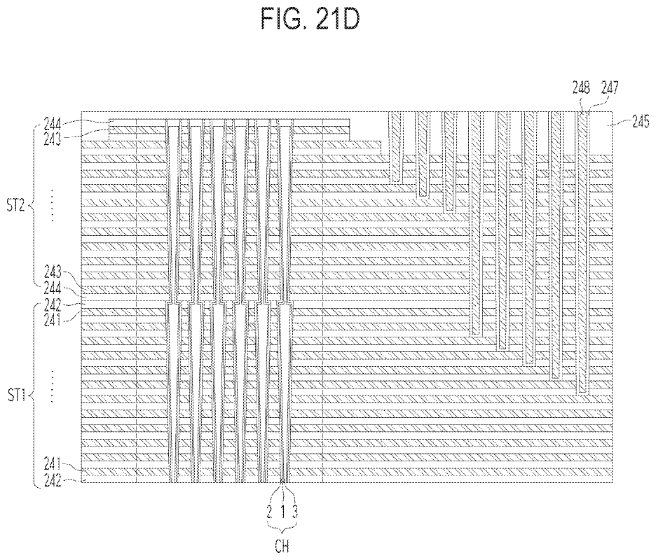

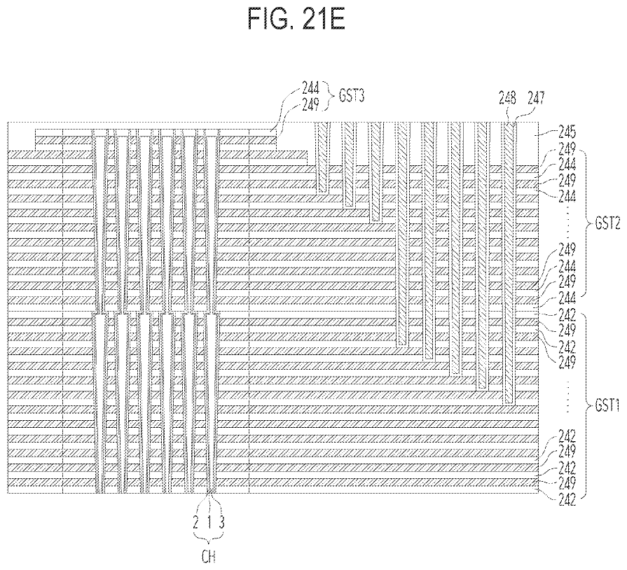

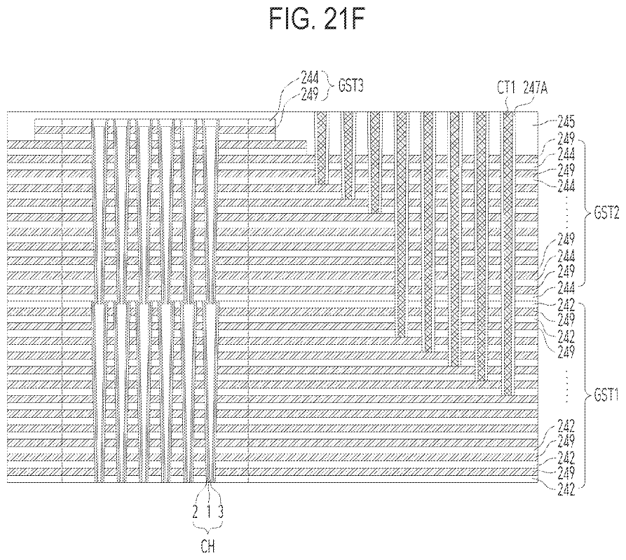

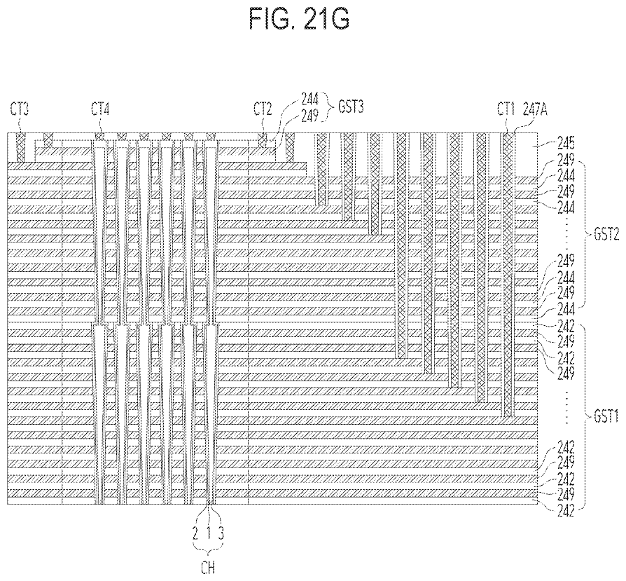

FIG. 21A through FIG. 21G are diagrams illustrating various views of a semiconductor device formed using a method of manufacturing a semiconductor device in accordance with an embodiment.

Referring to FIG. 21A, a first stack ST1 is formed. The first stack ST1 includes first material layers 241 that are alternately stacked with first insulating layers 242. Subsequently, a second stack ST2 is formed on or over the first stack ST1. The second stack ST2 includes second material layers 243 that are alternately stacked with second insulating layers 244. In this example, the first material layers 241 and the second material layers 243 may be used to form gate lines. The first insulating layers 242 and the second insulating layers 244 insulate the stacked gate lines from each other. Each of the first material layers 241 and each of the second material layers 243 may comprise a material having a high etching selectivity with respect to the etching selectivity of the first insulating layers 242 and the second insulating layers 244. As an example, each of the first material layers 241 and each of the second material layers 243 may comprise a sacrificial material such as a nitride or a conductive material such as polysilicon or metal. Each of the first insulating layers 242 and each of the second insulating layers 244 may comprise an insulating material such as an oxide, a nitride, or a void.

Subsequently, a channel structure CH extending through the second stack ST2 and the first stack ST1 is formed. The channel structure CH extends into the first stack ST1 through a second cell region CR2 of the second stack ST2. The channel structure CH may include at least one of a channel layer 1, a memory layer 2, and an insulating core 3.

Subsequently, at least a portion of the second stack ST2 is formed or patterned in a stair shape. As an example, a first mask pattern M1 (shown by the dashed lines in FIG. 21A) is formed on the second stack ST2, and the second stack ST2 is etched using the first mask pattern M1 as an etching barrier. The first mask pattern M1 has a shape that covers the second cell region CR2 and exposes at least a portion of a second contact region CTR2. The first mask pattern M1 exposes regions where first contact plugs will be formed later. Subsequently, the first mask pattern M1 is reduced in size or shrunk (shown by the shaded area), and the second stack ST2 is etched. The mask pattern M1 may be shrunk on one or both sides, depending on how many stairs are to be formed by the mask on each side. A stair structure is formed by repeatedly performing the reduction or shrinking of the first mask pattern M1 and the etching. As an example, a reduction and etching process may be repeated n times, where n is an integer having a value of 2 or more. Through this process, at least one of a first stair structure SS1 and a second stair structure SS2 are formed. Subsequently, the first mask pattern M1 may be removed.

Referring to FIG. 21B, an interlayer insulating layer 245 is formed on or over the second stack ST2 including the stair structure. The interlayer insulating layer 245 may include an oxide. Subsequently, a hard mask pattern HM may be formed on the interlayer insulating layer 245. The hard mask pattern HM includes openings OPA exposing regions where first contact plugs are to be formed. As an example, the hard mask pattern HM may include polysilicon.

Subsequently, a second mask pattern M21 may be formed on the hard mask pattern HM. The second mask pattern M21 may include at least one opening OPB1 exposing at least one of the openings OPA. The second mask pattern M21 covers the remaining openings OPA, and a material of the second mask pattern M21 may be formed in the openings OPA covered by the second mask pattern M21. The second mask pattern M21 may comprise a photoresist.

Subsequently, the interlayer insulating layer 245 and the second stack ST2 are etched using the hard mask pattern HM and the second mask pattern M21 as an etching barrier. Through this process, a first opening OP1 extending into the second stack ST2 and exposing the second material layer 243 is formed. Subsequently, the second mask pattern M21 may be removed.

Referring to FIG. 21C, a second mask pattern M2m is formed on the hard mask pattern HM. The second mask pattern M2m includes at least one opening OPBm exposing at least some of the openings OPA. Subsequently, the interlayer insulating layer 245 and the second stack ST2 are etched using the hard mask pattern HM and the second mask pattern M2m as an etching barrier. As an example, a process of forming the second mask pattern M2m and an etching process may be repeated m times, where m is an integer having a value of 2 or more.

As described above, by repeating the process of forming the second mask pattern M2m and performing the etching process, first openings OP1 and second openings OP2 are formed. The first openings OP1 extend into the first stack ST1 through the second stack ST2 and expose the first material layers 241. The second openings OP2 extend into the second stack ST2 and expose the second material layers 243. For convenience of explanation and simplicity of the drawing, only some of the second openings OP2 are illustrated in FIG. 21C.

Relative locations of the first openings OP1 and the second openings OP2 may vary. As an example, the first openings OP1 may be located farther from the second cell region CR2 or closer to the second cell region CR2 than where the second openings OP2 are located. Alternatively, the first openings OP1 and the second openings OP2 may be mixed and located, in other words, not all the first openings OP1 may be located in a single group and not all the second openings OP2 may be located in a single group, such that the first openings OP1 are interspersed with the second openings OP1.

Referring to FIG. 21D, an insulating liner 247 is formed in each of the first openings OP1 and in each of the second openings OP2, and a sacrificial plug 248 is formed in each insulating liner 247. As an example, each of the sacrificial plugs 248 may comprise tungsten. During a process of forming the insulating liners 247 and the sacrificial plugs 248, the hard mask pattern HM may be removed.

Referring to FIG. 21E, the first material layers 241 and the second material layers 243 are replaced with third material layers 249. Through this process, a first gate structure GST1 is formed including the third material layers 249 that are alternately stacked with the first insulating layers 242. The third material layers 249 of the first gate structure GST1 may be first gate lines. The first gate lines may be source select lines, word lines, or dummy gate lines. A second gate structure GST2 is formed including the third material layers 249 that are alternately stacked with the second insulating layers 244. The third material layers 249 of the second gate structure GST2 do not have a stair shape and may be second gate lines. The second gate lines may be word lines or dummy gate lines. A third gate structure GST3 is formed including the third material layers 249 that are alternately stacked with the second insulating layers 244. The third material layers 249 of the third gate structure GST3 are stacked in a stair shape and may be third gate lines. The third gate lines may be drain select lines.

The process of replacing the material layers may be omitted when each of the first material layers 241 and the second material layers 243 include a conductive material. In this example, the first material layers 241 and the second material layers 243 may be gate lines, the first stack ST1 may be the first gate structure GST1, and the second stack ST2 may be the second gate structure GST2 and the third gate structure GST3.

Subsequently, although not illustrated in FIG. 21E, a first slit structure may be formed in the third gate structure GST3 at a depth through the drain select lines but not formed at a depth through the word lines.

Referring to FIG. 21F, the sacrificial plugs 248 are removed. Subsequently, insulating spacers 247A are formed by etching the insulating liners 247. Subsequently, a first contact plug CT1 is formed in each of the first openings OP1 and the second openings OP2. Each first contact plug CT1 is electrically connected to a different one of the third material layers 249 having a non-stair shape. As an example, the first contact plugs CT1 may be connected to the source select lines, the word lines, or the dummy gate lines.

Referring to FIG. 21G, at least one of second contact plugs CT2 and third contact plugs CT3 connected to the third material layers 249 having the stair shape is formed. As an example, one second contact plug CT2 connected to a first end of a first of the third material layers 249 and one third contact plug CT3 connected to a second end of the first of the third material layers 249 are formed.

Fourth contact plugs CT4 connected to the channel structures CH are formed. At least one of the third contact plugs CT3 and the fourth contact plugs CT4 may be formed when the second contact plugs CT2 are formed.

According to the manufacturing method described above, at least one level of the stacks ST1 and ST2 may be patterned in a stair shape and the remaining levels of the stacks ST1 and ST2 may be maintained without a stair shape. Accordingly, contact plugs may be formed in an appropriate structure according to shapes within corresponding gate structures. When a gate structure does not have a stair shape, a contact plug may be formed in a structure that extends into the gate structure. When a gate structure has a stair shape, a contact plug may be connected via a stair structure.

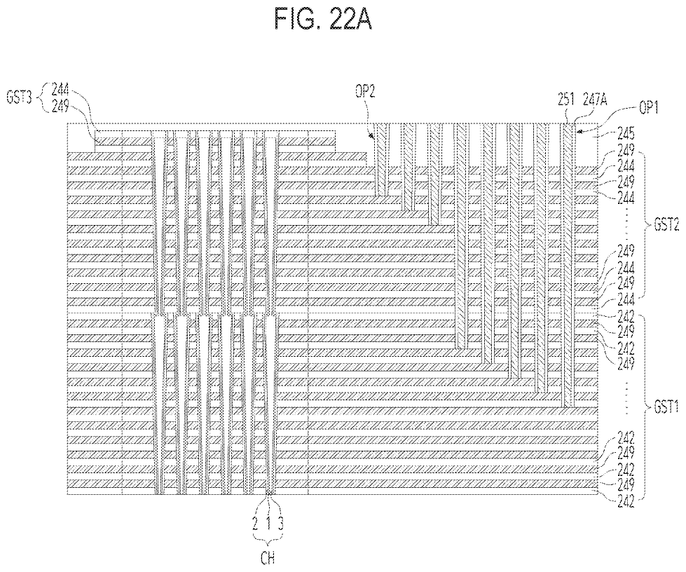

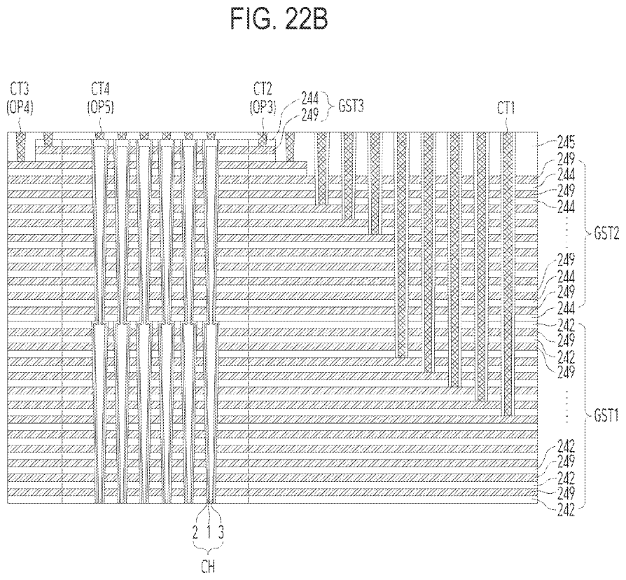

FIG. 22A and FIG. 22B are diagrams illustrating various views of a semiconductor device formed using a method of manufacturing a semiconductor device in accordance with an embodiment.

FIG. 22A is a diagram corresponding to FIG. 21F described above. Insulating spacers 247A may be formed by etching the insulating liner 247. The first material layers 249 (241) may be exposed through the first openings OP1, and the second material layers 249 (243) may be exposed through the second openings OP2. Subsequently, sacrificial layers 251 may be formed in the first openings OP1 and the second openings OP2.

Referring to FIG. 22B, each of the third openings OP3 and the fourth openings OP4 exposing the third material layers 249 having a stair shape are formed by etching the interlayer insulating layer 245. As an example, each third opening OP3 exposing one end of a first of the third material layers 249 and each fourth opening OP4 exposing the other end of the first of the third material layers 249 are formed.

Fifth openings OP5 exposing the channel structures CH are formed by etching the interlayer insulating layer 245. At least one of the fourth openings OP4 and the fifth openings OP5 may be formed when the third openings OP3 are formed, for example, at the same time or simultaneously.

Subsequently, a first contact plugs CT1 is formed in each of the first openings OP1 and each of the second openings OP2. A second contact plug CT2 is formed in each of the third openings OP3. A third contact plug CT3 is formed in each of the fourth openings OP4. A fourth contact plug CT4 is formed in each of the fifth openings OP5. At least one of the second contact plugs CT2, the third contact plugs CT3, and the fourth contact plugs CT4 may be formed when the first contact plugs CT1 are formed.

According to the manufacturing method described above, contact plugs having different shapes or structures may be formed at the same time. Accordingly, the manufacturing process may be simplified, and manufacturing costs may be reduced.

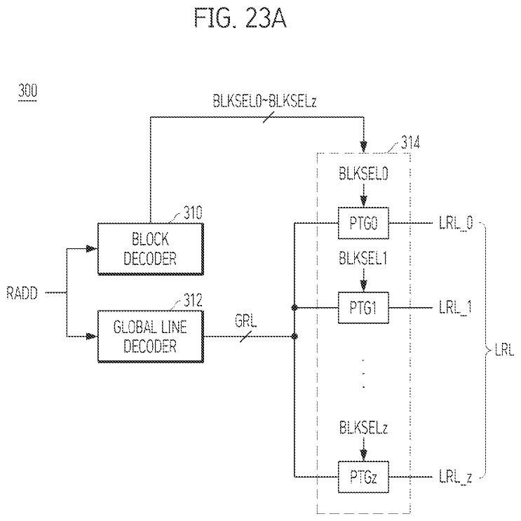

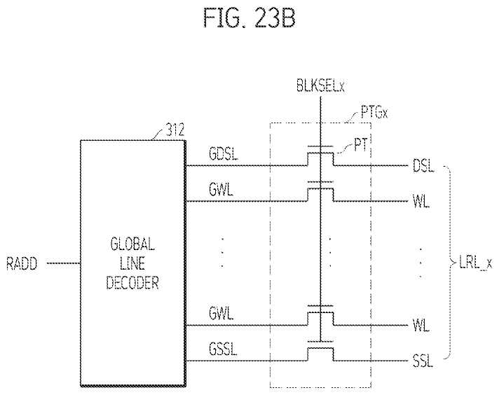

FIG. 23A and FIG. 23B are diagrams illustrating the configuration of a semiconductor device in accordance with an embodiment and are block diagrams of a row decoder.

Referring to FIG. 23A, the semiconductor device includes a row decoder 300, and the row decoder 300 includes a block decoder 310, a global line decoder 312, and a switch circuit 314. The row decoder 300 decodes a row address RADD and selects one memory block included in a cell array according to the decoded row address RADD. The row decoder 300 transmits or applies an operation voltage provided from a voltage generator to local row lines LRL_0 to LRL_z of the selected memory block, where z is an integer having a value of 2 or more.

The block decoder 310 generates block select signals BLKSEL0 to BLKSELz by decoding the row address RADD. The block select signals BLKSEL0 to BLKSELz may be used to select a memory block of which local row lines LRL are to be connected to global row lines GRL among the memory blocks included in the cell array. The block select signals BLKSEL0 to BLKSELz may include information for the selected memory block.

The global line decoder 312 drives the global row lines GRL by decoding the row address RADD.

The switch circuit 314 connects the global low lines GRL to the local low lines LRL in response to the block select signals BLKSEL0 to BLKSELz. The switch circuit 314 includes pass transistor groups PTG0 to PTGz respectively corresponding to the memory blocks. When the block select signal BLKSEL0 is activated, pass transistors of the pass transistor group PTG0 are turned on, and the global low lines GRL may be connected to the local low lines LRL_0. Likewise, when the block select signal BLKSELz is activated, pass transistors of the pass transistor group PTGz are turned on, and the global low lines GRL are connected to the local low lines LRL_z.

Referring to FIG. 23B, the global line decoder 312 drives a global row line GRL including at least one global drain select line GDSL, global word lines GWL, and at least one global source select line GSSL. Pass transistors PT of a pass transistor group PTG_x electrically connect the global low line GRL to a local low line LRL_x in response to a voltage level of a block select signal BLKSEL_x, where x is an integer having a value of 0 or more and z or less.

According to the configuration described above, the semiconductor device may include a peripheral circuit region where a peripheral circuit including the row decoder 300 is located and a cell region where the cell array including the local row lines LRL is located. In this example, the peripheral circuit region and the cell region may be located on the same plane or be located on different planes. As an example, the peripheral circuit region and the cell region may be stacked and located in a vertical direction. In this example, the pass transistor groups PTG0 to PTGz and the local low lines LRL may be connected to each other through an interconnection structure. The interconnection structure may include a contact plug, a wiring line, and the like.

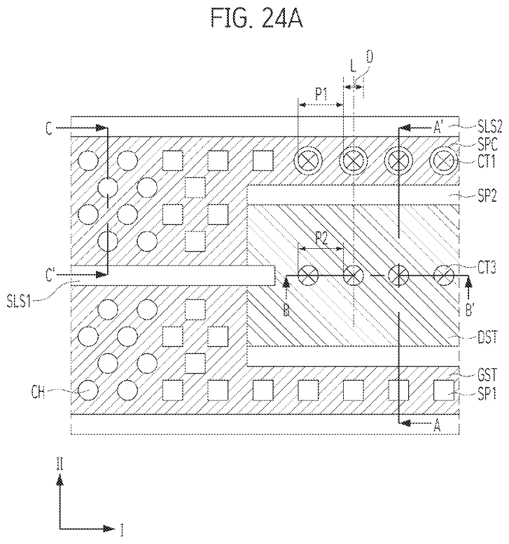

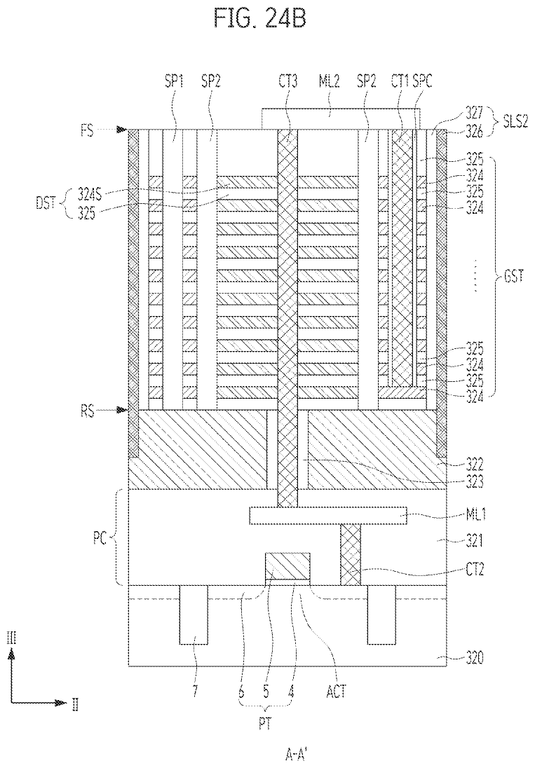

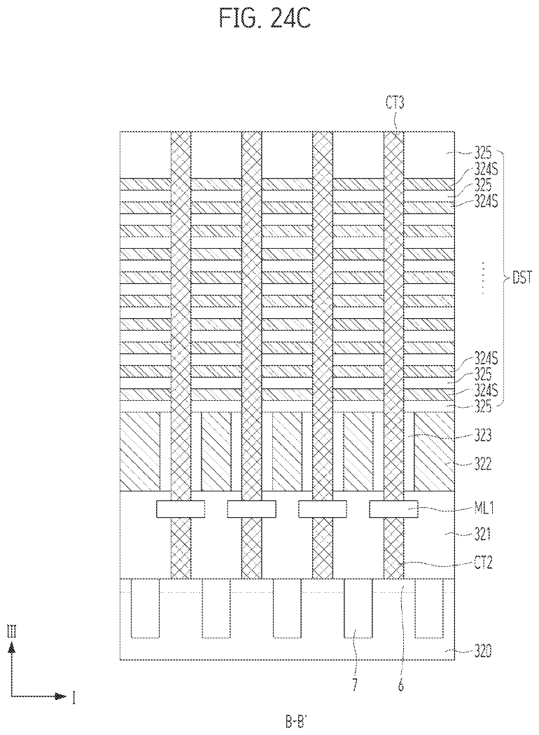

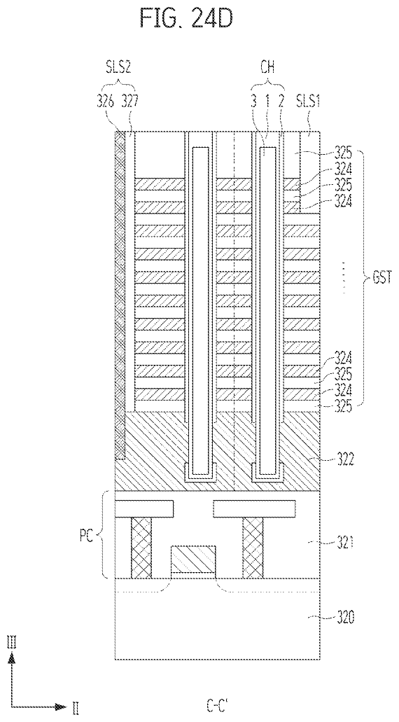

FIG. 24A through FIG. 24D are diagrams illustrating the structure of a semiconductor device in accordance with an embodiment.

Referring to FIG. 24A through FIG. 24D, the semiconductor device may include a gate structure GST, a first contact plug CT1, and a peripheral circuit PC. The semiconductor device may include at least one of a substrate 320, an element isolation layer 7, an interlayer insulating layer 321, a second contact plug CT2, a third contact plug CT3, a first wiring line ML1, a second wiring line ML2, a dummy stack DST, a source structure 322, an insulating layer 323, a slit structure SLS1 and SLS2, an insulating spacer SPC, and a support SP1 and SP2.

The peripheral circuit PC may be located on the substrate 320, and may include a pass transistor PT. The element isolation layer 7 may be located in the substrate 320, and an active region ACT may be defined by the element isolation layer 7. The pass transistor PT may be located in the active region ACT of the substrate 320. The pass transistor PT may include a gate insulating layer 4, a gate electrode 5, and a junction 6. The junction 6 may be located in the active region ACT.

The interlayer insulating layer 321 may be located on the substrate 320. The second contact plug CT2 and the first wiring line ML1 may be located in the interlayer insulating layer 321, and the second contact plug CT2 may be connected to the junction 6 of the pass transistor PT.

The source structure 322 may be located on the interlayer insulating layer 321. The source structure 322 may comprise a conductive material such as polysilicon or metal. The gate structure GST may be located on the source structure 322. The gate structure GST may include stacked gate lines 324. As an example, the gate lines 324 are alternately stacked with insulating layers 325. The gate lines 324 may extend in the first direction I. The gate lines 324 may be local low lines such as source select lines, drain select lines, or word lines. Each of the gate lines 324 may comprise a conductive material such as polysilicon, tungsten, or molybdenum.

A plurality of channel structures CH may extend through the gate structure GST. The channel structures CH are formed through the gate structure GST and may extend into the source structure 322. The channel structure CH may include at least one of a channel layer 1, a memory layer 2, and an insulating core 3. The source structure 322 is formed through the memory layer 2 and is directly connected to the channel layer 1. The channel layer 1 may optionally be connected to the source structure 322 or the substrate through an epitaxial pattern. The peripheral circuit PC may be located below the channel structure CH. As an example, the peripheral circuit PC may include a page buffer.

A second slit structure SLS2 may extend in the first direction I and may isolate gate structures GST adjacent to each other in the second direction II that intersects the first direction I. The second slit structure SLS2 may include at least one of an insulating material, a semiconductor material, and a conductive material. As an example, the second slit structure SLS2 includes a source contact structure 326 and an insulating spacer 327. the second slit structure SLS2 may optionally include at least one of an insulating material and a semiconductor material as a gap fill material.

A first slit structure SLS1 may be located between the channel structures CH and between first supports SP1. In a plan view, the first slit structure SLS1 may extend in the first direction I and may protrude into the dummy stack DST. The first slit structure SLS1 may have a different height from the second slit structure SLS2. As an example, the first slit structure SLS1 is formed through the drain select line but is not formed through the word lines.

The first supports SP1 may be located near or around the dummy stack DST. In the plane extending between the first direction I and the second direction II, the first support SP1 may have a shape such as a circular shape, an elliptical shape, or a polygonal shape. In a plan view, a second support SP2 may extend in the first direction I. As an example, the dummy stack DST is located between a pair of consecutive second supports SP2 in the second direction II. The dummy stack DST may be located in the gate structure GST and may include stacked sacrificial layers 324S. As an example, the dummy stack DST may share the insulating layers 325 with the gate structure GST and may include the sacrificial layers 324S that are alternately stacked with the insulating layers 325. The sacrificial layers 324S may remain without being replaced with the gate lines 324 during a manufacturing process.

The first contact plug CT1 may extend through the gate structure GST. As an example, the first contact plug CT1 may extend from a first surface, such as a front surface FS, of the gate structure GST toward as second surface, such as a rear surface RS, of the gate structure GST. A plurality of first contact plugs CT1 may extend into the gate structure GST at different depths. The sidewalls of each of the first contact plugs CT1 are individually surrounded by an insulating spacer SPC. The first contact plugs CT1 may be electrically connected to the gate lines 324, respectively.

The first contact plug CT1 and the second contact plug CT2 are located at different levels and may be electrically connected to each other through an interconnection structure. The interconnection structure may include at least one of the third contact plug CT3, the first wiring line ML1, and the second wiring line ML2.

The third contact plug CT3 may extend through the dummy stack DST. The third contact plug CT3 is formed through the dummy stack DST and the source structure 322 and may extend into the interlayer insulating layer 321. The insulating layer 323 may be located between the third contact plug CT3 and the source structure 322. The third contact plug CT3 and the source structure 322 may be insulated from each other by the insulating layer 323.

The first wiring line ML1 may be located in the interlayer insulating layer 321. The third contact plug CT3 may be connected to the second contact plug CT2 through the first wiring line ML1. The second wiring line ML2 may be located on the gate structure GST and/or the dummy stack DST. The third contact plug CT3 may be connected to the first contact plug CT1 through the second wiring line ML2. As an example, the gate line 324 may be connected to the junction 6 of the pass transistor PT through the first contact plug CT1, the second wiring line ML2, the third contact plug CT3, the first wiring line ML1, and the second contact plug CT2.

For reference, when the second contact plug CT2 and the third contact plug CT3 overlap with each other in the third direction III, the second contact plug CT2 and the third contact plug CT3 may be directly connected to each other. In this example, the third direction III is a direction perpendicular to the plane extending between the first direction I and the second direction II and is a vertical direction in the drawings as shown in FIG. 24B, FIG. 24C, and FIG. 24D.

According to the structure described above, the first contact plug CT1, the second contact plug CT2, and the third contact plug CT3 may be located on the same line L extending in the second direction II, for example, aligned along their respective centers, or may be located within a predetermined distance D from the same line L as shown in FIG. 24A. In this example, the predetermined distance D may be a diameter of the first contact plug CT1, a diameter of the second contact plug CT2, or a diameter of the third contact plug CT3. Accordingly, the first contact plug CT1, the second contact plug CT2, and the third contact plug CT3 may be aligned with each other in the second direction II. The first contact plugs CT1 may be aligned in the first direction I and may be spaced apart from each other at a first pitch P1. The third contact plugs CT3 may be arranged in the first direction I and may be located to be spaced apart from each other at a second pitch P2. In the same manner, the second contact plugs CT2 may be arranged in the first direction I and may be located to be spaced apart from each other at the second pitch P2. The first pitch P1 and the second pitch P2 may be substantially the same as or similar to each other. Accordingly, the first wiring line ML1 and the second wiring line ML2 may extend in the second direction II and may not extend in the first direction I or distances of the first wiring line ML1 and the second wiring line ML2 extending in the first direction I may be reduced.

When the first contact plug CT1, the second contact plug CT2, and the third contact plug CT3 are not aligned with each other in the second direction II, the first contact plug CT1, the second contact plug CT2, and the third contact plug CT3 are spaced apart in the first direction I and the second direction II. In such a case, the interconnection structure for connecting the first contact plug CT1 and the third contact plug CT3 to each other may include both a wiring line extending in the first direction I and a wiring line extending in the second direction II. When a spaced distance in the first direction I is great, the number of wiring lines extending in the first direction I may increase. Accordingly, a layout of the wiring lines may become complicated, and an area occupied by the interconnection structure may increase.

According to an embodiment of the present disclosure, because the first contact plug CT1, the second contact plug CT2 and the third contact plug CT3 are aligned with each other in the second direction II, the interconnection structure may not include wiring lines extending in the first direction I or the quantity of wiring lines extending in the first direction I in the interconnection structure may be reduced. As an example, the first wiring line ML1 and the second wiring line ML2 may extend in the second direction II. Accordingly, layout of the wiring lines may be simplified, and an area occupied by the interconnection structure may be reduced.

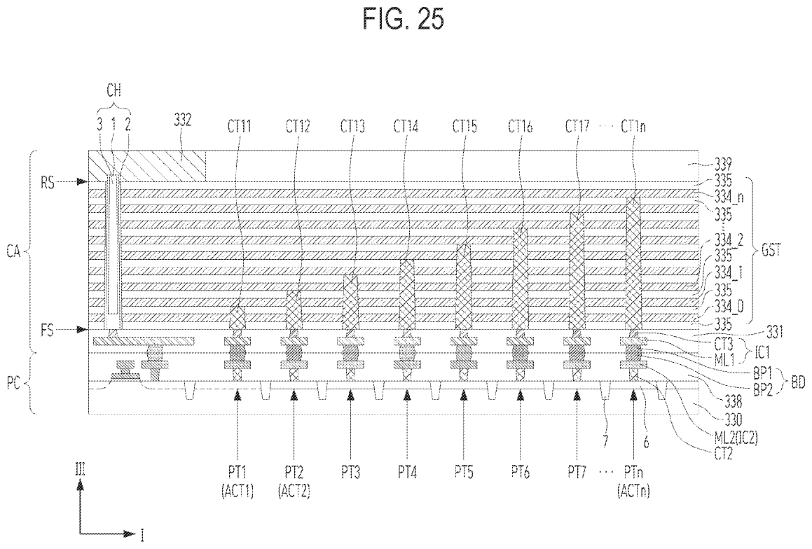

FIG. 25 is a diagram illustrating the structure of a semiconductor device in accordance with an embodiment.

Referring to FIG. 25, the semiconductor device may include a cell array CA, a peripheral circuit PC, and a plurality of bonding structures BD. The bonding structures BD electrically connect the cell array CA and the peripheral circuit PC. The bonding structures BD may each include a first bonding pad BP1, a second bonding pad BP2, and a bonding interface. The bonding interface may be an interface between a first interlayer insulating layer 331 and a second interlayer insulating layer 338.

The cell array CA may include memory cells stacked along a channel structure CH. The peripheral circuit PC may include a circuit for driving the cell array CA. As an example, the peripheral circuit PC may include a page buffer, a row decoder, and the like.

The peripheral circuitry PC may be located on a substrate 330. A substrate may or might not be located on the cell array CA. As an example, after a first wafer including the cell array CA and a second wafer including the peripheral circuit PC are bonded to each other, at least a portion of a substrate of the first wafer may be removed. For example, a source structure 332, a metal wiring line, and the like, of the cell array CA may be formed after the wafers are bonded to each other and at least a portion of the substrate is removed. The source structure 332, the metal wiring line, and the like, may serve as a substrate of the cell array CA.

The semiconductor device may include at least one of the substrate 330, the first interlayer insulating layer 331, the peripheral circuit PC, a gate structure GST, the channel structure CH, the source structure 332, the second interlayer insulating layer 338, an insulating layer 339, first contact plugs CT11 to CT1n, second contact plugs CT2, the bonding structures BD, a plurality of first interconnection structures IC1, and a plurality of second interconnection structures IC2. The gate structure GST, the channel structure CH, the source structure 332, the first interlayer insulating layer 331, and the first contact plugs CT1 may be part of the cell array CA. The first interconnection structures IC1 may be electrically connected to the cell array CA. The second interconnection structures IC2 may be electrically connected to the peripheral circuit PC. The bonding structures BD may be electrically connected to the first interconnection structures IC1 and the second interconnection structures IC2.

The gate structure GST includes gate lines 334_0 to 334_n that are alternately stacked with insulating layers 335. In this example, n is an integer having a value of 1 or more. A first surface, such as a front surface FS, of the gate structure GST may be located close to the bonding structure BD. The source structure 332 may be formed after the wafers are bonded to each other. The source structure 332 may partially or entirely cover a second surface, such as a rear surface RS, of the gate structure GST. The source structure 332 may serve as the substrate of the cell array CA.

The first contact plugs CT11 to CT1n may extend from the front surface FS of the gate structure GST toward the rear surface RS of the gate structure GST. A plurality of first contact plugs CT11 to CT1n may extend into the gate structure GST at different depths and are each electrically connected to a different one of the gate lines 334_1 to 334_n. The first contact plug CT11 may be electrically connected to a first gate line 334_1, the first contact plug CT12 may be electrically connected to a second gate line 334_2, the first contact plug CT1n may be electrically connected to an n-th gate line 334_n, and so forth.

The peripheral circuit PC may include a row decoder, and the row decoder may include a plurality of pass transistors PT1 to PTn. A first pass transistor PT1 may be located in a first active region ACT1 and may at least partially overlap with the first contact plug CT11 in the vertical direction. A second pass transistor PT2 may be located in a second active region ACT2 and may at least partially overlap with the first contact plug CT12 in the vertical direction. An n-th pass transistor PTn may be located in an n-th active region ACTn and may at least partially overlap with the first contact plug CT1n in the vertical direction.

The first pass transistor PT1 may be connected to the first gate line 334_1 through the first contact plug CT11. The first gate line 334_1 may be a local line. The first pass transistor PT1 may control the connection between the first gate line 334_1 and a global line according to a block select signal. The second pass transistor PT2 may be connected to the second gate line 334_2 through the first contact plug CT12. The second pass transistor PT2 may control the connection between the second gate line 334_2 and the global line according to the block select signal. The n-th pass transistor PTn may be connected to the n-th gate line 334_n through the first contact plug CT1n. The n-th pass transistor PTn may control the connection between the n-th gate line 334_n and the global line according to the block select signal.

The first contact plugs CT11 to CT1n and the second contact plugs CT2 may be connected to each other through the first interconnection structures IC1 and the second interconnection structures IC2. The first interconnection structures IC1 may be located in the first interlayer insulating layer 331. Each of the first interconnection structures IC1 may include at least one of a third contact plug CT3 and a first wiring line ML1. Each of the first bonding pads BP1 may be electrically connected to the cell array CA through the first interconnection structures IC1. Each of the second interconnection structures IC2 may include a second wiring line ML2 and may be electrically connected to the peripheral circuit PC through one of the second contact plugs CT2. For example, the second contact plug CT2 may be part of one of the second interconnection structures IC2. The second bonding pads BP2 may be electrically connected to the peripheral circuit PC through the second interconnection structures IC2.

According to the structure described above, the first contact plugs CT11 to CT1n and the second contact plugs CT2 may at least partially overlap with each other in the third direction III. Alternatively, the first contact plugs CT11 to CT1n and the second contact plugs CT2 may be aligned with each other in the second direction II and may be spaced apart from each other in the second direction II. A pitch between the first contact plugs CT11 to CT1n and a pitch between the second contact plugs CT2 may be substantially the same as or similar to each other. The pitch between the first contact plugs CT11 to CT1n and a pitch between the pass transistors PT1 to PTn may be substantially the same as or similar to each other. Accordingly, the first interconnection structure IC1 and the second interconnection structure IC2 may be simplified, and an area occupied by the interconnection structures may be reduced.

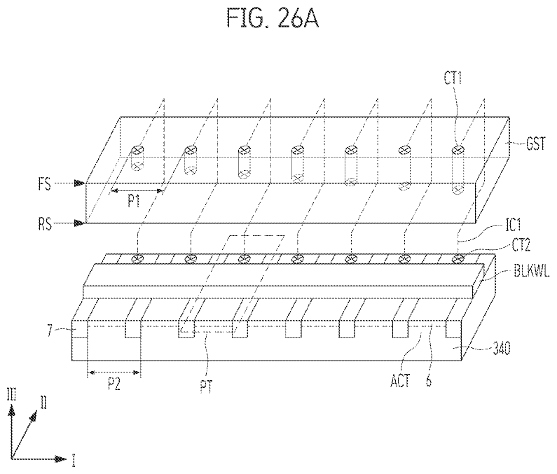

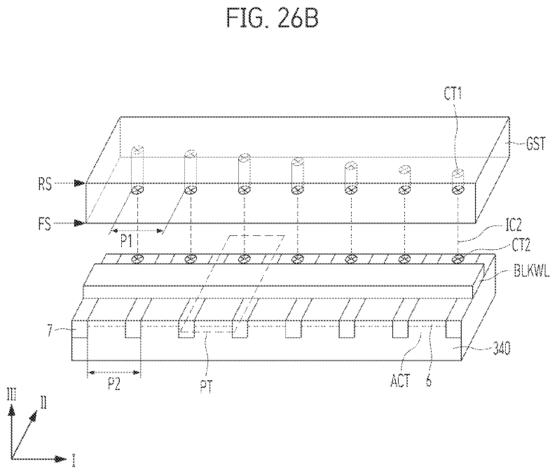

FIG. 26A and FIG. 26B are diagrams illustrating the structure of a semiconductor device in accordance with an embodiment.

Referring to FIG. 26A and FIG. 26B, the semiconductor device may include at least one of a substrate 340, a pass transistor PT, a block word line BLKWL, a gate structure GST, a first contact plug CT1, and a second contact plug CT2.

The gate structure GST may include stacked gate lines. each of the plurality of first contact plugs CT1 may extend into the gate structure GST at a different depth. The first contact plugs CT1 may extend from a first surface, such as a front surface FS, of the gate structure GST toward a second surface, such as a rear surface RS, of the gate structure GST. The first contact plugs CT1 may be aligned in the first direction I and may be spaced apart from each other at a first pitch P1.

The block word line BLKWL may be located on the substrate 340. The block word line BLKWL may be located below the gate structure GST and may face the rear surface RS. The gate structure GST and the block word line BLKWL may extend in the first direction I.

An element isolation layer 7 may be located within the substrate 340, and a junction 6 of a pass transistor PT may be located in an active region ACT. The junction 6 may be an impurity region where N-type or P-type impurities are implanted. The active regions ACT may be adjacent or consecutive in the first direction I and may extend in the second direction II. In this example, the second direction II is perpendicular to the first direction I. The active regions ACT may be spaced apart from each other at a second pitch P2. The second pitch P2 may be substantially the same as the first pitch P1.

The pass transistors PT may be located in each region where an active region ACT and the block word line BLKWL intersect each other. Each of the plurality of pass transistors PT may be located in a different one of the active regions ACT and may be arranged consecutively or adjacent to each other in the first direction I. The pass transistors PT may be spaced apart from each other at the second pitch P2. The second pitch P2 may be substantially the same as the first pitch P1. The pass transistors PT may be connected to the block word line BLKWL. The pass transistors PT may be turned on or off according to a block select signal applied to the block word line BLKWL.

Each of the second contact plugs CT2 may be connected to a different one of the junctions 6 of the pass transistors PT. The second contact plugs CT2 may be arranged in the first direction. Each of the second contact plugs CT2 may be located below a different one of the first contact plugs CT1. The first contact plug CT1 and the second contact plug CT2 may be located on the same line extending in the second direction II. As an example, the first contact plugs CT1 and the second contact plugs CT2 may be aligned with each other in the second direction II and may be spaced apart from each other in the second direction II. As an example, the first contact plug CT1 and the second contact plug CT2 may at least partially overlap with each other in the third direction III. In this example, the third direction III is the vertical direction.

Referring to FIG. 26A, the first contact plug CT1 and the pass transistor PT are aligned with each other in the second direction II. The gate structure is located such that the rear surface RS faces the block word line BLKWL. The first contact plug CT1 may be connected to the second contact plug CT2 via a first interconnection structure IC1. The first interconnection structure IC1 may be connected to the first contact plug CT1 on the front surface FS of the gate structure GST. The first interconnection structure IC1 may include a contact plug formed through a slit structure, a support, a dummy stack, and the like. The first interconnection structure IC1 may include a wiring line extending in the second direction II.

Referring to FIG. 26B, the first contact plug CT1 and the pass transistor PT may at least partially overlap with each other in the third direction III. The gate structure is located such that the front surface FS faces the block word line BLKWL. The first contact plug CT1 may be connected to the second contact plug CT2 via a second interconnection structure IC2. Each second interconnection structure IC2 may be connected to the first contact plug CT1 on the front surface FS of the gate structure GST. Each second interconnection structure IC2 may include a bonding structure such as a bonding pad.

According to the structure described above, the first contact plug CT1 and the second contact plug CT2 may be located on the same line extending in the second direction II or may be located within a predetermined distance or range from the same line. The first contact plug CT1 and the pass transistor PT may be located on the same line extending in the second direction II or may be located within a predetermined distance or range from the same line. Accordingly, the interconnection structures IC1 and IC2 may not include wiring lines extending in the first direction I or may include fewer wiring lines extending in the first direction I, and an area occupied by the interconnection structures IC1 and IC2 may be reduced.

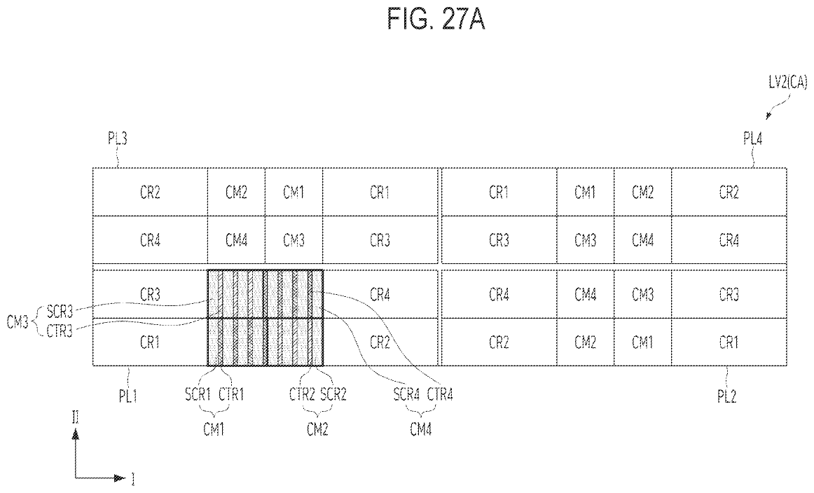

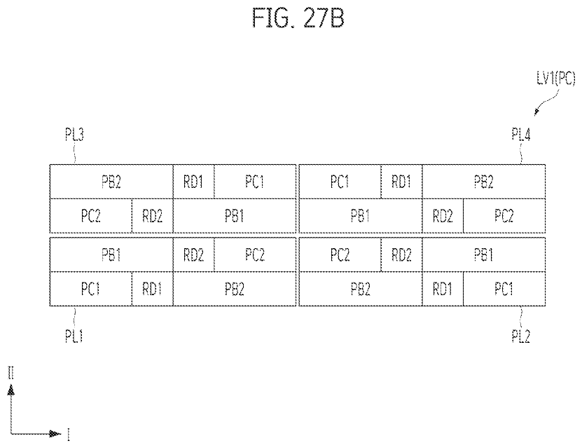

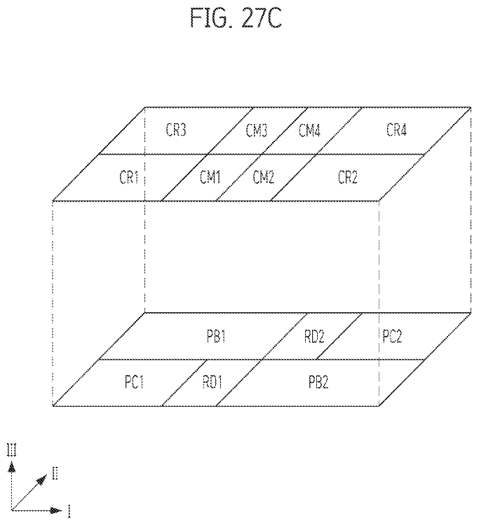

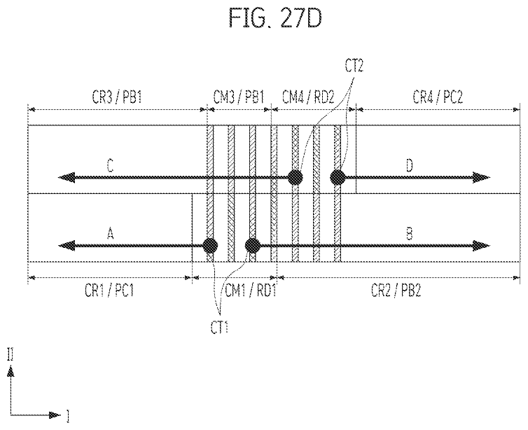

FIG. 27A through FIG. 27D are diagrams illustrating the structure of a semiconductor device in accordance with an embodiment.

Referring to FIG. 27A through FIG. 27D, the semiconductor device may be a semiconductor chip, and one chip may include four memory planes PL1, PL2, PL3, and PL4. The memory planes PL1, PL2, PL3, and PL4 may have different structures depending on levels. The semiconductor device may include a peripheral circuit PC located at a first level LV1 and a cell array CA located at a second level LV2. The second level LV2 may be located below or above the first level LV1. As an example, the cell array CA may be stacked on the peripheral circuit PC or the peripheral circuit PC and the cell array CA may be bonded to each other via a bonding structure.

Referring to FIG. 27A, the cell array CA may include at least one of a first cell region CR1, a second cell region CR2, a third cell region CR3, and a fourth cell region CR4. The first cell region CR1, second cell region CR2, third cell region CR3, and fourth cell region CR4 may be regions where memory cells are stacked. Channel structures may be located in the first cell region CR1, second cell region CR2, third cell region, and fourth cell region CR4.

The first cell region CR1 may be adjacent to the second cell region CR2 in the first direction I, and the third cell region CR3 may be adjacent to the fourth cell region CR4 in the first direction I. The first cell region CR1 may be adjacent to the third cell region CR3 in the second direction II, and the second cell region CR2 may be adjacent to the fourth cell region CR4 in the second direction II. In this example, the first direction I and the second direction II may intersect each other. As an example, the first direction I and the second direction II may intersect each other at a right angle, i.e., the first direction I may be perpendicular to the second direction II.

The cell array CA may include at least one of a first common region CM1, a second common region CM2, a third common region CM3, and a fourth common region CM4. The first common region CM1, common cell region CM2, third common region CM3, and fourth common region CM4 may be regions used as contact regions as well as cell regions. The contact region may be a region where an interconnection structure is located, through which a bias is transmitted for driving the stacked memory cells. The interconnection structure may include a contact plug, a wiring line, and the like.

The first common region CM1 may be located between the first cell region CR1 and the second cell region CR2, and the second common region CM2 may be located between the first common region CM1 and the second cell region CR2. The third common region CM3 may be located between the third cell region CR3 and the fourth cell region CR4, and the fourth common region CM4 may be located between the third common region CM3 and the fourth cell region CR4.

Each of the first common region CM1, common cell region CM2, third common region CM3, and fourth common region CM4 may include sub-cell regions and contact regions. The first common region CM1 may include first sub-cell regions SCR1 that are alternately arranged with first contact regions CTR1. The first sub-cell regions SCR1 are alternately arranged with the first contact regions CTR1 along the first direction I. The second common region CM2 may include second sub-cell regions SCR2 that are alternately arranged with second contact regions CTR2. The third common region CM3 may include third sub-cell regions SCR3 that are alternately arranged with third contact regions CTR3. The fourth common region CM4 may include fourth sub-cell regions SCR4 that are alternately arranged with fourth contact regions CTR4.

Referring to FIG. 27B, the peripheral circuit PC may include at least one of a first peripheral circuit PC1, a second peripheral circuit PC2, a first page buffer PB1, a second page buffer PB2, a first row decoder RD1, and a second row decoder RD2. The first row decoder RD1 and the second row decoder RD2 may be circuits for selecting a memory block and a row line according to an address and driving the row line. At least one of the first row decoder RD1 and the second row decoder RD2 may include pass transistors controlling the connection between global lines and local lines.

In a first memory plane PL1, the first peripheral circuit PC1 may include an analog circuit such as a voltage generator. The second peripheral circuit PC2 may include at least one of a page buffer, an input/output circuit, and a data control circuit. The page buffer may be a circuit for access (read, program, and so forth) of the cell array. The input/output circuit may be a circuit for transmitting and receiving a command, an address, data, and the like, to and from the outside of the chip. In this example, “the outside of the chip” may be a memory controller. The data control circuit may be a circuit for controlling the data transmitted and received through the input/output circuit to transmit and receive the data to and from the page buffer.

In a third memory plane PL3, the first peripheral circuit PC1 may include a logic circuit for controlling operation of a memory device. The second peripheral circuit PC2 may include at least one of a page buffer, an input/output circuit, and a data control circuit.

The first peripheral circuit PC1 and the second page buffer PB2 may be spaced apart in the first direction I, and the first page buffer PB1 and the second peripheral circuit PC2 may be spaced apart in the first direction I. The first peripheral circuit PC1 may be adjacent to the first page buffer PB1 in the second direction II, and the second page buffer PB2 may be adjacent to the second peripheral circuit PC2 in the second direction II. The first row decoder RD1 may be located between the first peripheral circuit PC1 and the second page buffer PB2, and the second row decoder RD2 may be located between the first page buffer PB1 and the second peripheral circuit PC2. The first row decoder RD1 and the second row decoder RD2 may not be aligned with each other in the second direction II and may have staggered locations.

The first memory plane PL1 and a second memory plane PL2 may each include the first peripheral circuit PC1, the second peripheral circuit PC2, the first page buffer PB1, the second page buffer PB2, the first row decoder RD1, and the second row decoder RD2 arranged in a mirror symmetry form. The third memory plane PL3 and a fourth memory plane PL4 may each include the first peripheral circuit PC1, the second peripheral circuit PC2, the first page buffer PB1, the second page buffer PB2, the first row decoder RD1, and the second row decoder RD2 arranged in a mirror symmetry form.

Referring to FIG. 27C, the first peripheral circuit PC1 may be located below the first cell region CR1, and the first row decoder RD1 may be located below the first common region CM1. The second page buffer PB2 may be located below the second common region CM2 and the second cell region CR2. The first page buffer PB1 may be located below the third cell region CR3 and the third common region CM3. The second row decoder RD2 may be located below the fourth common region CM4, and the second peripheral circuit PC2 may be located below the fourth cell region CR4.

Referring to FIG. 27D, first contact plugs CT1 may be located in the first common region CM1 of the first common region CM1 and the second common region CM2. Second contact plugs CT2 may be located in the fourth common region CM4 of the third common region CM3 and the fourth common region CM4. The first contact plugs CT1 may not be adjacent to the second contact plugs CT2 in the second direction II and may have staggered locations.

Biases applied to the first contact plugs CT1 and the second contact plugs CT2 may be transmitted in both directions (bi-directionally). As an example, the biases applied to the first contact plugs CT1 may be transmitted to memory cells of 4 to 8 KB on one side A and may be transmitted to memory cells of 8 to 12 KB on the other side B. The biases applied to the second contact plugs CT2 may be transmitted to memory cells of 8 to 12 KB on one side C and may be transmitted to memory cells of 4 to 8 KB on the other side D. Loading in one direction may be different from loading in the other direction.

According to the structure described above, the cell array CA and the peripheral circuit PC may be stacked in the third direction III, e.g., vertically. The common regions CM1, CM2, CM3, and CM4 may be located between the cell regions CR1, CR2, CR3, and CR4, and the contact regions CTR1, CTR2, CRT3, and CTR4 may be distributed and disposed between the sub-cell regions SCR1, SCR2, SCR3, and SCR4. The first row decoder RD1 and second row decoders RD2 may be located below the common regions CM1, CM2, CM3, and CM4 and may be staggered. Accordingly, the interconnection structure connecting the cell array CA to the peripheral circuit PC may be simplified, and a pitch between bit lines may be reduced.

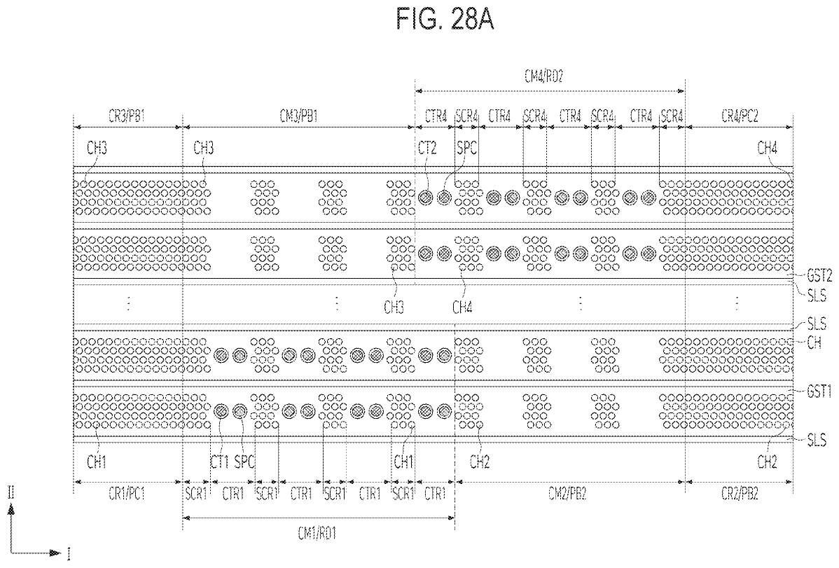

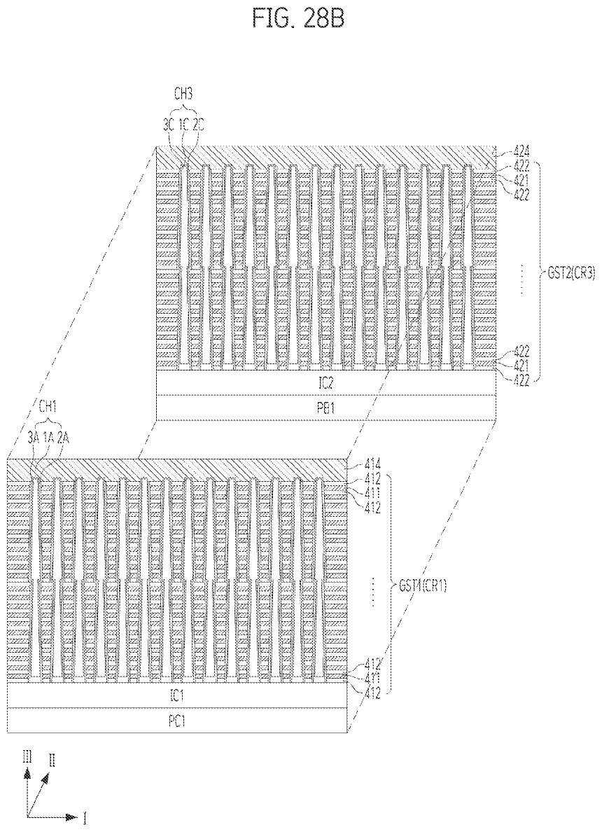

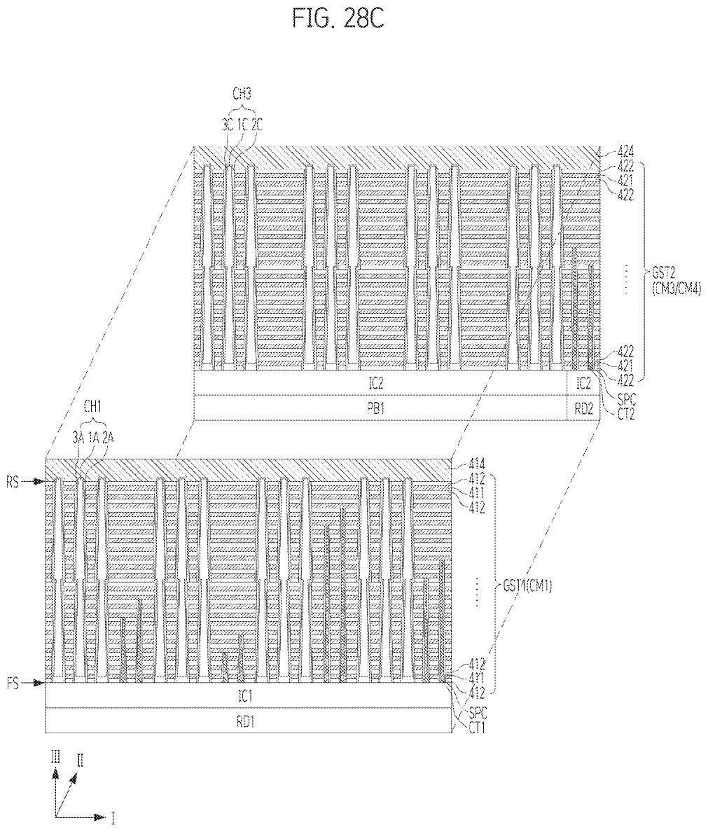

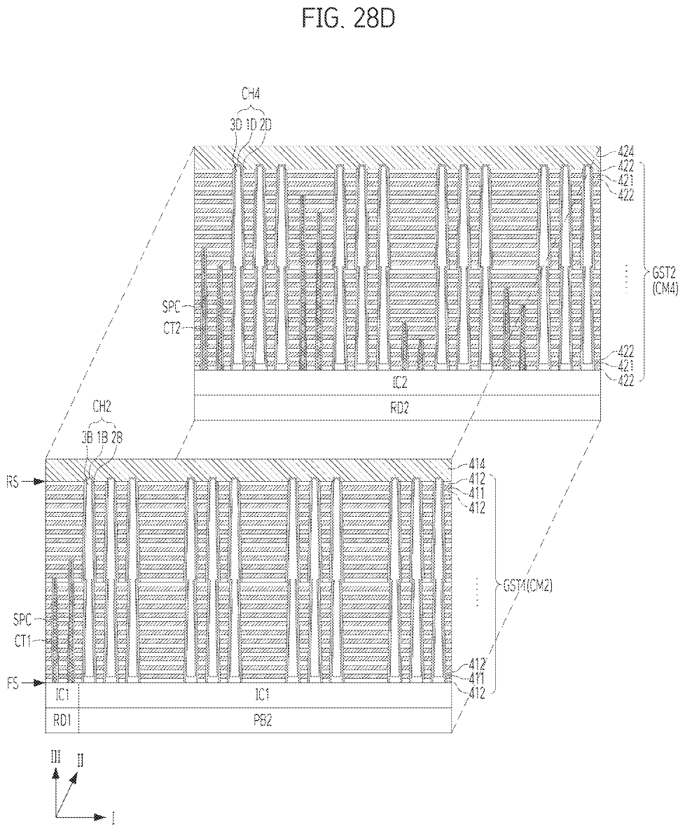

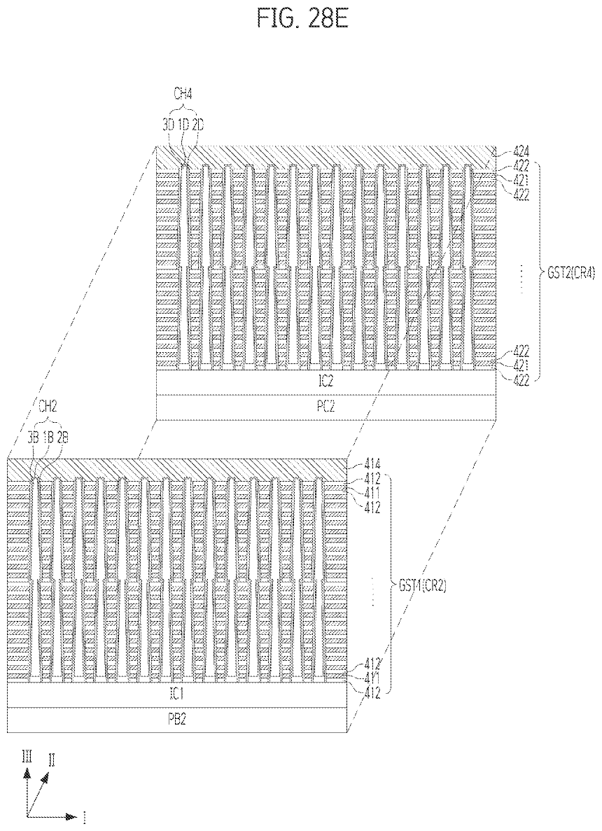

FIG. 28A through FIG. 28E are diagrams illustrating the structure of a semiconductor device in accordance with an embodiment.

Referring to FIG. 28A through FIG. 28E, the semiconductor device may include at least one of a first gate structure GST1, a second gate structure GST2, a slit structure SLS, a first channel structure CH1, a second channel structure CH2, a third channel structure CH3, a fourth channel structure CH4, a first contact plug CT1, a second contact plug CT2, a first source structure 414, a second source structure 424, a first peripheral circuit PC1, a second peripheral circuit PC2, a first page buffer PB1, a second page buffer PB2, a first row decoder RD1, and a second row decoder RD2.

The first gate structure GST1 may include first gate lines 411 that are alternately stacked with first insulating layers 412. The first gate lines 411 may be word lines, source select lines, or drain select lines. The first gate lines 411 may each comprise a conductive material such as polysilicon, tungsten, or molybdenum.

The first gate structure GST1 may extend in the first direction I, and may include a first cell region CR1, a second cell region CR2, a first common region CM1, and a second common region CM2. The first common region CM1 may be located between the first cell region CR1 and the second cell region CR2, and the second common region CM2 may be located between the first common region CM1 and the second cell region CR2. The first common region CM1 may include first sub-cell regions SCR1 that are alternately arranged with first contact regions CTR1.

The first channel structures CH1 may each include at least one of a first channel layer 1A, a first memory layer 2A, and a first insulating core 3A. The first channel structures CH1 may extend through the first cell region CR1 and the first common region CM1 of the first gate structure GST1. The first channel structures CH1 may be distributed and disposed in the first common region CM1 and may be located in the first sub-cell regions SCR1.

The second channel structures CH2 may each include at least one of a second channel layer 1B, a second memory layer 2B, and a second insulating core 3B. The second channel structures CH2 may extend through the second cell region CR2 and the second common region CM2 of the first gate structure GST1. The second channel structures CH2 may be distributed and disposed in the second common region CM2 and may be located in second sub-cell regions SCR2 of the second common region CM2.

First memory cells may be located in regions where the first channel structure CH1 intersect the first gate lines 411. The first memory cells may be stacked along the first channel structures CH1. Second memory cells may be located in regions where the second channel structures CH2 intersect the first gate lines 411. The second memory cells may be stacked along the second channel structures CH2.

The first contact plugs CT1 may be located in the first common region CM1 among the first common region CM1 and the second common region CM2, and may be distributed and disposed in the first contact regions CTR1. The first contact plugs CT1 may not be located in the second common region CM2. The first contact plugs CT1 each extend at a different depth through the first contact regions CTR1. The sidewalls of each first contact plug CT1 are individually surrounded by an insulating spacer SPC. Each of the first contact plugs CT1 may be electrically connected to a different one of the first gate lines 411.

The second gate structure GST2 may include second gate lines 421 that are alternately stacked with second insulating layers 422. The second gate lines 421 may be word lines, source select lines, or drain select lines. Each of the second gate lines 421 may comprise a conductive material such as polysilicon, tungsten, or molybdenum.

The second gate structure GST2 may be adjacent to the first gate structure GST1 in the second direction II. The slit structure SLS may be located between the first gate structures GST1 and the second gate structures GST2 adjacent to each other the second direction II. The slit structure SLS may include at least one of an insulating material, a conductive material, and a semiconductor material.

The second gate structure GST2 may extend in the first direction I, and may include a third cell region CR3, a fourth cell region CR4, a third common region CM3, and a fourth common region CM4. The third common region CM3 may be located between the third cell region CR3 and the fourth cell region CR4, and the fourth common region CM4 may be located between the third common region CM3 and the fourth cell region CR4. The fourth common region CM4 may include fourth sub-cell regions SCR4 that are alternately stacked with fourth contact regions CTR4.

The third channel structures CH3 may each include at least one of a third channel layer 1C, a third memory layer 2C, and a third insulating core 3C. The third channel structures CH3 may extend through the third cell region CR3 and the third common region CM3 of the second gate structure GST2. The third channel structures CH3 may be distributed and disposed in the third common region CM3 and may be located in third sub-cell regions SCR3 of the third common region CM3.

The fourth channel structure CH4 may include at least one of a fourth channel layer 1D, a fourth memory layer 2D, and a fourth insulating core 3D. The fourth channel structures CH4 may extend through the fourth cell region CR4 and the fourth common region CM4 of the second gate structure GST2. The fourth channel structures CH4 may be distributed and disposed in the fourth common region CM4 and may be located in the fourth sub-cell regions SCR4.

Third memory cells may be located in regions where the third channel structure CH3 intersect the second gate lines 421 intersect. The third memory cells may be stacked along the third channel structure CH3. Fourth memory cells may be located in regions where the fourth channel structure CH4 intersect the second gate lines 421. The fourth memory cells may be stacked along the fourth channel structure CH4.

The second contact plugs CT2 may be located in the fourth common region CM4 among the third common region CM3 and the fourth common region CM4 and may be distributed and disposed in the fourth contact regions CTR4. The second contact plugs CT2 may not be located in the third common region CM3. The second contact plugs CT2 each extend at a different depth through the fourth contact regions CTR4. The sidewalls of each second contact plug CT2 are individually surrounded by an insulating spacer SPC. Each of the second contact plugs CT2 may be electrically connected to a different one of the second gate lines 421.

Because the first contact plugs CT1 are located in the first common region CM1 and the second contact plugs CT2 are located in the fourth common region CM4, the first contact plugs CT1 and the second contact plugs CT2 may have staggered locations.

Referring to FIG. 28B, a first interconnection structure IC1 and the first peripheral circuit PC1 may be located below the first cell region CR1 of the first gate structure GST1. As an example, the first interconnection structure IC1 may include at least one bonding structure such as a bonding pad and a bonding interface. The first source structure 414 may be located above the first gate structure GST1. As an example, the first channel structures CH1 may extend into the first source structure 414, and the first channel layer 1A may be connected to the first source structure 414.

The first cell region CR1 of the first gate structure GST1 may be adjacent to the third cell region CR3 of the second gate structure GST2 in the second direction II. A second interconnection structure IC2 and the first page buffer PB1 may be located below the third cell region CR3 of the second gate structure GST2. As an example, the second interconnection structure IC2 may include at least one bonding structure such as a bonding pad and a bonding interface. The second source structure 424 may be located above the second gate structure GST2. As an example, the third channel structure CH3 may extend into the second source structure 424, and the third channel layer 3C may be connected to the second source structure 424.

Referring to FIG. 28C, the first interconnection structure IC1 and the first row decoder RD1 may be located below the first common region CM1 of the first gate structure GST1. The first common region CM1 of the first gate structure GST1 may be adjacent to the third common region CM3 of the second gate structure GST2 in the second direction II. The second interconnection structure IC2 and the first page buffer PB1 may be located below the third common region CM3 of the second gate structure GST2.

In the first common region CM1, the first contact plugs CT1 may each extend at a different depth from a first surface, such as a front surface FS, of the first gate structure GST1 toward a second surface, such as a rear surface RS, of the first gate structure GST1. Each of the first contact plugs CT1 may be electrically connected to a different one of the first gate lines 411. For convenience of explanation and simplicity of the drawing, only some of the first contact plugs CT1 are illustrated in FIG. 28C.

Referring to FIG. 28D, the first interconnection structure IC1 and the second page buffer PB2 may be located below the second common region CM2 of the first gate structure GST1. The second common region CM2 of the first gate structure GST1 may be adjacent to the fourth common region CM4 of the second gate structure GST2 in the second direction II. The second interconnection structure IC2 and the second row decoder RD2 may be located below the fourth common region CM4 of the second gate structure GST2.

In the fourth common region CM4, each of the second contact plugs CT2 may extend at a different depth from a front surface FS of the second gate structure GST2 toward a rear surface RS of the second gate structure GST2. Each of the second contact plugs CT2 may be electrically connected to a different one of the second gate lines 421. For convenience of explanation and simplicity of the drawing, only some of the second contact plugs CT2 are illustrated in FIG. 28D.

Referring to FIG. 28E, the first interconnection structure IC1 and the second page buffer PB2 may be located below the second cell region CR2 of the first gate structure GST1. The second cell region CR2 of the first gate structure GST1 may be adjacent to the fourth cell region CR4 of the second gate structure GST2 in the second direction II. The second interconnection structure IC2 and the second peripheral circuit PC2 may be located below the fourth cell region CR4 of the second gate structure GST2.

According to the structure described above, the first and second gate structures GST1 and GST2 do not include a stair structure, and the first and second contact plugs CT1 and CT2 may extend through the first and second gate structures GST1 and GST2, respectively. Accordingly, areas of the contact regions CTR1 and CTR2 may be reduced compared to an example where the first and second gate structures include a stair structure.

The first contact plugs CT1 are located in the first common region CM1 located between the first cell region CR1 and the second cell region CR2. Accordingly, biases applied through the first contact plug CT1 may be applied in both directions (bi-directionally) along the first gate line 411 and may be transmitted to the first memory cells and the second memory cells. Likewise, biases applied through the second contact plug CT2 may be applied in both directions (bi-directionally) along the second gate line 421 and may be transmitted to the third memory cells and the fourth memory cells. By transmitting the biases in both directions (bi-directionally) as described above, loading time may be reduced.

Because the first row decoder RD1 is located below the first common region CM1, the first contact plugs CT1 may be directly connected to the first row decoder RD1 and the first interconnection structure IC1 may be simplified. As an example, the first interconnection structure IC1 may be simplified by designing a pitch between the first contact plugs CT1 to be substantially the same as a pitch between pass transistors.

Likewise, because the second row decoder RD2 is located below the fourth common region CM4, the second contact plugs CT2 may be directly connected to the second row decoder RD2 and the second interconnection structure IC2 may be simplified. As an example, the second interconnection structure IC2 may be simplified by designing a pitch between the second contact plugs CT2 to be substantially the same as the pitch between the pass transistors.

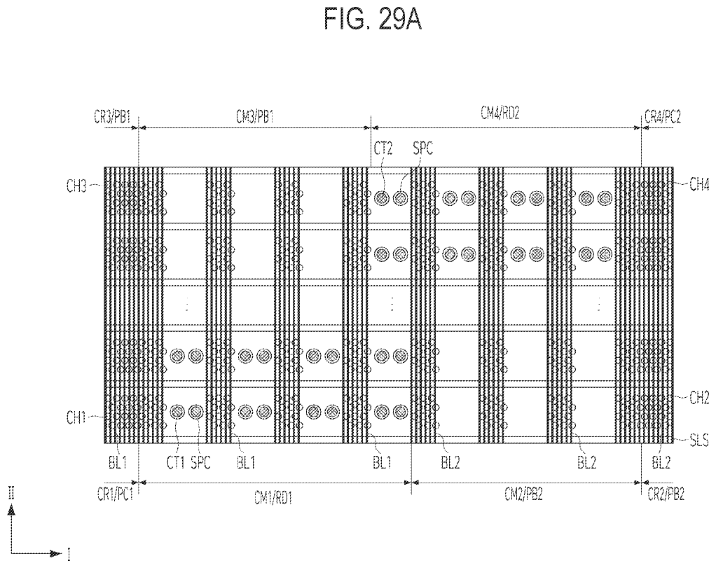

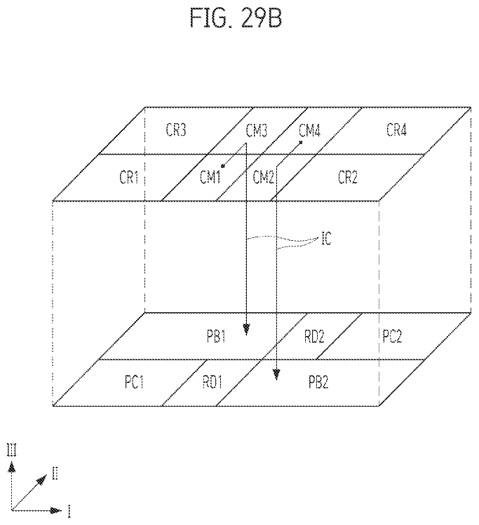

FIG. 29A and FIG. 29B are diagrams illustrating the structure of a semiconductor device in accordance with an embodiment.

Referring to FIG. 29A, the semiconductor device may include at least one of a first gate structure GST1, a second gate structure GST2, a slit structure SLS, a first channel structure CH1, a second channel structure CH2, a third channel structure CH3, a fourth channel structure CH4, a first contact plug CT1, a second contact plug CT2, a first bit line BL1, a second bit line BL2, a first peripheral circuit PC1, a second peripheral circuit PC2, a first page buffer PB1, a second page buffer PB2, a first row decoder RD1, and a second row decoder RD2.

The first bit lines BL1 may be located in a first cell region CR1, a third cell region CR3, a first common region CM1, and a third common region CM3. The first bit lines BL1 may be located in sub-cell regions of the first common region CM1 and the third common region CM3. The first bit line BL1 may be connected to the first channel structure CH1 and the third channel structure CH3 and may extend in the second direction II.

The second bit lines BL2 may be located in a second cell region CR2, a fourth cell region CR4, a second common region CM2, and a fourth common region CM4. The second bit lines BL2 may be located in sub-cell regions of the second common region CM2 and the fourth common region CM4. The second bit line BL2 may be connected to the second channel structures CH2 and the fourth channel structure CH4 and may extend in the second direction II.

Referring to FIG. 29A and FIG. 29B, an interconnection structure IC may be located between or across the first and second gate structures GST1 and GST2 and a peripheral circuit PC. The interconnection structure IC may include the first bit lines BL1 and the second bit lines BL2 and may further include a plurality of bonding structures. The first channel structures CH1 and the third channel structures CH3 may be connected to the first page buffer PB1 through the first bit lines BL1. The second channel structures CH2 and the fourth channel structures CH4 may be connected to the second page buffer PB2 through the second bit lines BL2.

The first channel structures CH1 located in the first common region CM1 may overlap with the first row decoder RD1 in the third direction III. The fourth channel structures CH4 located in the fourth common region CM4 may overlap with the second row decoder RD2 in the third direction III. When the first row decoder RD1 is located adjacent to the second row decoder RD2 in the second direction II, the first channel structures CH1 located in the first common region CM1 may not be connected to the first page buffer PB1 through the first bit lines BL1. Likewise, the fourth channel structures CH4 located in the common region CM4 may not be connected to the second page buffer PB2 through the second bit lines BL2. According to an embodiment of the present disclosure, the first row decoder RD1 and the second row decoder RD2 may have staggered locations. The first row decoder RD1 may not be adjacent to the second row decoder RD2 in the second direction II. Through this process, the first channel structures CH1 of the first common region CM1 may be connected to the first page buffer PB1 through the first bit lines BL1. The fourth channel structures CH4 of the fourth common region CM4 may be connected to the second page buffer PB2 through the second bit lines BL2.

According to the structure described above, the row decoders RD1 and RD2 may have staggered locations in a memory plane. Accordingly, the channel structures CH1, CH2, CH3, and CH4 may be formed in the common regions CM1, CM2, CM3, and CM4, respectively, and a degree of integration of a memory may be increased. By locating the bit lines BL1 and the bit lines BL2 in the common regions CM1, CM2, CM3, and CM4, areas for forming the bit lines BL1 and BL2 may be increased and pitches between the bit lines BL1 and bit lines BL2 may be increased.

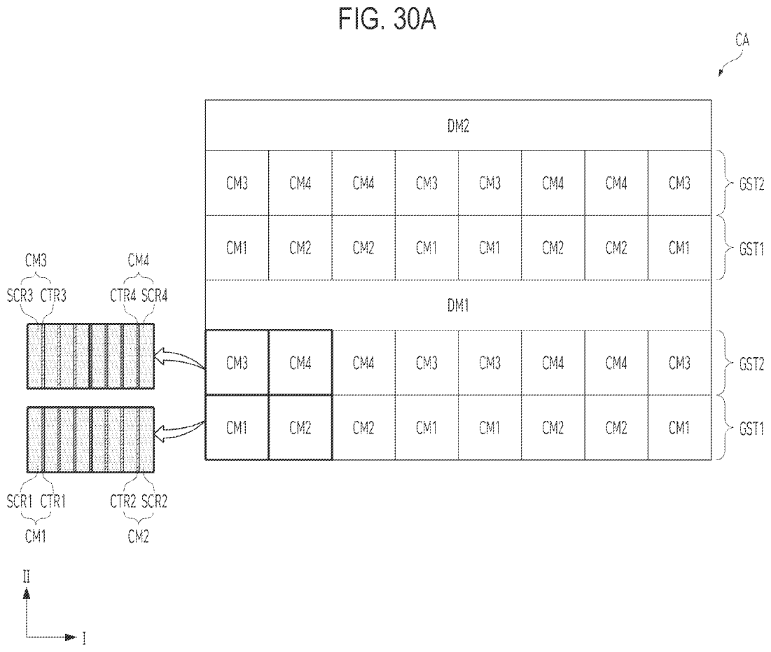

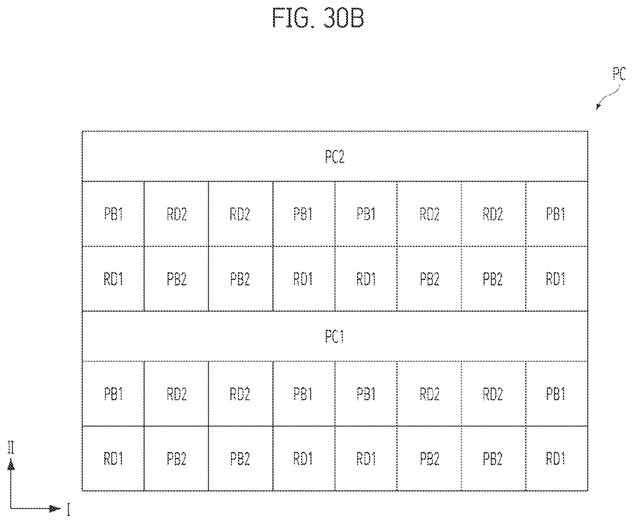

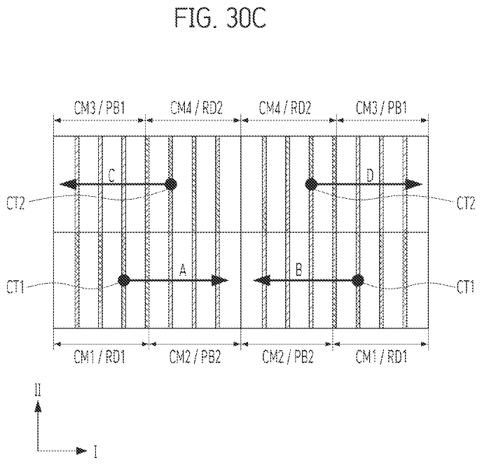

FIG. 30A to FIG. 30C are diagrams illustrating the structure of a semiconductor device in accordance with an embodiment.

Referring to FIG. 30A and FIG. 30B, the semiconductor device may include a cell array CA and a peripheral circuit PC. The peripheral circuit PC may be located above or below the cell array CA, and the cell array CA may be electrically connected to the peripheral circuit PC through an interconnection structure.

Referring to FIG. 30A, the cell array CA may include a first gate structure GST1 and a second gate structure GST2. The first gate structure GST1 and the second gate structure GST2 may extend in the first direction I and may be adjacent to each other in the second direction II. The first gate structures GST1 are alternately stacked with the second gate structures GST2 along the second direction II that intersects the first direction. For example, the second direction II may be perpendicular to the first direction. As an example, the first gate structure GST1, the second gate structure GST2, a first dummy region DM1, the first gate structure GST1, the second gate structure GST2, and a second dummy region DM2 may be sequentially arranged along the second direction II. The first dummy region DM1 and the second dummy region DM2 may be regions where channel structures and contact plugs are not located.

The first gate structure GST1 may include a first common region CM1 and a second common region CM2. The first common region CM1 may include first sub-cell regions SCR1 that are alternately arranged with first contact regions CTR1. The second common region CM2 may include second sub-cell regions SCR2 that are alternately arranged with second contact regions CTR2.

The second gate structure GST2 may include a third common region CM3 and a fourth common region CM4. The third common region CM3 may include third sub-cell regions SCR3 that are alternately arranged with third contact regions CTR3. The fourth common region CM4 may include fourth sub-cell regions SCR4 that are alternately arranged with fourth contact regions CTR4.

Referring to FIG. 30B, the peripheral circuit PC may include at least one of a first row decoder RD1, a second row decoder RD2, a first page buffer PB1, a second page buffer PB2, a first peripheral circuit PC1, and a second peripheral circuit PC2. In this example, the first peripheral circuit PC1 may include at least one of a page buffer, an input/output circuit, and a data control circuit. The second peripheral circuit PC2 may include at least one of a pad, a logic circuit, and an analog circuit. As an example, the second peripheral circuit PC2 may be located closer to a memory plane edge than where the first peripheral circuit PC1 is located. The first peripheral circuit PC1 and the second peripheral circuit PC2 may be located below the first dummy region DM1 and the second dummy region DM2, respectively.

The first row decoder RD1 may be located below the first common region CM1. The second row decoder RD2 may be located below the fourth common region CM4. The first row decoder RD1 may not be adjacent to the second row decoder RD2 in the second direction II and may be staggered. The first page buffer PB1 may be located below the third common region CM3. The second page buffer PB2 may be located below the second common region CM2. The first page buffer PB1 may not be adjacent to the second page buffer PB2 in the second direction II and may be staggered.

Referring to FIG. 30C, first contact plugs CT1 may be located in the first common region CM1 of the first common region CM1 and the second common regions CM2. Second contact plugs CT2 may be located in the fourth common region CM4 of the third common region CM3 and the fourth common region CM4. The first contact plugs CT1 may not be adjacent to the second contact plugs CT2 in the second direction II and may have staggered locations.

Biases applied to the first contact plugs CT1 and the second contact plugs CT2 may be transmitted in both directions (bi-directionally). As an example, the biases applied to the first contact plugs CT1 may be transmitted to memory cells of about 4 KB on one side A and may be transmitted to memory cells of about 4 KB on the other side B. The biases applied to the second contact plugs CT2 may be transmitted to memory cells of about 4 KB on one side D and may be transmitted to memory cells of about 4 KB on the other side C. Loading in one direction may be the same as loading in the other direction. By distributing and disposing the channel structures and the contact plugs through the first common region CM1, the second common region CM2, the third common region CM3, and the fourth common region CM4, resistances Rs of the gate lines may be reduced, program speed may be improved, and loading may be reduced. As an example, the contact plugs may be distributed and disposed at 16 KB/2^{N}, where N is an integer having a value of 0 or more.

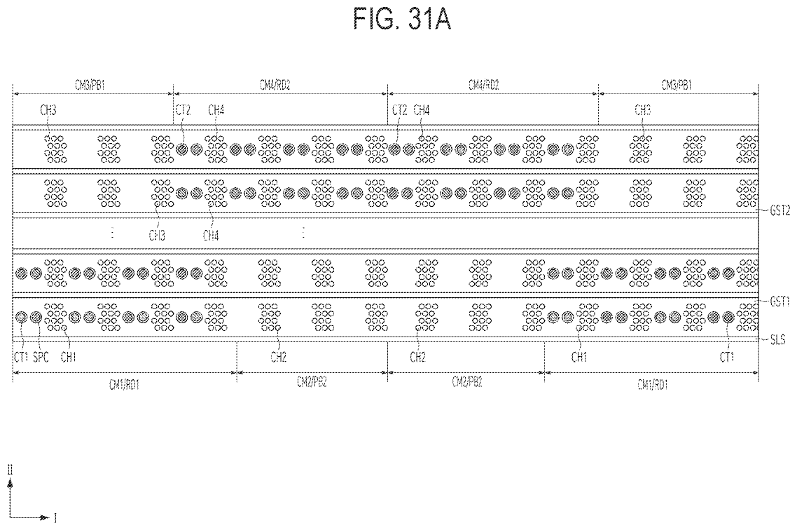

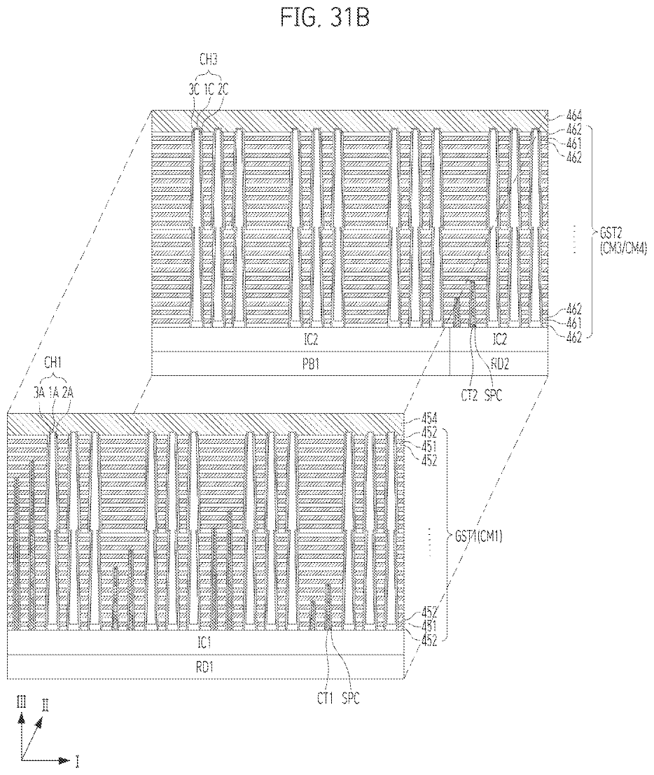

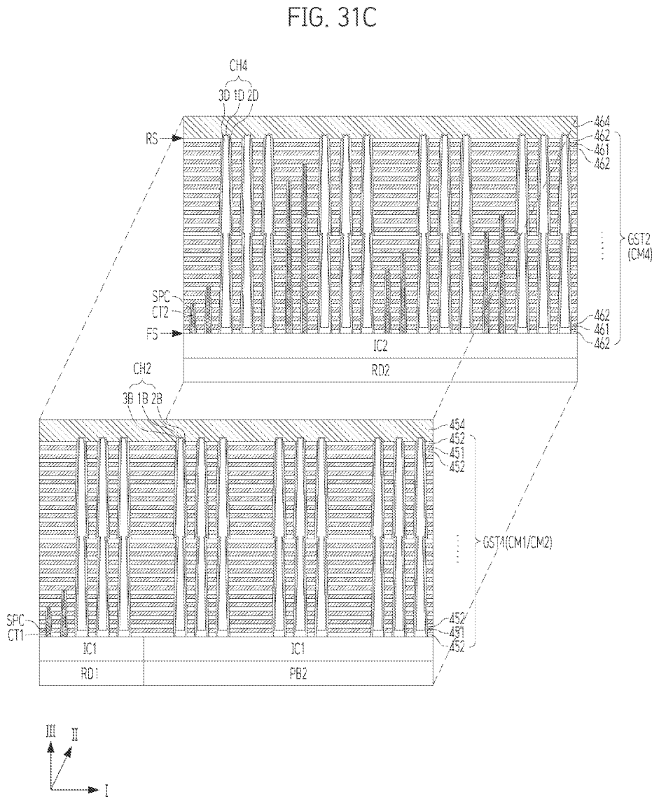

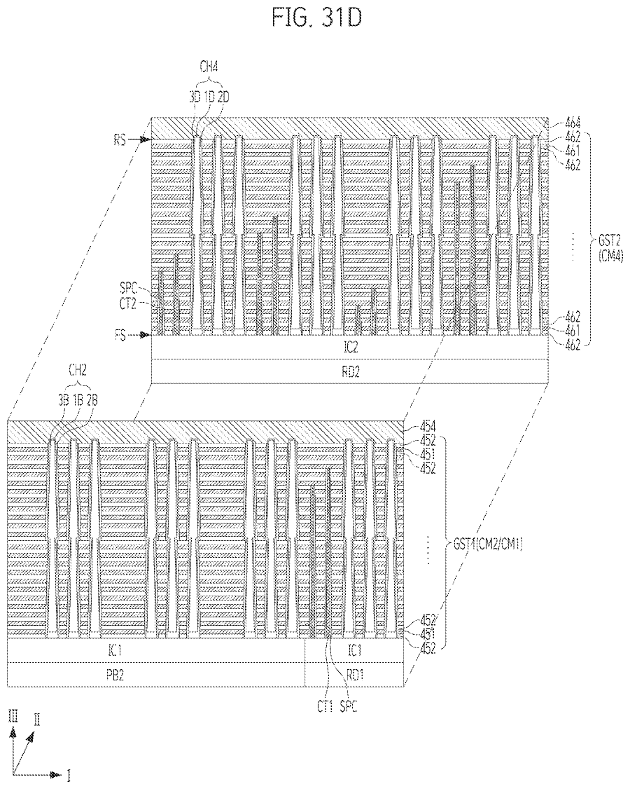

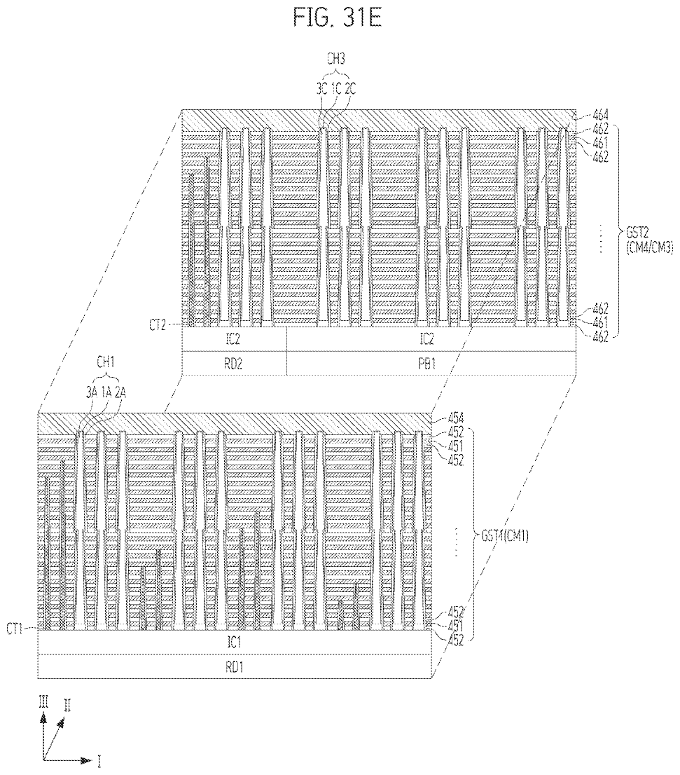

FIG. 31A through FIG. 31E are diagrams illustrating the structure of a semiconductor device in accordance with an embodiment.

Referring to FIG. 31A through FIG. 31E, the semiconductor device may include at least one of a first gate structure GST1, a second gate structure GST2, a slit structure SLS, a first channel structure CH1, a second channel structure CH2, a third channel structure CH3, a fourth channel structure CH4, a first contact plug CT1, a second contact plug CT2, a first source structure 454, a second source structure 464, a first peripheral circuit PC1, a second peripheral circuit PC2, a first page buffer PB1, a second page buffer PB2, a first row decoder RD1, and a second row decoder RD2.

The first gate structure GST1 may include first gate lines 451 that are alternately stacked with first insulating layers 452. The first gate structure GST1 may include first common regions CM1 and second common regions CM1. Each of the first common regions CM1 and the second common regions CM2 may include sub-cell regions that are alternately arranged with contact regions along the first direction I.

The first channel structures CH1 may each include at least one of a first channel layer 1A, a first memory layer 2A, and a first insulating core 3A. The first channel structures CH1 may extend through the first common region CM1 and may be distributed and disposed in the first common region CM1. First memory cells may be stacked along the first channel structures CH1.

The second channel structures CH2 may each include at least one of a second channel layer 1B, a second memory layer 2B, and a second insulating core 3B. The second channel structures CH2 may extend through the second common region CM2 of the first gate structure GST1 and may be distributed and disposed in the second common region CM2. Second memory cells may be stacked along the second channel structures CH2.

The first contact plugs CT1 may be located in the first common region CM1 of the first common region CM1 and the second common region CM2 and may be distributed and disposed in first contact regions CTR1. The first contact plugs CT1 may not be located in the second common regions CM2. The first contact plugs CT1 may each extend at a different depth through the first contact regions. The sidewalls of each first contact plug CT1 are individually surrounded by an insulating spacer SPC. Each first contact plug CT1 may be electrically connected to a different one of the first gate lines 451.

The second gate structure GST2 may include second gate lines 461 that are alternately stacked with second insulating layers 462. The second gate structure GST2 may include third common regions CM3 and fourth common regions CM4. Each of the third common regions CM3 and the fourth common regions CM4 may include sub-cell regions that are alternately arranged with contact regions along the first direction I.

The third channel structures CH3 may each include at least one of a third channel layer 1C, a third memory layer 2C, and a third insulating core 3C. The third channel structures CH3 may extend through the third common region CM3 and may be distributed and disposed in the third common region CM3. Third memory cells may be stacked along the third channel structures CH3.

The fourth channel structures CH4 may each include at least one of a fourth channel layer 1D, a fourth memory layer 2D, and a fourth insulating core 3D. The fourth channel structures CH4 may extend through the fourth common region CM4 and may be distributed and disposed in the fourth common region CM4. Fourth memory cells may be stacked along the fourth channel structures CH4.

The second contact plugs CT2 may be located in the fourth common region CM4 of the third common region CM3 and the fourth common region CM4 and may be distributed and disposed in fourth contact regions CTR4. The second contact plugs CT2 may not be located in the third common region CM3. The second contact plugs CT2 may each extend at a different depth through the fourth contact regions. The sidewalls of each second contact plug CT2 are individually surrounded by an insulating spacer SPC. The second contact plugs CT2 may each be electrically connected to a different one of the second gate lines 461.

Referring to FIG. 31B, a first interconnection structure IC1 and the first row decoder RD1 may be located below the first common region CM1 of the first gate structure GST1. The first source structure 454 may be located above the first gate structure GST1.

The first common region CM1 of the first gate structure GST1 may be adjacent to the third common region CM3 of the second gate structure GST2 in the second direction II. A second interconnection structure IC2 and the first page buffer PB1 may be located below the third common region CM3 of the second gate structure GST2. The second source structure 464 may be located above the second gate structure GST2.

In the first common region CM1, the first contact plugs CT1 may each extend at a different depth from a first surface or a front surface FS of the first gate structure GST1 toward a second surface or a rear surface RS of the first gate structure GST1. Each of the first contact plugs CT1 may be electrically connected to a different one of the first gate lines 451. For convenience of explanation and simplicity of the drawing, only some of the first contact plugs CT1 are illustrated in FIG. 31B.

Referring to FIG. 31C, the first interconnection structure IC1 and the second page buffer PB2 may be located below the first common region CM1 of the first gate structure GST1. The second common region CM2 of the first gate structure GST1 may be adjacent to the fourth common region CM4 of the second gate structure GST2 in the second direction II. The second interconnection structure IC2 and the second row decoder RD2 may be located below the fourth common region CM4 of the second gate structure GST2.

In the fourth common region CM4, the second contact plugs CT2 may each extend at a different depth from a front surface FS of the second gate structure GST2 toward a rear surface RS of the second gate structure GST2. Each of the second contact plugs CT2 may be electrically connected to a different one of the second gate lines 461. For convenience of explanation and simplicity of the drawing, only some of the second contact plugs CT2 are illustrated in FIG. 31C.

Referring to FIG. 31D, the first interconnection structure IC1 and the second page buffer PB2 may be located below the second common region CM2 of the first gate structure GST1. The second common region CM2 of the first gate structure GST1 may be adjacent to the fourth common region CM4 of the second gate structure GST2 in the second direction II. The second interconnection structure IC2 and the second row decoder RD2 may be located below the fourth common region CM4 of the second gate structure GST2. The second row decoder RD2 may be located near a first surface or a front surface FS of the second gate structure GST2 or the fourth common region CM4.

In the fourth common region CM4, the second contact plugs CT2 may each extend at a different depth from the front surface FS of the second gate structure GST2 toward the rear surface RS of the second gate structure GST2. Each of the second contact plugs CT2 may be electrically connected to a different one of the second gate lines 461. For convenience of explanation and simplicity of the drawing, only some of the second contact plugs CT2 are illustrated in FIG. 31D.

Referring to FIG. 31E, the first interconnection structure IC1 and the first row decoder RD1 may be located below the first common region CM1 of the first gate structure GST1. The first row decoder RD1 may be located near a first surface or a front surface FS of the first gate structure GST1 or the first common region CM1. The first common region CM1 of the first gate structure GST1 may be adjacent to the third common region CM3 of the second gate structure GST2 in the second direction II. The second interconnection structure IC2 and the first page buffer PB1 may be located below the third common region CM3 of the second gate structure GST2.

In the first common region CM1, the first contact plugs CT1 may each extend at a different depth from the front surface FS of the first gate structure GST1 toward the rear surface RS of the first gate structure GST1. Each of the first contact plugs CT1 may be electrically connected to a different one of the first gate lines 451. For convenience of explanation and simplicity of the drawing, only some of the first contact plugs CT1 are illustrated in FIG. 31E.

According to the structure described above, the first and second gate structures GST1 and GST2 do not include a stair structure, and the first and second contact plugs CT1 and CT2 may extend through the first and second gate structures GST1 and GST2, respectively. Accordingly, areas of the contact regions CTR1 and CTR2 may be reduced compared to an example where the first and second gate structures include a stair structure.

The first contact plugs CT1 may be located in the first common region CM1, and biases applied through the first contact plugs CT1 may be transmitted to the second common region CM2 along the first gate lines 451. The second contact plugs CT2 may be located in the fourth common region CM4, and biases applied through the second contact plugs CT2 may be transmitted to the third common region CM3 along the second gate lines 461.

Because the first row decoder RD1 is located below the first common region CM1, the first contact plugs CT1 may be directly connected to the first row decoder RD1 and the first interconnection structure IC1 may be simplified. As an example, the first interconnection structure IC1 may be simplified by designing a pitch between the first contact plugs CT1 to be substantially the same as a pitch between pass transistors.

Because the second row decoder RD2 is located below the fourth common region CM4, the second contact plugs CT2 may be directly connected to the second row decoder RD2 and the second interconnection structure IC2 may be simplified. As an example, the second interconnection structure IC2 may be simplified by designing a pitch between the second contact plugs CT2 to be substantially the same as the pitch between the pass transistors.

The first row decoder RD1 and the second row decoder RD2 may have staggered locations, and the first page buffer PB1 and the second page buffer PB2 may have staggered locations. Accordingly, the first channel structures CH1 and the third channel structures CH3 may be connected to the first page buffer PB1 by first bit lines extending in the second direction II. The second channel structures CH2 and fourth channel structures CH4 may be connected to the second page buffer PB2 by second bit lines extending in the second direction II.

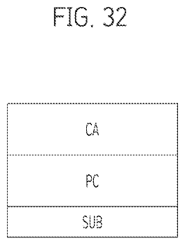

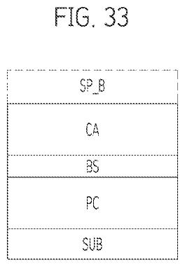

The structure and the manufacturing method according to the above-described embodiments may be applied to semiconductor devices of various structures. FIG. 32 and FIG. 33 illustrate a schematic configuration of a semiconductor device to which the above-described embodiments are applicable.

FIG. 32 is a configuration diagram of a semiconductor device according to an embodiment of the present disclosure.

Referring to FIG. 32, the semiconductor device may include a substrate SUB, a peripheral circuit PC, and a memory cell array CA. In this example, the peripheral circuit PC and the memory cell array CA may be formed on the same substrate.

The substrate SUB may include a semiconductor material. As an embodiment, the semiconductor material may include at least one of a group IV semiconductor, a group III-V compound semiconductor, and a group II-VI compound semiconductor. In this example, the group IV semiconductor may include single crystal silicon Si, polycrystalline silicon, germanium Ge, or silicon germanium SiGe. The group III-V compound semiconductor may include GaAs, GaN, GaP, GaAsP, GaInAsP, AlAs, AlGa, InP, InSb, or InGaAs. The group II-VI compound semiconductor may include ZnS, ZnO, or CdS.

The substrate SUB may include a dielectric layer. The substrate SUB may be a silicon-on-insulator (SOI) substrate, a germanium-on-insulator (GeOI) substrate, or a glass substrate. The substrate SUB may include an organic material. As an embodiment, the substrate SUB may include graphene.

The substrate SUB may be a bulk wafer or an epitaxial layer grown in a selective epitaxial growth (SEG) method. The substrate SUB may be a layer formed in a metal induced lateral crystallization (MILC) method and may partially comprise metal. The substrate SUB may have a single crystalline, polycrystalline, or amorphous state. The substrate SUB may include an impurity of group II, group III, group IV, group V, or group VI. As an embodiment, the substrate SUB may include an n-well region doped with an n-type impurity and/or a p-well region doped with a p-type impurity.

The peripheral circuit PC may be positioned between the substrate SUB and the memory cell array CA. The peripheral circuit PC may include a row decoder, a column decoder, a page buffer, a logic circuit, a control circuit, a sense amplifier, an input/output circuit, and the like, such as described with respect to previous figures. As an embodiment, the peripheral circuit PC may include an NMOS transistor, a PMOS transistor, a resistor, a capacitor, and the like. The peripheral circuit PC may further include an interconnection structure. The interconnection structure may be used as a path for transferring an operation voltage, and may include a contact plug, a line, and the like, such as described with respect to previous figures.

The memory cell array CA may include memory cells. As an embodiment, the memory cell array CA may include memory strings connected between a source line and a bit line, and each memory string may include stacked memory cells. As an embodiment, the memory cell array CA may include memory cells connected between a word line and a bit line. The memory cell array CA may further include an interconnection structure, such as described with respect to previous figures.

FIG. 33 is a configuration diagram of a semiconductor device according to an embodiment of the present disclosure.

Referring to FIG. 33, the semiconductor device may include a substrate SUB, a peripheral circuit PC, a bonding structure BS, and a memory cell array CA. The peripheral circuit PC and the memory cell array CA may be formed on separate substrates and then bonded. The semiconductor device may further include a support base SP_B.

The substrate SUB may be used as a support in a process of forming the peripheral circuit PC. The support base SP_B may be used as a support in a process of forming the memory cell array CA. As an embodiment, after respectively manufacturing a first wafer including the memory cell array CA and a second wafer including the peripheral circuit PC, the first wafer and the second wafer may be electrically connected by the bonding structure BS, such as described with respect to previous figures. After bonding, at least a portion of the support base SP_B of the first wafer may be removed. The support base SP_B may be completely removed or may partially remain on the memory cell CA array.

The support base SP_B may be a semiconductor substrate, an insulating substrate, a silicon-on-insulator (SOI) substrate, a germanium-on-insulator (GeOI) substrate, or the like. The support base SP_B may be a bulk wafer, an epitaxial layer grown in a selective epitaxial growth (SEG) method, or a layer formed in a metal induced lateral crystallization (MILC) method. The support base SP_B may have a single crystalline, polycrystalline, or amorphous state. The support base SP_B may include an impurity of group II, group III, group IV, group V, or group VI.

The bonding structure BS may connect the memory cell array CA to the peripheral circuit PC. As an embodiment, the memory cell array CA and the peripheral circuit PC may be bonded in a wafer-on-wafer bonding method, a chip-on-wafer bonding method, a chip-on-chip bonding method, or the like. The bonding structure BS may include a bonding pad, a bonding layer, a bonding interface, and the like. The bonding pad may include a metal such as copper and aluminum, and/or an alloy. The bonding interface may include a non-metal-non-metal interface, a metal-metal interface, or the like. The memory cell array CA and the peripheral circuit PC may be electrically connected by the bonding structure BS, such as described with respect to previous figures.

For reference, an interconnection structure included in the memory cell array CA and/or the peripheral circuit PC may be directly connected without a bonding pad. As an embodiment, a bonding layer included in the memory cell array CA and a bonding layer included in the peripheral circuit PC may be bonded to form a bonding interface, and the interconnection structure included in the memory cell array CA and the interconnection structure included in the peripheral circuit PC may be directly connected. Through this process, contact plugs, lines, and the like formed on different wafers may be electrically connected without a separate bonding pad.

Other configurations may be equal or similar to those described above with reference to FIG. 32.

The semiconductor device may have a structure in which the embodiments described above with reference to FIG. 32 and FIG. 33 are combined or may have a partially modified structure. In the embodiment described with reference to FIG. 32 and FIG. 33, positions of the memory cell array CA and the peripheral circuit PC may be changed. At least one memory cell array CA and/or at least one peripheral circuit PC may be additionally bonded to the embodiment described with reference to FIG. 32. As an embodiment, a portion of the peripheral circuitry PC may be positioned in the memory cell array CA.

Although embodiments according to the technical spirit of the present disclosure are described with reference to the accompanying drawings, this is only for describing an embodiment according to the concept of the present disclosure, and the present disclosure is not limited to the above-described embodiments. Within the scope of the technical spirit of the present disclosure described in the claims, various forms of substitution, modification, and change of the embodiments will be possible by those skilled in the art to which the present disclosure belongs, and these also belong to the scope of the present disclosure.

Although embodiments according to the technical idea of the present disclosure are described above with reference to the accompanying drawings, this is only for explaining the embodiments according to the concept of the present disclosure, and the present disclosure is not limited to the above embodiments. Various types of substitutions, modifications, and changes for the embodiments may be made by those skilled in the art, to which the present disclosure pertains, without departing from the technical idea of the present disclosure defined in the following claims, and it should be construed that these substitutions, modifications, and changes belong to the scope of the present disclosure.

What is claimed is:

1. A semiconductor device comprising:
a first gate structure including a plurality of first conductive layers that are alternately stacked with a plurality of first insulating layers;
a second gate structure including a plurality of second conductive layers that are alternately stacked with a plurality of second insulating layers;
a third gate structure including a plurality of third conductive layers that are alternately stacked with a plurality of third insulating layers; and
a first contact plug extending into the first gate structure through the third gate structure and the second gate structure, the first contact plug connected to a first of the plurality of first conductive layers, and the first contact plug including a first inflection portion located at an interface between the second gate structure and the third gate structure.

2. The semiconductor device of claim 1, wherein the first contact plug comprises:
a first sub-contact plug extending into the first gate structure through the second gate structure and connected to the first of the plurality of first conductive layers; and
a second sub-contact plug connected to the first sub-contact plug through the third gate structure;
wherein a width of the first sub-contact plug is different from a width of the second sub-contact plug at the first inflection portion; and
wherein the first inflection portion is formed at an interface where the first sub-contact plug and the second sub-contact plug meet.

3. The semiconductor device of claim 1, wherein the first contact plug comprises:
a first sub-contact plug located in the first gate structure and the second gate structure, wherein the first sub-contact plug includes a first pad located in the first gate structure and extends into the first gate structure through the first pad and connected to the first of the plurality of first conductive layers; and
a second sub-contact plug connected to the first sub-contact plug and extending through the third gate structure.

4. The semiconductor device of claim 3, wherein the first pad protrudes from sidewalls of the first sub-contact plug.

5. The semiconductor device of claim 1, further comprising a plurality of second contact plugs extending into the second gate structure through the third gate structure, wherein each of the plurality of second contact plugs is connected to a different one of the plurality of second conductive layers.

6. The semiconductor device of claim 5, wherein each of the plurality of second contact plugs includes a second pad located in the second gate structure and extends into the second gate structure through the second pad.

7. The semiconductor device of claim 6, wherein the second pad protrudes from sidewalls of the second contact plug.

8. The semiconductor device of claim 1, further comprising a plurality of third contact plugs located in the third gate structure, wherein each of the plurality of third contact plugs is connected to a different one of the plurality of third conductive layers.

9. The semiconductor device of claim 1, further comprising at least one channel structure extending through the third gate structure, the second gate structure, and the first gate structure, wherein the at least one channel structure includes a second inflection portion located at an interface between the first gate structure and the second gate structure and a third inflection portion located at an interface between the second gate structure and the third gate structure.

10. The semiconductor device of claim 1, wherein the first inflection portion includes a step in a sidewall at an interface between consecutive sections of the first contact plug.

11. A semiconductor device comprising:
a first gate structure including a plurality of first conductive layers that are alternately stacked with a plurality of first insulating layers;
a second gate structure including a plurality of second conductive layers that are alternately stacked with a plurality of second insulating layers;
a plurality of first contact plugs located in the second gate structure and the first gate structure, wherein each of the plurality of first contact plugs includes a first pad located in the first gate structure, extends into the first gate structure through the first pad, and is connected to a different one of the plurality of first conductive layers; and
a plurality of second contact plugs located in the second gate structure, wherein each of the plurality of second contact plugs is connected to a different one of the plurality of second conductive layers.

12. The semiconductor device of claim 11, wherein the first pad overlaps with an uppermost first conductive layer of the plurality of first conductive layers.

13. The semiconductor device of claim 11, wherein the first pad protrudes from sidewalls of at least one of the plurality of first contact plugs.

14. The semiconductor device of claim 11, further comprising:
a third gate structure including a plurality of third conductive layers that are alternately stacked with a plurality of third insulating layers; and
a plurality of third contact plugs located in the third gate structure, wherein each of the plurality of third contact plugs is connected to a different one of the plurality of the third conductive layers.

15. The semiconductor device of claim 11, wherein each of the plurality of second contact plugs includes a second pad located in the second gate structure, extends into the second gate structure through the second pad, and is connected to a different one of the plurality of second conductive layers.

16. The semiconductor device of claim 15, wherein the second pad overlaps with an uppermost second conductive layer of the plurality of second conductive layers.

17. The semiconductor device of claim 15, wherein the second pad protrudes from sidewalls of the second contact plug.

18. The semiconductor device of claim 14, wherein the first contact plug includes an inflection portion located at an interface between the second gate structure and the third gate structure.
